(19) United States
(12) Patent Application Publication
(10) Pub. No.: US 2002/0140461 A1
(43) Pub. Date: Oct. 3, 2002

(54) Low voltage differential signaling output buffer

(76) Inventors: Syed K. Enam, Mission Viego, CA (US); Masoud Djafari, Marina Del Rey, CA (US); Vi Lee, Los Angeles, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/873,936

(22) Filed: Jun. 4, 2001

Related U.S. Application Data
(60) Provisional application No. 60/208,899, filed on Jun. 2, 2000.
(60) Provisional application No. 60/267,366, filed on Feb. 7, 2001.

(51) Int. Cl. H03K 5/22

(52) U.S. Cl. 327/65

(57) ABSTRACT

The invention relates to methods and apparatus that advantageously provide relatively high-frequency data communication and relatively low power consumption in a low voltage differential signaling (LVDS) output buffer or driver. The LVDS output buffer includes an output resistance selected to terminate reflections from mismatched loads. Advantageously, a portion of the resistance is isolated by an emitter to base junction from a load applied to output terminals of the LVDS output buffer. A remaining portion of the resistance can thereby be reduced, advantageously allowing a reduction in power loss and reducing an amount of voltage swing at output transistors of the LVDS output buffer.

### PRIORITY CLAIMS

The benefit under 35 U.S.C. § 119(e) of U.S. Provisional Application No. 60/208,899, filed Jun. 2, 2000, and entitled “MIXED MODE TRANSCEIVER” and of U.S. Provisional Application No. 60/267,366, filed Feb. 7, 2001, and entitled “TRANSCEIVER,” is hereby claimed.

### APPENDIX A

Appendix A, which forms a part of this disclosure, is a list of commonly owned copending U.S. patent applications. Each one of the applications listed in Appendix A is hereby incorporated herein in its entirety by reference thereto.

### COPYRIGHT RIGHTS

A portion of the disclosure of this patent document contains material that is subject to copyright protection. The copyright owner has no objection to the facsimile reproduction by anyone of the patent document or of the patent disclosure as it appears in the Patent and Trademark Office patent files or records, but otherwise reserves all copyright rights whatsoever.

### BACKGROUND OF THE INVENTION

1. Field of the Invention

The invention generally relates to networking. In particular, embodiments of the invention relate to network interfaces.

2. Description of the Related Art

Common electronic devices, including computers, printers, telephones, and televisions, are often interconnected so that they can communicate with one another. As time progresses, even greater numbers of devices are networked together, the devices themselves increase in, speed, and more users rely upon networked connections. Thus, there is an ever-present need for increased data rates along networks that interconnect electronic devices.

Conventional circuits for communicating data at very high data rates have proven inadequate. Conventional circuits are relatively expensive to implement or are relatively slow in operation. Further, conventional systems employing present techniques are often relatively unstable in operation and are difficult to integrate with other systems. In addition, conventional circuits inefficiently consume relatively large amounts of power, thereby wasting power, requiring expensive circuit packaging, and increasing heat dissipation requirements.

Due to the inadequacies of the present art, users have had to pay for expensive network interfaces or have suffered from the frustration and the wasted time associated with low-speed systems.

### SUMMARY OF THE INVENTION

The invention relates to methods and apparatus that advantageously provide relatively high-frequency data communication and relatively low power consumption in a low voltage differential signaling (LVDS) output buffer or driver. The LVDS output buffer includes an output resistance selected to terminate reflections from mismatched loads. Advantageously, a portion of the resistance is isolated by an emitter to base junction from a load applied to output terminals of the LVDS output buffer. A remaining portion of the resistance can thereby be reduced, advantageously allowing a reduction in power loss and reducing an amount of voltage swing at output transistors of the LVDS output buffer.

Advantageously, one embodiment of the LVDS output buffer is implemented using only transistors of the same type, such as using only NPN transistors, to simplify fabrication and to reduce cost as compared to conventional embodiments implemented with complementary devices. The similar device topology also allows the output transistors of the LVDS output buffer to be fabricated from similar devices. The similar output transistors of the LVDS output buffer according to an embodiment of the invention allow the output transistors of the LVDS output buffer to transition from a logic zero state to a logic one state and vice-versa at similar speeds and with a relatively high degree of symmetry. This is in contrast to conventional LVDS output buffers made with complementary devices, which can vary dramatically in frequency response.

One embodiment of the invention is a low voltage differential signaling (LVDS) buffer output circuit, comprising: a first voltage source terminal; a first output terminal; a first current sink circuit; a second current sink circuit; a first NPN transistor configured to source current to the first output terminal when biased to a first state, the first NPN transistor having a first base, a first collector, and a first emitter, the first collector coupled to the first voltage source terminal; a first resistor having a first resistor terminal and a second resistor terminal, the first resistor terminal connected to the first base; a second NPN transistor configured to sink current from the first output terminal when biased to a second state, the second NPN transistor having a second base, a second collector, and a second emitter, the second base coupled to the first current sink circuit, the second collector coupled to the first emitter, and the second emitter coupled to a second current sink; and a second resistor having a third resistor terminal and a fourth resistor terminal, the third resistor terminal connected to the first emitter and the second collector, and the fourth resistor terminal coupled to the first output terminal, the second resistor selected to dampen reflections from a termination mismatch.

Another embodiment of the invention is a transceiver, comprising: a first network port having an first input and a first output, the first input configured to receive a differential network signal; a buffer input terminal having a second input and a second output, the second input coupled to the first output; and a buffer, comprising: an inverter having a third input and a third output, the third input coupled to the second output; and an output circuit, comprising: a first voltage source terminal; a first output terminal; a first current sink circuit; a second current sink circuit; a first NPN transistor configured to source current to the first output terminal when biased to a first state, the first NPN transistor having a first base, a first collector, and a first emitter, the first collector coupled to the first voltage source terminal; a first resistor having a first resistor terminal and a second resistor terminal, the first resistor terminal connected to the first base; a second NPN transistor configured to sink current from the first output terminal when biased to a second state, the second NPN transistor having a second base, a second collector, and a second emitter, the second base coupled to the first current sink circuit, the second collector coupled to the first emitter, and the second emitter coupled to a second current sink; and a second resistor having a third resistor terminal and a fourth resistor terminal, the third resistor terminal connected to the first emitter and the second collector, and the fourth resistor terminal coupled to the first output terminal, the second resistor selected to dampen reflections from a termination mismatch.

Another embodiment is a low voltage differential signaling (LVDS) buffer circuit, comprising: a first input terminal configured to receive a non-inverted input signal; a second input terminal configured to receive an inverted input signal; a first output terminal configured to provide a non-inverted output signal; a second output terminal configured to provide an inverted output signal; a first transistor having a first base, a first collector, and a first emitter, the first base coupled to the first input terminal, and the first emitter coupled to a first current sink; a first resistor having a first resistor terminal and a second resistor terminal, the first resistor terminal connected to a first voltage source, and the second resistor terminal coupled to the first collector; a second transistor having a second base, a second collector, and a second emitter, the second base coupled to the first input terminal, the second collector coupled to a second voltage source, and the second emitter coupled to a second current sink; a third transistor having a third base, a third collector, and a third emitter, the third base coupled to the first collector, the third collector coupled to the first voltage source, and the third emitter coupled to a third current sink; a second resistor having a third resistor terminal and a fourth resistor terminal, the fourth resistor terminal coupled to the second output terminal; a third resistor having a fifth resistor terminal and a sixth resistor terminal, the fifth resistor terminal connected to the third emitter and the third current sink; a fourth transistor having a fourth base, a fourth collector, and a fourth emitter, the fourth base coupled to the second emitter and the second current sink, the fourth collector coupled to the third resistor terminal, and the fourth emitter coupled to a fourth current sink; a fifth transistor having a fifth base, a fifth collector, and a fifth emitter, the fifth base coupled to the sixth resistor terminal, the fifth collector coupled to a third voltage source, and the fifth emitter coupled to the fourth collector and the third resistor terminal; a sixth transistor having a sixth base, a sixth collector, and a sixth emitter, the sixth base coupled to the second input terminal, and the sixth emitter coupled to the first current sink; a fourth resistor having a seventh resistor terminal and an eighth resistor terminal, the seventh resistor terminal connected to the first voltage source, and the eighth resistor terminal coupled to the sixth collector; a seventh transistor having a seventh base, a seventh collector, and a seventh emitter, the seventh base coupled to the second input terminal, the seventh collector coupled to the second voltage source, and the seventh emitter coupled to a fifth current sink; an eighth transistor having an eighth base, an eighth collector, and an eighth emitter, the eighth base coupled to the sixth collector, the eighth collector coupled to the first voltage source, and the eighth emitter coupled to a sixth current sink; a fifth resistor having a ninth resistor terminal and a tenth resistor terminal, the tenth resistor terminal coupled to the second output terminal; a sixth resistor having an eleventh resistor terminal and a twelfth resistor terminal, the eleventh resistor terminal connected to the eighth emitter and the sixth current sink; a ninth transistor having a ninth base, a ninth collector, and a ninth emitter, the ninth base coupled to the seventh emitter and the fifth current sink, the ninth collector coupled to the ninth resistor terminal, and the ninth emitter coupled to the fourth current sink; and a tenth transistor having a tenth base, a tenth collector, and a tenth emitter, the tenth base coupled to the twelfth resistor terminal, the tenth collector coupled to the third voltage source, and the tenth emitter coupled to the ninth collector and the ninth resistor terminal.

### BRIEF DESCRIPTION OF THE DRAWINGS

These and other features of the invention will now be described with reference to the drawings summarized below. These drawings and the associated description are provided to illustrate preferred embodiments of the invention and are not intended to limit the scope of the invention.

FIG. 1 illustrates local area networks (LANs) interconnected by an optical network.

FIG. 2 illustrates a top-level view of an interface to a network, where the interface includes transceivers.

FIG. 3 consists of FIGS. 3A and 3B and illustrates a transceiver according to one embodiment of the invention.

FIG. 4 illustrates one embodiment of a receiver phase locked loop and a clock data recovery circuit.

FIG. 5A illustrates a process of phase detection.

FIG. 5B illustrates one embodiment of a phase detector circuit.

FIG. 6 illustrates one embodiment of a phase demultiplexer circuit.

FIG. 7A illustrates one embodiment of a phase alignment circuit.

FIG. 7B is a timing diagram of the phase alignment circuit.

FIG. 8 consists of FIGS. 8A, 8B, and 8C and illustrates one embodiment of a phase detector and data demultiplexer circuit.

FIG. 9 consists of FIGS. 9A and 9B and illustrates one embodiment of a digital multiplier circuit.

FIG. 10 is a timing diagram of a portion of the phase detector and data demultiplexer circuit.

FIG. 11 is a timing diagram illustrating integration of a data transition, where the data transition occurs approximately in the center of the integration window.

FIG. 12 is a timing diagram illustrating integration of a data transition, where the data transition occurs relatively late in the integration window.

FIG. 13 is a timing diagram illustrating integration of a data transition, where the data transition occurs relatively early in the integration window.

FIG. 14 illustrates an alternative embodiment of an integration circuit.

FIG. 15 illustrates an alternate embodiment of a multiplier circuit.

FIG. 16 is a timing diagram of the alternate embodiment of the integration circuit illustrated in FIG. 14.

FIG. 17 illustrates one embodiment of a sample and hold circuit.

FIG. 18 illustrates an embodiment of a data sequence identifier circuit.

FIG. 19 illustrates an embodiment of a single-ended to differential input buffer.

FIG. 20 is a timing diagram illustrating differential delay in a single-ended to differential input buffer.

FIG. 21 illustrates a process of comparing the clock frequencies of two different clocks.

FIG. 22 illustrates one embodiment of an acquisition aid circuit.

FIG. 23 illustrates one embodiment of a full-wave differentiator circuit.

FIG. 24 illustrates one embodiment of a half-wave differentiator circuit.

FIG. 25 illustrates a content of a timer or a counter in response to relatively low and relatively high beat frequency.

FIG. 26 is a timing diagram of the acquisition aid circuit of FIG. 22 with a relatively close match between a voltage-controlled oscillator signal and a reference clock signal.

FIG. 27 is a timing diagram of the acquisition aid circuit of FIG. 22 with a relatively poor match between a voltage-controlled oscillator signal and a reference clock signal.

FIG. 28 illustrates one embodiment of a framer circuit.

FIG. 29 illustrates one embodiment of a multiplexer set.

FIG. 30 illustrates one embodiment of a byte detection circuit.

FIG. 31 illustrates one embodiment of a low voltage differential signaling (LVDS) buffer circuit.

### DETAILED DESCRIPTION OF PREFERRED EMBODIMENTS

Although this invention will be described in terms of certain preferred embodiments, other embodiments that are apparent to those of ordinary skill in the art, including embodiments which do not provide all of the benefits and features set forth herein, are also within the scope of this invention. Accordingly, the scope of the invention is defined only by reference to the appended claims.

Embodiments of the invention inexpensively and reliably communicate data at relatively high data rates. Embodiments of the invention include a receiver that receives relatively high-speed serial data and automatically demultiplexes the relatively high-speed serial data to a relatively low-speed parallel data. The receiver includes a phase locked loop that quickly and efficiently synchronizes a local voltage controlled oscillator to the relatively high-speed serial data. Embodiments of the invention also include a transmitter that receives relatively low-speed parallel data and automatically multiplexes the relatively low-speed parallel data to a relatively high-speed serial data.

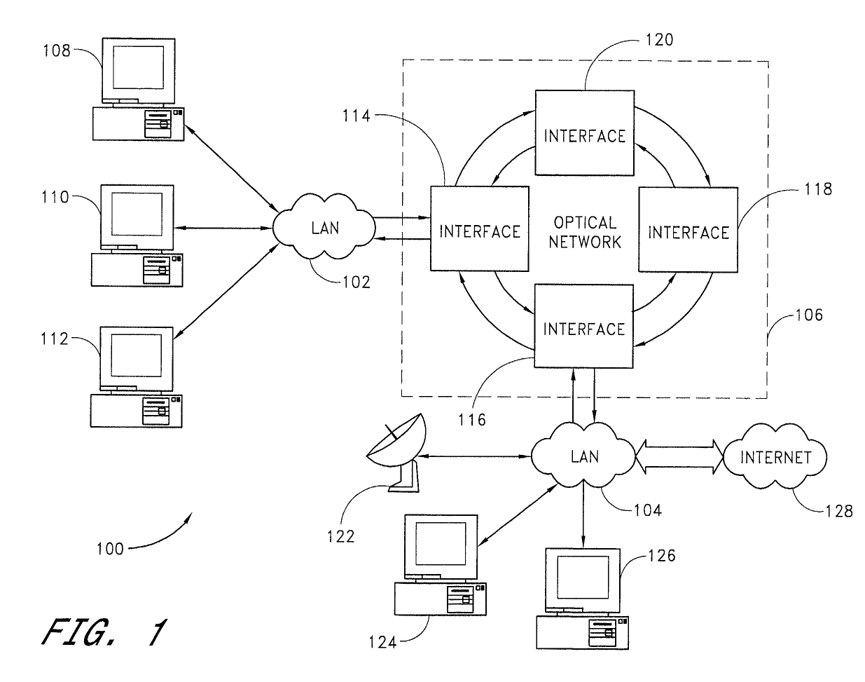

FIG. 1 illustrates a network 100 of interconnected computer systems. The illustrated network 100 includes a first local area network (LAN) 102, a second LAN 104, and an optical network 106. Computer systems 108, 110, 112 communicate with each other and external networks via the first LAN 102. The first LAN can correspond to a variety of network types, including electrical networks such as Ethernet and Fast Ethernet, and optical networks such as SONET Gigabit Ethernet 1000Base-SX and 1000Base-LX.

Networks of interconnected computer systems include transceivers. A transceiver is a device that both transmits and receives signals. A transceiver applies signals to a line in order to send data to other devices or circuits and also detects signals from a line to receive data from other devices or circuits.

The first LAN 102 communicates with the optical network 106 through a first interface 114. The optical network 106 shown in FIG. 1 is arranged in a ring. Of course, other topologies can be used such as point-to-point, star, hub, and the like. In one embodiment, the optical network 106 is a Synchronous Optical Network (SONET), and the first interface is an add/drop multiplexer (ADM). Another example of an optical network is a synchronous digital hierarchy (SDH). The interface 114 shown allows the first LAN 102 to download or drop data from and to upload or add data to the optical network 106, while allowing data unrelated to the first interface to continue or repeat to the other interfaces 116, 118, 120 in the optical network 106.

The second LAN 104 similarly communicates with the optical network 106 through a second interface 116. The optical network 106 can be either a LAN or a wide area network (WAN). The second LAN 104 shown allows a variety of devices to communicate with the optical network 106, such as a satellite dish 122, local computer systems 124, 126, and a connection to the Internet 128. In addition to computer data, the communication within the LANs 102, 104 and the optical network 106 can include a variety of data types including telephony data and video data.

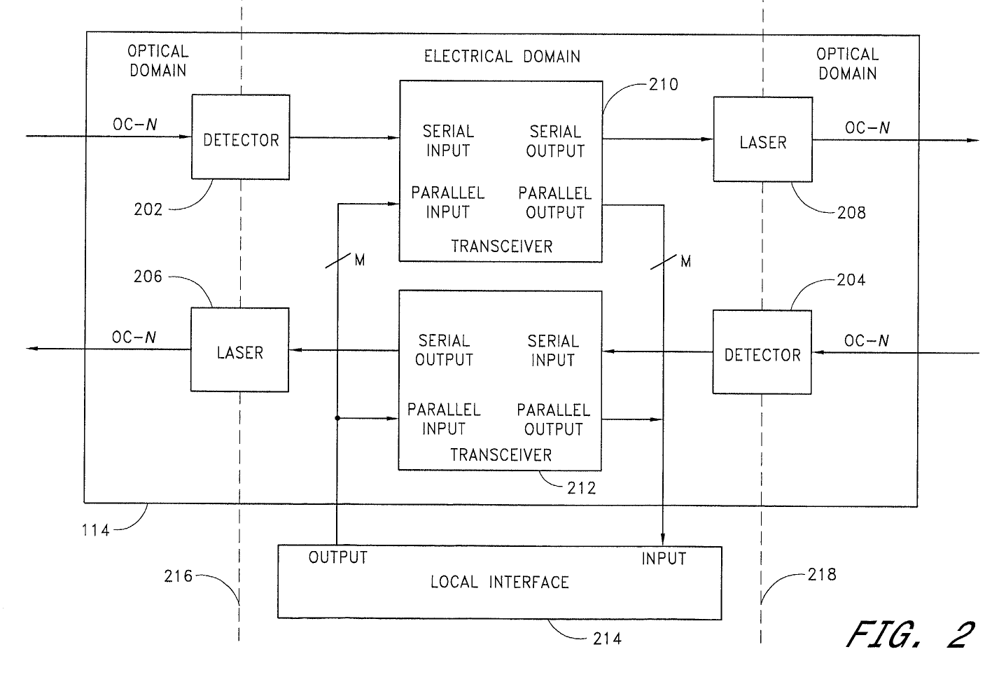

FIG. 2 illustrates further details of the first interface 114. The first interface 114 includes a first detector 202, a second detector 204, a first laser 206, a second laser 208, a first transceiver 210, a second transceiver 212, and a local interface 214. The first detector 202 and the first laser 206 allow the interface to communicate with a first path of an optical network. Similarly, the second detector 204 and the second laser 208 allow the interface to communicate with a second path of the optical network. Typically, the data in the optical network is modulated onto an optical carrier and carried within the network in fiber optic cables. The optical network can correspond to a variety of optical standards, such as numerous standards under SONET for optical carrier levels (OC) such as OC-1, OC-3, OC-12, OC-48, and OC-192, or more generally, OC-N.

The detectors 202, 204 receive the optical signals carried by the optical network and convert the optical signals to electrical signals, which are applied as inputs to the transceivers 210, 212. The lasers 204, 206 convert electrical signals from the transceivers 210, 212 to optical signals. Of course, the first interface 114 can further include conventional amplifiers, buffers, and the like. Dashed lines 216, 218 indicate where the signals are electrical and where the signals are optical.

The transceivers 210, 212 demultiplex the electrical signals from the detectors 202, 204. In one embodiment, the demultiplex process includes a conversion from serial data to parallel data. The transceivers 210, 212 drop data for the local system or local device associated with the interface 114 from the received signals and apply the extracted data as an input to the local interface 214. In addition, the transceivers 210, 212 add data from the local system or local device and combine the added data with the remainder of the received signals, i.e., the data that continues through the interface 114, and applies the combined data as inputs to the lasers 206, 208.

The illustrated embodiment of FIG. 2 uses the transceivers 210, 212 in an interface, such as an add/drop multiplexer (ADM). However, it will be understood by one of ordinary skill in the art that the transceivers can also be applied in other applications such as switches, digital cross connects, and test equipment.

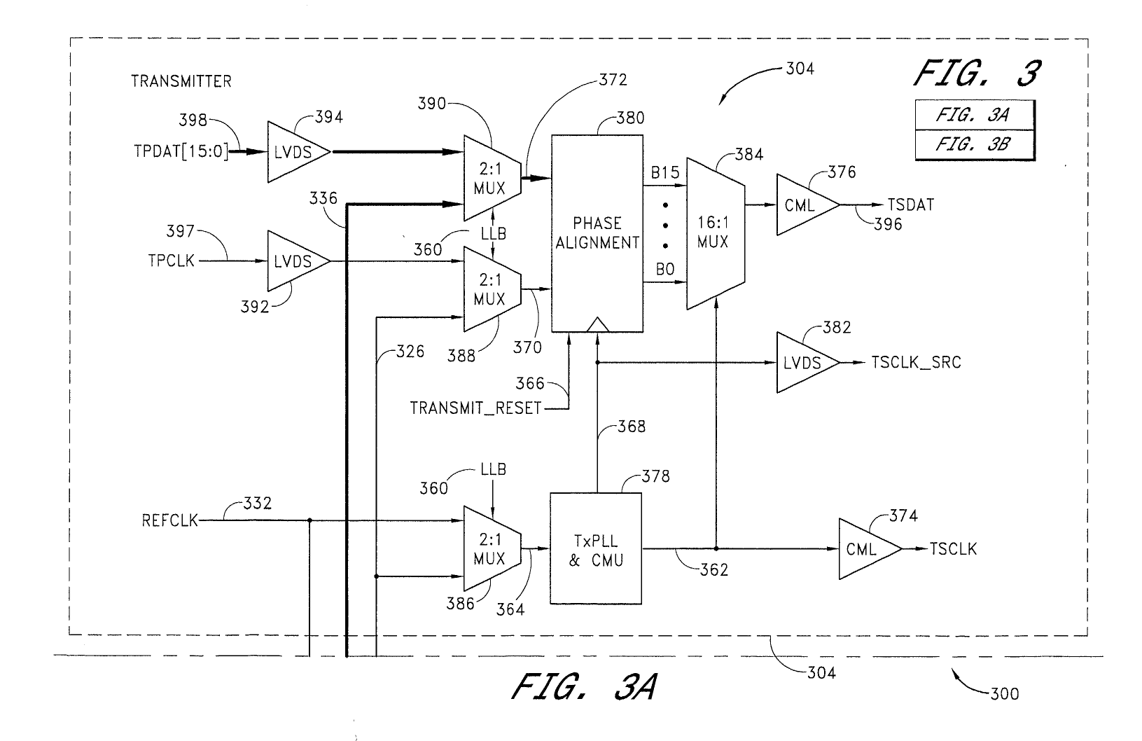

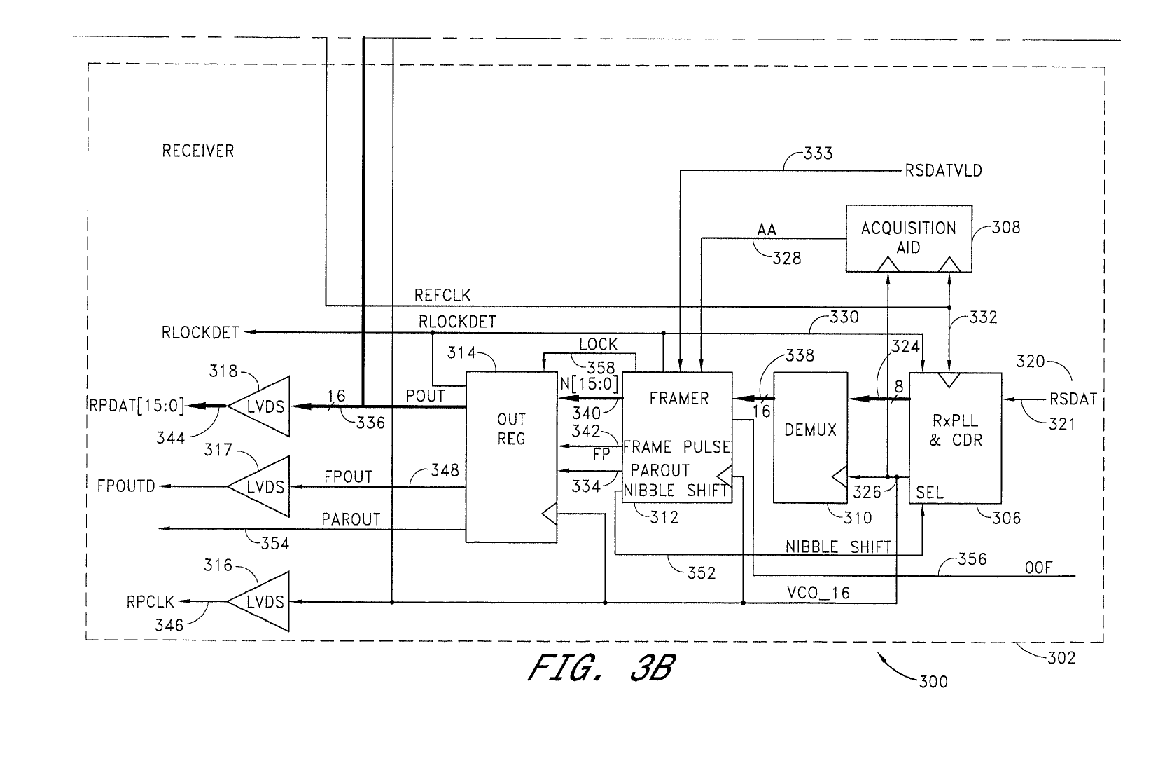

FIG. 3 illustrates a transceiver 300 according to one embodiment of the invention. Signals provided to, provided by, and internal to the transceiver 300 are differential signals. However, most signals in the illustration of FIG. 3 are shown as single lines for clarity. The transceiver 300 includes a receiver 302 and a transmitter 304. The receiver 302 accepts serial data 320 (RSDAT) at a receiver data input terminal 321, and the receiver 302 converts the serial data 320 to parallel data (RPDAT), which is available at a receiver data output terminal 344. For example, the receiver 302 of the transceiver 300 can receive the serial data 320 from the first detector 202 and can provide the parallel data (RPDAT) to the local interface 214.

The transmitter 304 accepts parallel data (TPDAT) at a transmitter data input terminal 398, and the transmitter 304 converts the parallel data (TPDAT) to serial data (TSDAT), which is available at a transmitter data output terminal 396. For example, the transmitter 304 can receive parallel data (TPDAT) from an output of the local interface 214 and can provide the converted serial data (TSDAT) as an input to the second laser 208. The transmitter 304 also receives a data clock (TPCLK) and a reference clock (REFCLK) which can come from the local interface 214. In addition to providing the serial data (TSDAT), the transmitter 304 provides an associated transmit clock (TSCLK) which can be sent in parallel with the serial data to a destination device. The transmitter 304 also outputs a sub-multiple of the transmit clock (TSCLK SRC) which can be used for testing purposes or provided to the local interface 214.

In one embodiment, the transceiver 300 is implemented by silicon-germanium (Si-Ge) npn bipolar transistors. However, it will be understood by one of ordinary skill in the art that the circuits can also be implemented with other technologies, such as Si-Ge pnp bipolar transistors, silicon npn or pnp bipolar transistors, metal-oxide semiconductor field-effect transistors (MOSFETs), gallium arsenide metal semiconductor field-effect transistors (GaAs FETs or MESFETs), heterojunction bipolar transistors (HBTs), Si-Ge bipolar complementary metal-oxide semiconductor (BiCMOS), and the like. In one embodiment of the transceiver 300, the transistors operate substantially in the linear region and do not reach cutoff or saturation under normal operating conditions.

The illustrated transceiver 300 couples to power and to ground through V_{DD} and V_{SS}, respectively. It will be understood by one of ordinary skill in the art that the voltage provided to the transceiver 300 by a power supply can vary widely from application to application, and the transceiver 300 can be designed to accommodate a relatively wide range of voltage. In one embodiment, V_{DD} is about 3.3 Volts relative to V_{SS}. Preferably, V_{DD} is maintained to about ±10% of 3.3 Volts relative to V_{SS}. More preferably, V_{DD} is within about ±5% of 3.3 Volts relative to V_{SS}.

The illustrated receiver 302 includes a receiver phase locked loop (Rx PLL) and clock data recovery (CDR) circuit 306, an acquisition aid circuit 308, a demultiplexer circuit 310, a framer circuit 312, an output register circuit 314, and low voltage differential signaling drivers (LVDS) 316, 318.

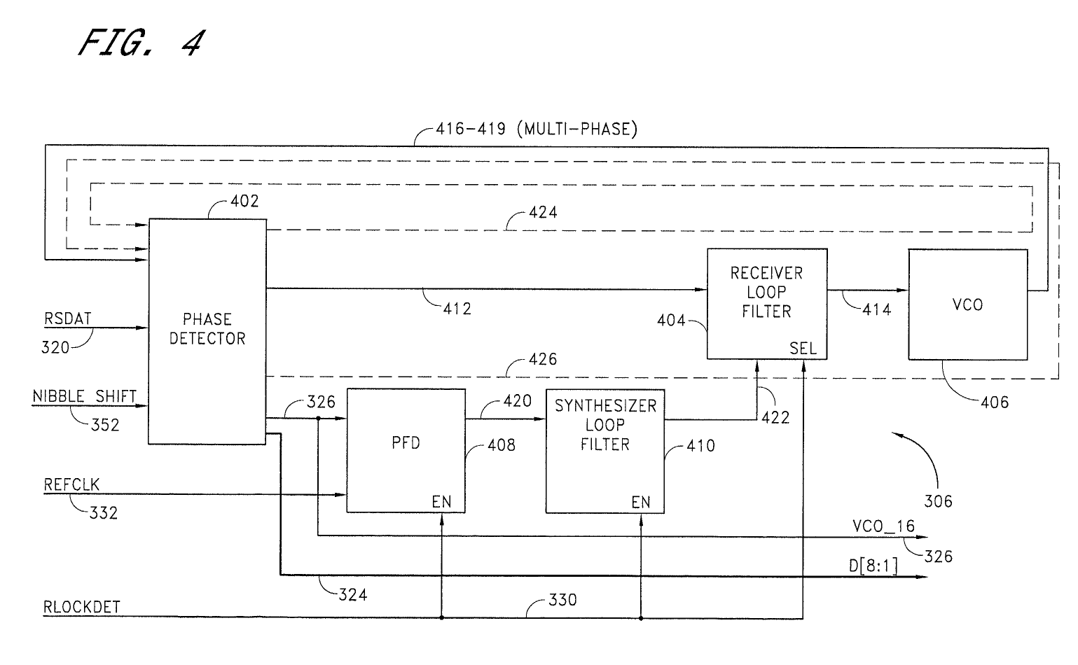

The Rx PLL and CDR circuit 306 is coupled to the receiver data input terminal 320 to receive the serial data 320 (RSDAT), and extracts a receiver clock signal 326 (VCO_{—}16) from the serial data 320 (RSDAT). The receiver clock signal (VCO_{—}16) 326 is applied as an input to other circuits in the receiver 302. In one embodiment, the receiver clock signal 326 (VCO_{—}16) is supplied as an output to the system through the LVDS driver 316. One embodiment of the Rx PLL and CDR circuit 306 also at least partially demultiplexes the serial data 320 (RSDAT) to a partially demultiplexed data 324 while the Rx PLL and CDR circuit 306 recovers the clock signal. In one embodiment, the partially demultiplexed data 324 is an 8-bit wide data path. Further details of one embodiment of the RX PLL and CDR circuit 306 are described later in connection with FIG. 4.

The acquisition aid circuit 308 receives a reference clock signal 332 from an external source and receives the receiver clock signal 326 from the RX PLL and CDR circuit 306. The reference clock signal 332 is derived from a relatively stable source such as a quartz oscillator. When the receiver clock signal 326 is properly detected by the Rx PLL and CDR circuit 306, the receiver clock signal 326 is closely related to the reference clock signal 332. In one example, the receiver clock signal 326 is closely related to the reference clock signal 332 in frequency but not in phase. In one example, when properly detected, the receiver clock signal 326 is within a predetermined variance from the reference clock signal 332. It will be understood by one of ordinary skill in the art that the frequencies of the receiver clock signal 326 and the reference clock signal 332 can also be related to each other through a multiple or sub-multiple.

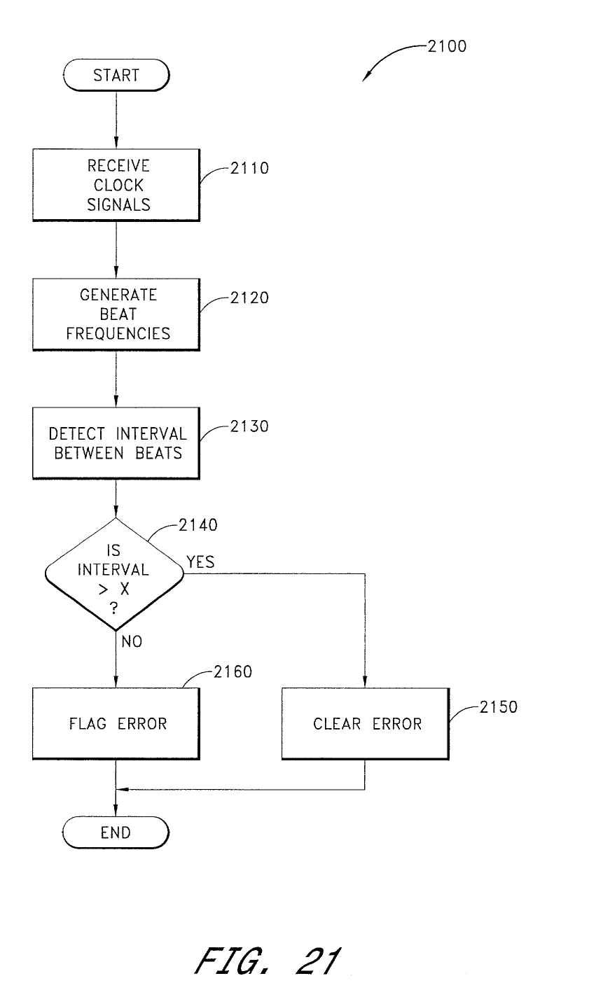

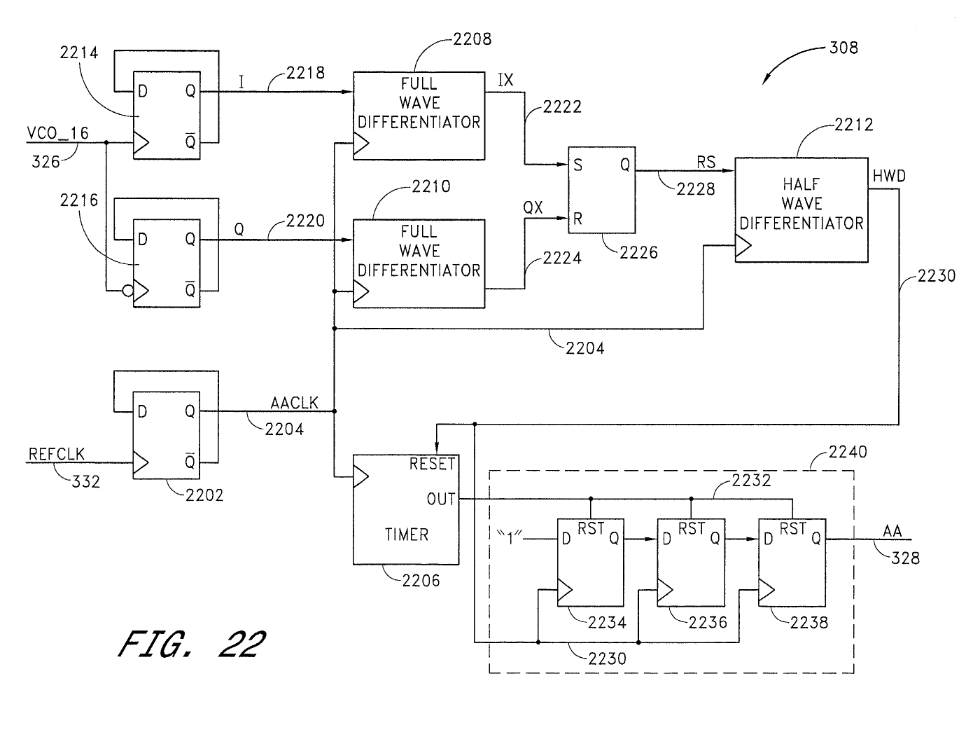

The acquisition aid circuit 308 compares the relative frequencies of the reference clock signal 332 and the receiver clock signal 326. The acquisition aid circuit 308 activates an AA signal 328 in response to a detection of a relatively close match in frequency between the reference clock signal 332 and the receiver clock signal 326. The AA signal 328 is used to indicate whether the Rx PLL and CDR 306 circuit has properly detected the receiver clock signal 326 (VCO_{—}16). A receiver lock detected signal 330 (RLOCKDET), which derives from the AA signal 328, provides a feedback indication to the Rx PLL and CDR circuit 306 that it is properly detecting the receiver clock signal 326. When the receiver clock signal 326 (VCO_{—}16) drifts from the reference clock signal 332 (REFCLK) by at least a predetermined amount, a phase locked loop within the Rx PLL and CDR circuit 306 locks to the reference clock signal 332 (REFCLK), rather than to the receiver serial data 320 (RSDAT), to maintain the frequency of the phase locked loop to within a lock range of the phase locked loop for a properly detected receiver clock signal 326. Further details of one embodiment of the acquisition aid circuit 308 are described later in connection with FIG. 22.

The demultiplexer circuit 310 receives the partially demultiplexed data 324 and the receiver clock signal 326 as inputs from the Rx PLL and CDR circuit 306. The demultiplexer circuit 310 converts the partially demultiplexed data 324 to a fully demultiplexed data 338 and applies the fully demultiplexed data 338 as an input to the framer 312. In one embodiment, the fully demultiplexed data 338 path is 16-bits wide.

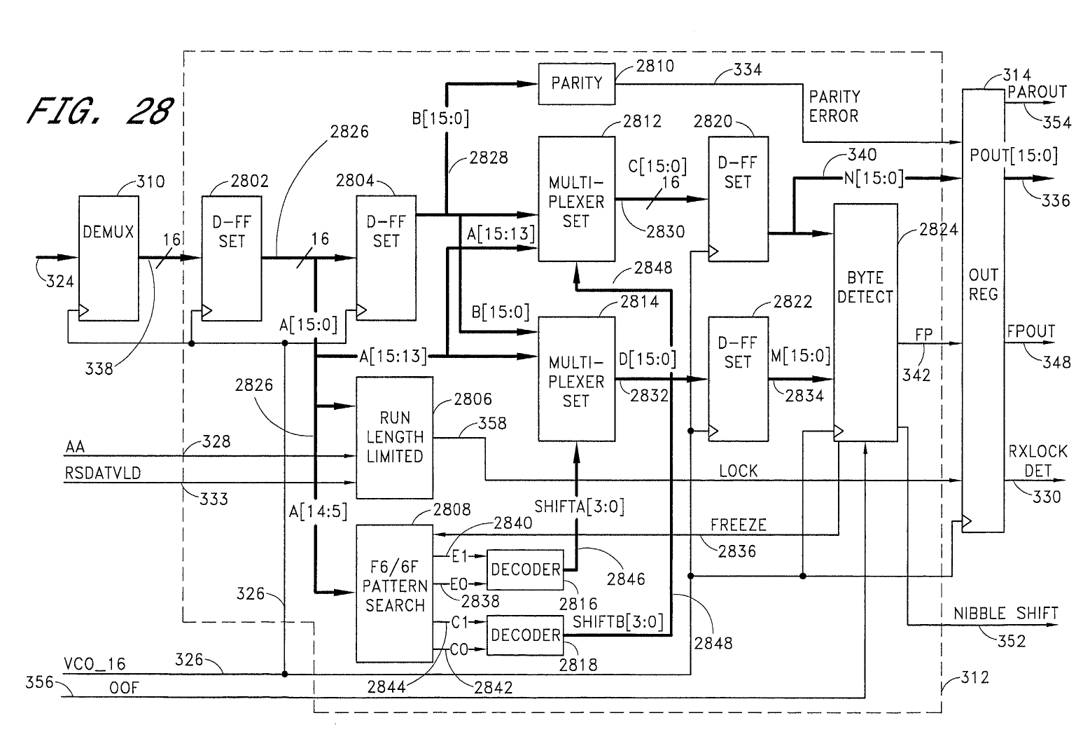

The framer circuit 312 receives the fully demultiplexed data 338 from the demultiplexer circuit 310 and uses the frame headers within the data to align the data in accordance with a predetermined standard, such as the SONET standard. The framer circuit 312 also performs data integrity checking operations such as parity checking and run length limited operations, and the framer circuit 312 extracts the raw data and the frame header components from the fully demultiplexed data 338. Further details of one embodiment of the framer circuit 312 are described later in connection with FIGS. 28, 29, and 30.

The output register 314 receives the aligned data 340 from the framer circuit 312, synchronizes the aligned data 340 and other signals to the receiver clock. Synchronized aligned data 336 (POUT[15:0]) is applied as inputs to the LVDS drivers 318 and sent to an external receiving device, such as an add/drop multiplexer (ADM). In addition, the output register 314 receives an FP signal 342 and a parity error signal 334, and aligns the signals to an FPOUT signal 348 and a parity output signal (PAROUT) signal 354, respectively. The FPOUT signal 348 is further buffered by a LVDS buffer 317 to a differential FPOUTD signal, which is supplied externally to indicate that the receiver 302 has detected a transition between framing bytes. The parity output signal 334 indicates that the data provided by the receiver 300 is corrupted.

The illustrated transmitter 304 includes LVDS input buffers 392, 394, multiplexers 384, 386, 388, 390, a phase alignment circuit 380, a clock multiplier unit 378, a LVDS output driver 382, and current mode logic (CML) drivers 374, 376.

Parallel input data (e.g., 16-bits wide words TPDAT[15:0]) is provided to a transmitter data input terminal 398 which is coupled to input terminals of the LVDS buffers 394. In one embodiment, the LVDS input buffers 394 are a set of 16 LVDS input buffers coupled to the respective bits of the parallel input data. A data clock (TPCLK) associated with the parallel input data is provided to a data clock input terminal 397 which is coupled to an input terminal of the LVDS buffer 392. The LVDS input buffers 392, 294 strengthen signals, such as the parallel input data and its associated clock, which may have traveled in lossy lines, have been subjected to noisy environments, or have been provided to multiple devices in parallel.

The outputs of the LVDS input buffers 394 are provided to inputs of the multiplexers 390. In one embodiment, the multiplexers 390 are a set of 16 2:1 multiplexers coupled to the respective outputs of the LVDS input buffers 394. Data lines 336 from the receiver 302 are also coupled to the multiplexers 390. The outputs of the multiplexers 390 are provided to the phase alignment circuit 380 via data lines 372.

During normal operation, the multiplexers 390 select the parallel input data from the transmitter data input terminal 398 to output on the data lines 372 for processing by the transmitter 304. During a test mode (i.e. a low-frequency loop back test), the multiplexers 390 select data on the data lines 336 from the receiver 302 to output on the data lines 372. A line loop back (LLB) signal 360 is provided to the multiplexers 390 to perform the data selection. The low-frequency loop back test is further described below.

The output of the LVDS input buffer 392 is provided to an input of the 2:1 multiplexer 388. A clock signal on a receiver clock signal line 326 is provided to another input of the multiplexer 388. The output of the multiplexer 388 is provided to the phase alignment circuit 380 via an input clock line 370.

During normal operation, the multiplexer 388 selects the data clock (TPCLK) at the data clock input terminal 397 of the transmitter 304 to output on the input clock line 370. During the low-frequency loop back test, the multiplexer 388 selects the clock signal on the receiver clock signal line 326 to output on the input clock line 370. The LLB signal 360 is provided to the multiplexer 388 to perform the clock selection. The low-frequency loop back test is further described below.

A reference clock (REFCLK) is provided to an input terminal of the 2:1 multiplexer 386 via a transmitter input terminal 332. The clock signal on the receiver clock signal line 326 is provided to another input of the multiplexer 386. The output of the multiplexer 386 is provided to the clock multiply unit 378 via a reference clock line 364.

During normal operation, the multiplexer 386 selects the reference clock (REFCLK) at the input terminal 332 of the transmitter 304 to output on the reference clock line 364. During the low-frequency loop back test, the multiplexer 386 selects the clock signal on the receiver clock signal line 326 to output on the reference clock line 364. The LLB signal 360 is provided to the multiplexer 388 to perform the reference clock selection. The low-frequency loop back test is further described below.

The clock multiply unit (CMU) 378 receives a reference clock signal on the reference clock line 364 and generates transmitter clocks which are phase locked with the reference clock signal. The outputs of the CMU 378 (i.e., transmitter clocks) are provided to other circuits in the transmitter 304, such as the phase alignment circuit 380, the multiplexer 384, and the CML output driver 374. The frequencies of transmitter clocks can be sub-multiples or multiples of the reference clock signal. In one embodiment, the reference clock signal is approximately 622 MHz, a first output of the CMU 378 (i.e., a first transmitter clock) provided to the phase alignment circuit 380 via clock line 368 is substantially the same frequency while a second output of the CMU 378 (i.e., a second transmitter clock) provided to the multiplexer 384 and the CML driver 374 via clock line 362 is approximately 10 GHz (i.e., approximately 16 times the frequency of the reference clock signal). The CMU 378 is explained in more detail below.

In addition to receiving the first transmitter clock via the clock line 368, the phase alignment circuit 380 receives a transmitter reset signal (TRANSMIT_RESET) on signal line 366, the data signals on data lines 372, and the associated data clock on input clock line 370. The phase alignment circuit 380 aligns the phases of the data signals to the phases of the first transmitter clock and provides the aligned data to the 16:1 multiplexer 384 for conversion to a serial format using the second transmitter clock which is phase locked with the first transmitter clock. The phase alignment circuit 380 is explained in more detail below.

The serial output of the 16:1 multiplexer 384 is provided to the CML driver 376. The output of the CML driver 376 is coupled to the transmitter data output terminal 396 to provide the serial data (TSDAT). The first transmitter clock is provided to the LVDS driver 382 which outputs a clock signal (TSCLK_SRC) with a frequency that is a sub-multiple of the transmission frequency. The second transmitter clock is provided to the CML driver 374 which outputs a clock signal (TSCLK) with a frequency that is substantially the same as the transmission frequency.

One embodiment of the transceiver 300 further includes a low-frequency loop back path. The low-frequency loop back path advantageously allows a relatively thorough test of the related lasers, fiber optic cables, optical detectors, and transceivers and yet, provides test equipment with a relatively simple interface.

By contrast, a line test disadvantageously fails to test a significant portion of a transceiver 300. For example, in a line test, test equipment applies test data serially to the receiver data input terminal 320, the transceiver 300 couples the receiver data input terminal 320 to the transmitter data output terminal 396, and the test equipment reads the test data from the transmitter data output terminal 396 to complete the test. Disadvantageously, potential malfunctions within the transceiver 300 can go undetected in a simple line test.

In another test known as a diagnostic test, test equipment applies test data to the low-frequency side of a transceiver 300 through a transmitter data input terminal 398. The test data propagates through circuits in a transmitter 304 of the transceiver 300 to a transmitter data output terminal 396, is coupled from the transmitter data output terminal 396 to a receiver data input terminal 320, and propagates through circuits in a receiver 302 of the transceiver 300 to a receiver data output terminal 344, where the test data is read by the test equipment to complete the test. Although the diagnostic test tests a relatively large portion of the transceiver 300, implementation of the diagnostic test disadvantageously requires a relatively large array of relatively expensive test equipment.

A low-frequency loop back advantageously allows a new test combining the relative thorough testing associated with the diagnostic test with the ease and simplicity of the line test. With reference to FIG. 3, test equipment activates a line loop back (LLB) signal 360 to prepare a transceiver 300 for the low-frequency loop back test. The LLB signal 360 is applied to select input terminals of respective multiplexers 386, 388, 390 in a transmitter of the transceiver 300. In one embodiment, the test equipment applies test data in a serial format to a receiver 302 at a receiver data input terminal 320. The test data is converted to a parallel format by the receiver 302, is coupled from an output stage of the receiver 302 to an input stage of the transmitter 304 in the parallel format, is converted back to the serial format by the transmitter 304, and is provided in the serial format at a transmitter data output terminal 396 for reading by the test equipment.

During the low-frequency loop back test, a clock signal associated with the test data is also coupled from the receiver 302 to the transmitter 304. The coupling of the test data and the associated clock signal from the receiver 302 to the transmitter 304 is achieved by the LLB signal 360. In response to the activation of the LLB signal 360, the set of data multiplexers 390 in the transmitter 304 selects data on data lines 336 from an output stage of the receiver 302 (e.g., data at inputs of LVDS drivers 318) for processing by the transmitter 304. In response to the activation of the LLB signal 360, the data clock multiplexer 388 selects a clock signal on a receiver clock signal line 326 (VCO_{—}16) as an input to a phase alignment circuit 380 of the transmitter 304. In response to the activation of the LLB signal 360, the reference clock multiplexer 386 also selects the clock signal on the receiver clock signal line 326 (VCO_{—}16) as an input to a clock multiply unit 378 of the transmitter 304.

As described above, the test data is applied serially to the receiver data input terminal 320, the test data propagates through a portion of the receiver 302 to a low-frequency or parallel side of the receiver 302, and the receiver 302 provides the test data in parallel form through the data lines 336. The receiver 302 also recovers embedded clock information in the test data and provides at least a portion of the recovered clock signal to the transmitter 304 as illustrated by the receiver clock signal line 326.

The transmitter 304 portion of the transceiver 302 receives the parallel test data on data lines 336 and the clock signal on the receiver clock signal line 326, and the transmitter 304 generates a serial bitstream from the parallel test data as an output at the transmitter data output terminal 396, which is applied as an input to and read by the test equipment. Advantageously, the illustrated low-frequency loop back allows testing of a substantial portion of the transceiver 300 from the high-speed serial interface side of the transceiver 300, thereby obviating the need for expensive and complex test equipment.

FIG. 4 illustrates one embodiment of the receiver phase locked loop and a clock data recovery (Rx PLL and CDR) circuit 306. The illustrated Rx PLL and CDR circuit 306 includes a phase detector circuit 402, a receiver loop filter circuit 404, a voltage controlled oscillator (VCO) circuit 406, a phase frequency detector (PFD) circuit 408, and a synthesizer loop filter circuit 410.

When the Rx PLL and CDR circuit 306 is locked to the serial data 320 (RSDAT) and generates the partially demultiplexed data 324 and the receiver clock signal (VCO_16) 326, the Rx PLL and CDR circuit 306 operates through a first path 424. The first path 424 starts at the phase detector circuit 402, continues to the receiver loop filter 404, continues to the VCO circuit 406, and returns to the phase detector circuit 402. When the Rx PLL and CDR circuit 306 is locked to the reference clock signal 332, the Rx PLL and CDR circuit 306 operates through a second path 426. The second path 426 starts at the phase detector circuit 402, continues to the PFD circuit 408, continues to the synthesizer loop filter 410, continues to the receiver loop filter circuit 404, continues to the VCO circuit 406, and returns to the phase detector circuit 402.

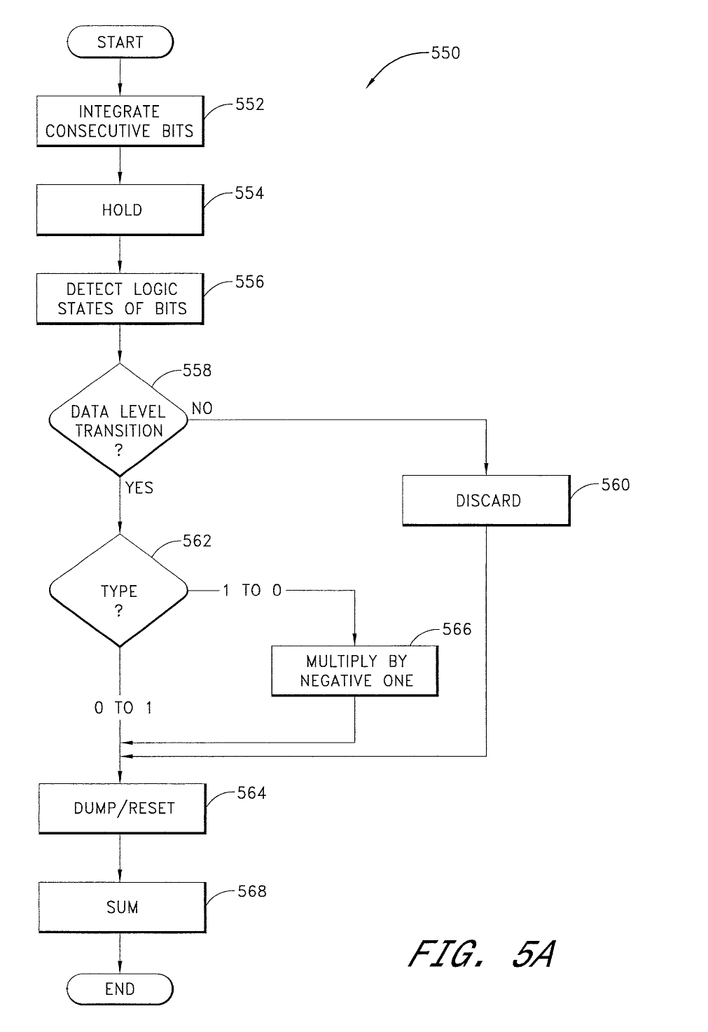

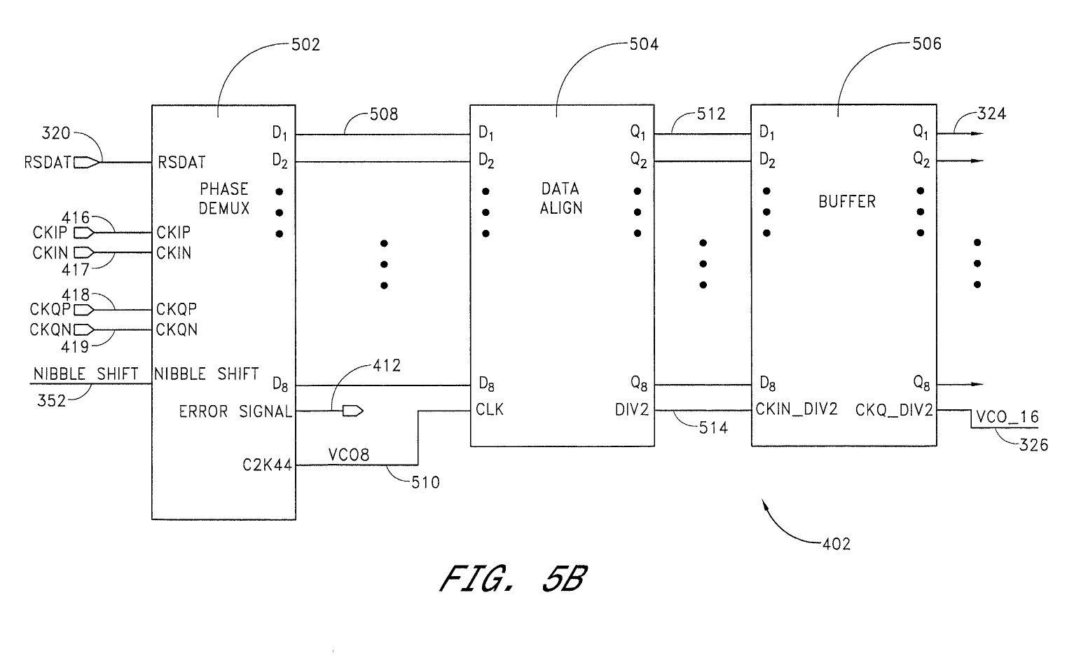

The phase detector circuit 402 receives the serial data 320 (RSDAT), a nibble shift signal 352, and VCO output signals 416, 417, 418, 419 as inputs. In one embodiment, the VCO output signals 416, 417, 418, 419 are derived from a common clock signal and provide multiple phases of the clock signal at about 90 degrees of phase shift. The phase detector circuit 402 generates a first error signal 412 in response to a comparison between the VCO output signals 416, 417, 418, 419 and the serial data 320. The phase detector circuit 402 also generates the partially demultiplexed data 324 and the receiver clock signal 326 (VCO_{—}16) from the serial data 320 and the VCO output signals 416, 417, 418, 419. In one embodiment, the receiver clock signal 326 is divided down by 16 from the cumulative frequency of the VCO output signals 416, 417, 418, 419. It will be understood by one of ordinary skill in the art that the receiver clock signal 326 can be divided by other amounts, such as by 8, by 32, and by the like. Further details of one embodiment of the phase detector circuit 402 are described later in connection with FIG. 5B.

The receiver loop filter circuit 404 applies a low-pass filter response to the first error signal 412 from the phase detector circuit 402 and generates an oscillator control signal 414, which is applied as a control input to the VCO circuit 406. One embodiment of the receiver loop filter circuit 404 supplies a relatively constant current source bias to the phase detector circuit 402, which adaptively sinks the current from the constant current source bias in response to the detected phase variance between the VCO output signals 416, 417, 418, 419 and the serial data 320.

The VCO circuit 406 receives the oscillator control signal 414 from the receiver loop filter 404 and generates the VCO output signals 416, 417, 418, 419. The VCO circuit 406 varies the frequency of the VCO output signals 416, 417, 418, 419 in response to the oscillator control signal 414. In one embodiment, the VCO circuit 406 generates four output signals 416, 417, 418, 419 at the same frequency, where the four output signals are at about 90 degrees of phase shift apart. When the Rx PLL and CDR circuit 306 is synchronized to the serial data 320, the combined frequency of the four output signals 416, 417, 418, 419 is the same as the bit rate of the serial data 320.

The phase frequency detector (PFD) circuit 408 receives the receiver clock signal 326 (VCO_{—}16) and the reference clock signal 332 (REFCLK). The phase frequency detector (PFD) circuit 408 compares the receiver clock signal 326 (VCO_{—}16) to the reference clock signal 332 (REFCLK) and generates a reference clock error signal 420 in response to the comparison. In one embodiment, the frequency of the receiver clock signal (VCO_{—}16) 326 is within a lockable range for the phase locked loop when the phase detector circuit 402 detects the embedded clock within the serial data 320. In one example, the reference clock signal 332 (REFCLK) is about 622 megahertz (MHz), the VCO output signals 416, 417, 418, 419 are each about 2.5 gigahertz (GHz) to combine to 10 GHz, and the receiver clock signal 326 (VCO_{—}16) is about 622 MHz. It will be understood by one of ordinary skill in the art that the reference clock signal 332 (REFCLK) and/or the receiver clock signal (VCO_{—}16) 326 applied to the phase frequency detector (PFD) circuit 408 may additionally be divided down to an alternative frequency.

The synthesizer loop filter circuit 410 receives the reference clock error signal 420 and applies a low-pass filter response to the reference clock error signal 420 to produce a second error signal 422, which is applied as an input to the receiver loop filter circuit 404. Optionally, the phase frequency detector circuit 408 and the synthesizer loop filter circuit 410 are powered down in response to an activation of a receiver lock detected signal 330 (RLOCKDET) by disabling the power supply biases to the respective circuits. The receiver loop filter 404 selects between the first error signal 412 and the second error signal 422 in response to the receiver lock detect signal 330 (RLOCKDET) to select which error signal is applied to the VCO circuit 406. The selection of the error signal applied to the VCO circuit 406 determines whether the first path 424 or the second path 426 is active.

FIG. 5A illustrates a process 550 of phase detection. The phase detection process compares the phase of a first clock signal such as a VCO clock signal and a phase of a second clock signal such as a clock signal embedded in a serial data bitstream. The process 550 can be used in a phase locked loop to synchronize a VCO clock to serial data. In contrast to a conventional phase detection process that samples the serial data with extremely narrow samples of varying pulsewidths, the process 550 detects the phase of the serial data by integrating over relatively fixed and relatively long integration periods.

In a first step 552, the process integrates over an integration period that includes two consecutive or two adjacent bits in the serial data. The integration period includes a transition between a first data bit and a second data bit. For example, the first data bit can be a logic 0 or a logic 1, and the second data bit can also be a logic 0 or a logic 1.

The first clock signal can correspond to either a single-phase clock signal or a multiple-phase clock signal. The integration period can be determined by periods of a single-phase first clock signal or by phases of a multiple phase first clock signal. Ordinarily, the first clock signal is relatively close in frequency to the frequency of the data rate of the serial data. However, it will be understood by one of ordinary skill in the art that the frequency of the clock signal and the frequency of the data rate of the serial data do not have to be identical, as one demonstrative use of the phase detection process is to synchronize the first clock signal and the second clock signal in a feedback loop. The process advances from the first step 552 to a second step 554.

In the second step 554, the process temporarily holds the result of the integration of the consecutive bits to allow control logic or steering logic to determine how to interpret the result of the integration performed in the first step 552. The process advances from the second step 554 to a third step 556.

In the third step 556, the process detects the logic states of the consecutive bits integrated in the first step 552. In one embodiment, the process latches the logic states of the serial data at times corresponding to the first data bit and the second data bit. The process advances from the third step 556 to a first decision block 558.

In the first decision block 558, the process determines whether the transition between the first data bit and the second data bit corresponded to a transition between logic levels or data content. For example, where the first data bit and the second data bit are both logic 0 or are both logic 1, the transition between the first data bit and the second data bit is not a transition between logic levels. The process proceeds to a fourth step 560 when there is no transition between logic levels. Where the first data bit is a logic 0 and the second data bit is a logic 1, there is a transition between logic levels. Similarly, where the first data bit is a logic 1 and the second data bit is a logic 0, there is also a transition between logic levels. The process proceeds to a second decision block 562 when there is a transition between logic levels.

In the fourth step 560, the process discards the result of the integration. When there is no logic level transition associated with the transition in data bits, there is no transition timing information to be recovered from the result of the integration. In one embodiment, the process discards the result of the integration by a multiplication by zero operation. The process advances from the fourth step 560 to a sixth step 564.

In the second decision block 562, the process evaluates the transition between logic levels to determine whether the transition was from a logic 0 to a logic 1, or whether the transition was from a logic 1 to a logic 0. The process detects the location or the time of the transition within the integration window by correlating the integration value and a direction of the transition to the position of the transition. For example, where the transition is from a logic 0 to a logic 1 and the transition occurs relatively late in the integration period, the results of the integration reflect the relatively late transition by integrating the logic 0 state for a longer period of time than integrating the logic 1 state. In one embodiment of the process, only one of the states, logic 0 or logic 1, is integrated. Nevertheless, the results of the integration reflect a duty cycle variation between the transition logic states that is correlated to a position of the transition. The process proceeds from the second decision block 562 to a sixth step 564 when the logic states for the first data bit to second data bit transition correspond to logic 0 and to logic 1, respectively. The process proceeds from the second decision block 562 to a fifth step 566 when the logic states for the first data bit to second data bit transition correspond to logic 1 and to logic 0, respectively.

In the fifth step 566, the process multiplies the result of the integration by negative one to compensate for the difference in direction between a logic 0 to logic 1 transition and a logic 1 to logic 0 transition. The multiplication by negative one inverts the result of the integration for the logic 1 to logic 0 transition. Without a multiplication step, an integration of a logic 0 to logic 1 transition would be cancelled by an integration of a logic 1 to a logic 0 transition. It will be understood by one of ordinary skill in the art that either of the logic 0 to logic 1 transition integration result and the logic 1 to logic 0 transition result can be inverted with respect to the other to detect the phase difference. In addition, in another embodiment, only one of the logic 0 to logic 1 transition integration or the logic 1 to logic 0 integration is used, with the other discarded in the manner described in the fourth step 560.

In the sixth step 564, the process dumps the results of the integration. In the sixth step 564, the integration is also reset to prepare for the next integration period associated with the process. The dumping of the integration can be combined with the resetting of the integration result or the dumping can be performed in a separate step prior to the resetting of the integration result. The integration result can be stored in a storage device such as a capacitor, which is reset by either charging or discharging. The process advances from the sixth step 564 to a seventh step 568.

In the seventh step 568, the process combines multiple integrations to provide the phase detection. In one embodiment, the process integrates multiple transitions of the serial data in parallel, and the process combines the integration results to detect the phase difference.

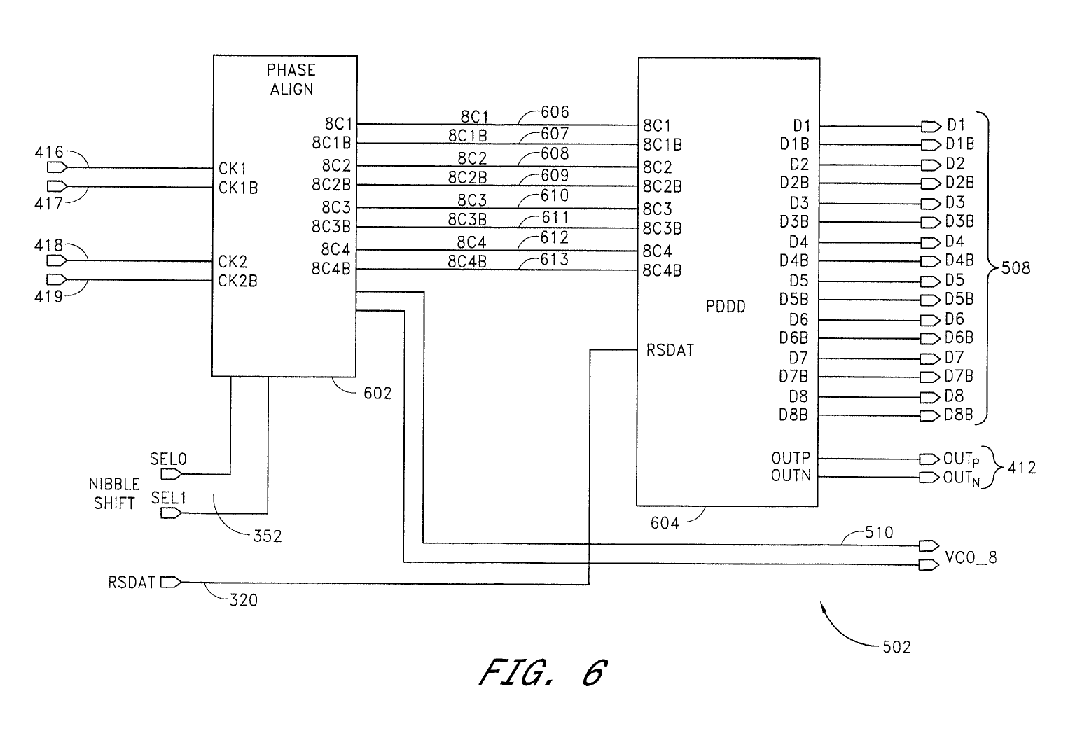

FIG. 5B illustrates one embodiment of the phase detector circuit 402. The phase detector circuit 402 includes a phase demultiplexer circuit 502, a data align circuit 504, and a buffer circuit 506. The phase demultiplexer circuit 502 receives the serial data 320 (RSDAT), the VCO output signals 416, 417, 418, 419, and the nibble shift signal 352 as inputs. The phase demultiplexer circuit 502 demultiplexes the serial data 320 to a first parallel data 508. The phase demultiplexer circuit 502 also generates the first error signal 412 and a data align clock signal 510 (VCO_{—}8). In one embodiment, the data align clock signal 510 is approximately one-half the frequency of one of the VCO output signals 416, 417, 418, 419 or one-eighth the frequency of the combined VCO output signals 416, 417, 418, 419. Further details of one embodiment of the phase demultiplexer circuit 502 are described later in connection with FIG. 6.

The data align circuit 504 receives the first parallel data 508 and synchronizes the data with a data align clock signal 510 to a second parallel data 512. The data align circuit 504 also divides the data align clock signal 510 by two to generate a pre-buffered receiver clock signal 514.

The buffer circuit 506 receives the second parallel data 512 and the pre-buffered receiver clock signal 514 from the receiver clock signal 514. The second parallel data 512 is buffered to the partially demultiplexed data 324, and the pre-buffered receiver clock signal 514 is buffered to the receiver clock signal 326 (VCO_{—}16).

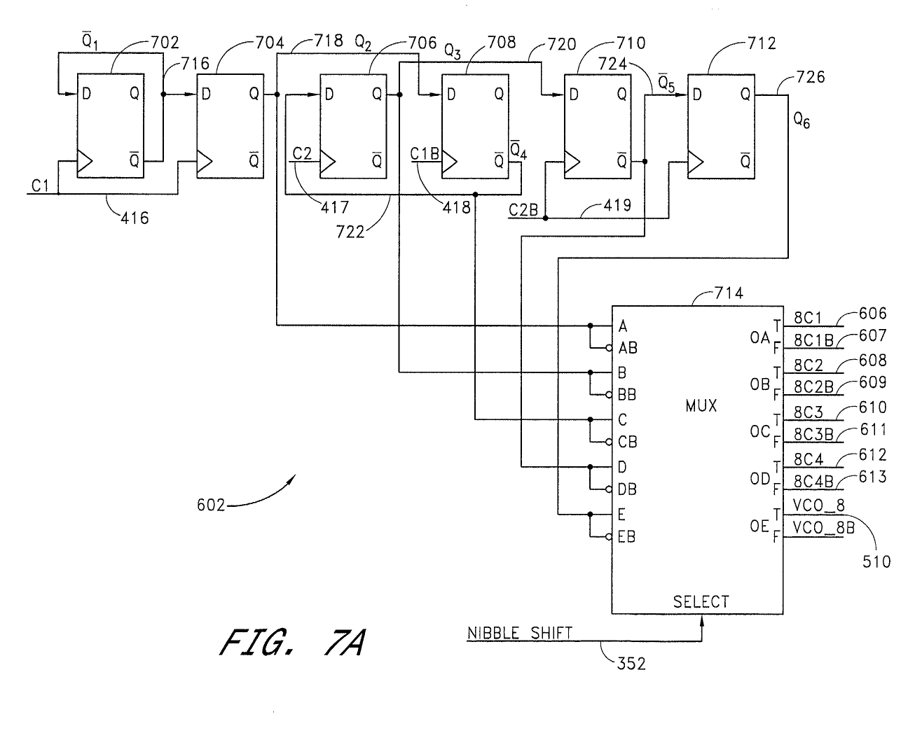

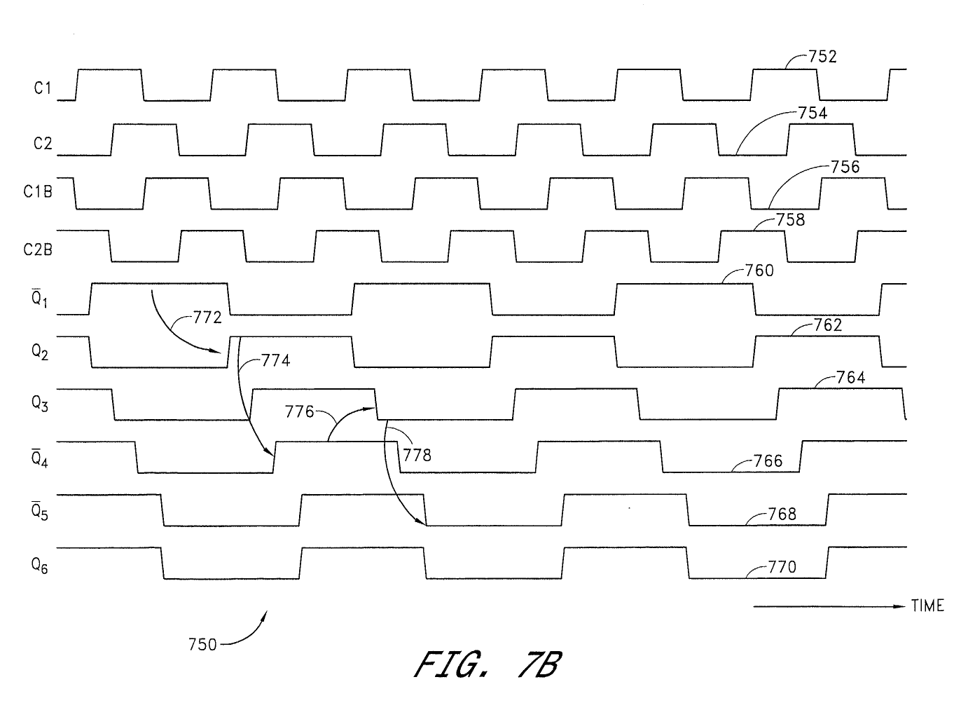

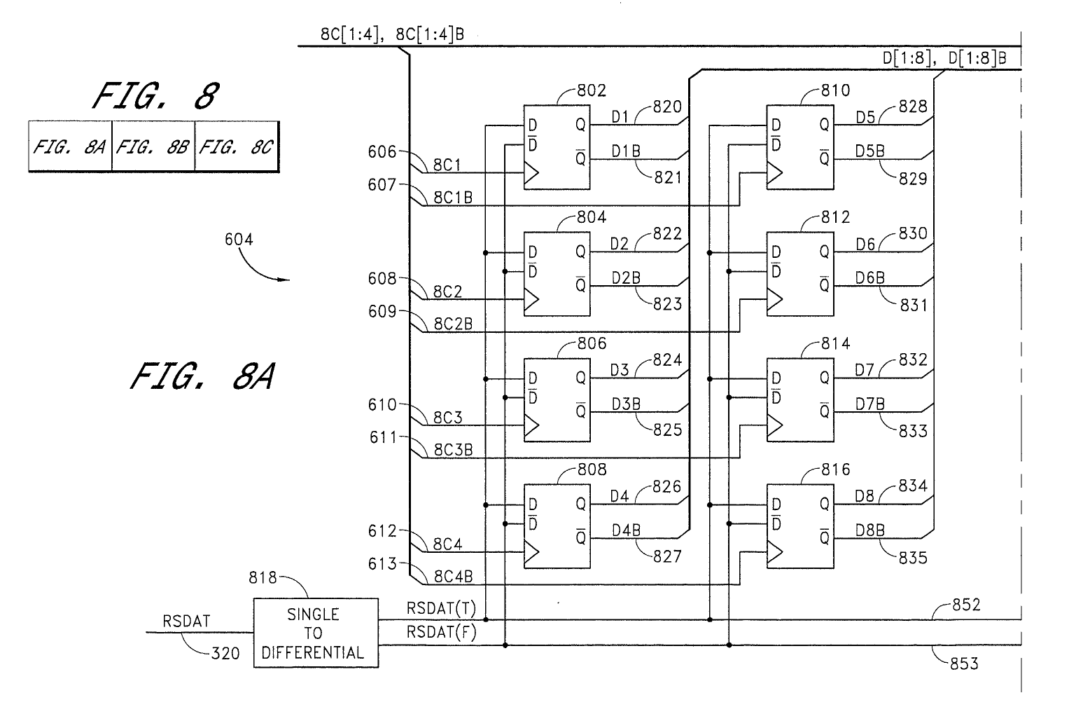

FIG. 6 illustrates one embodiment of the phase demultiplexer circuit 502. The illustrated phase demultiplexer circuit 502 includes a phase alignment circuit 602 and a phase detector and data demultiplexer circuit (PDDD) 604. The phase alignment circuit 602 further subdivides the four-phase VCO output signals 416, 417, 418, 419 to a set of eight-phase clock signals 606, 607, 608, 609, 610, 611, 612, 613 and generates the data align clock 510 signal from the VCO output signals 416, 417, 418, 419. The phase alignment circuit 602 also receives the nibble shift signal 352 and shifts the relative phases of the eight-phase clock signals 606, 607, 608, 609, 610, 611, 612, 613 and the data align clock 510 by a time period corresponding to a nibble or four data bits in response to a state of the nibble shift signal 352. In one embodiment, the phase shift corresponding to a nibble is 180 degrees. The phase demultiplexer circuit 502 is described in greater detail later in connection with FIG. 7A.

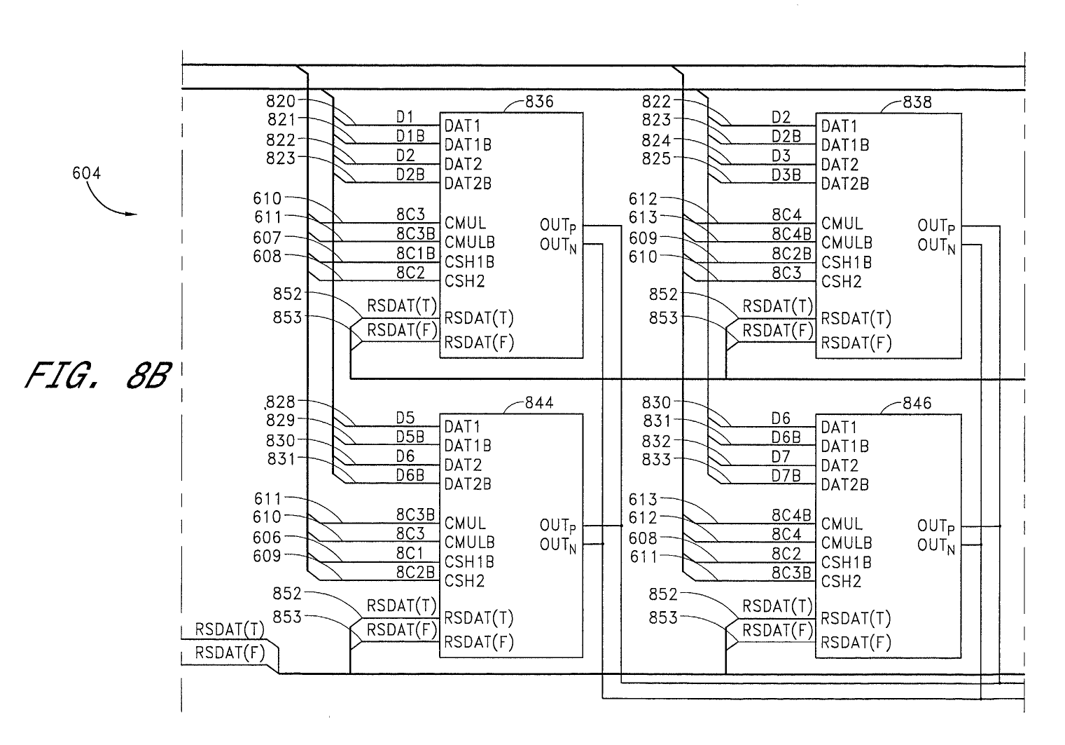

The phase detector and data demultiplexer circuit 604 receives the eight-phase clock signals 606, 607, 608, 609, 610, 611, 612, 613 and the serial data 320 (RSDAT) as inputs and generates the first parallel data 508. Further details of the phase detector and data demultiplexer circuit 604 are described later in connection with FIG. 8.

FIG. 7A illustrates one embodiment of the phase alignment circuit 602. The illustrated phase alignment circuit 602 includes a first D-type flip-flop 702, a second D-type flip-flop 704, a third D-type flip-flop 706, a fourth D-type flip-flop 708, fifth D-type flip-flop 710, a sixth D-type flip-flop 712, and a multiplexer 714. In FIG. 7A, the four-phase VCO output signals 416, 417, 418, 419 corresponding to approximately 0 degrees, 90 degrees, 180 degrees, and 270 degrees of relative phase shift are indicated by C1, C2, C1B, and C2B, respectively. Although the various signals 716, 718, 720, 722, 724, 726 are drawn as single ended, it will be understood by one of ordinary skill in the art that such signals can be differential as well.

The first D-type flip-flop 702 is configured as a toggle flip-flop and divides the clock signal C1 416 by two. The output \overline{Q}₁ 716 of the first D-type flip-flop 702 is applied as an input to the second D-type flip-flop 704. The second D-type flip-flop 704 is triggered by clock signal C2 416. The output Q₂ 718 of the second D-type flip-flop 704 is applied as an input to the fourth D-type flip-flop 708. The fourth D-type flip-flop 708 is triggered by the clock signal C1B 418. The inverted output \overline{Q}₄ 722 of the fourth D-type flip-flop 708 is applied as an input to the third D-type flip-flop 706. The third D-type flip-flop 706 is triggered by the clock signal C2 417. The output Q₃ 720 of the third D-type flip-flop 706 is applied as an input to the fifth D-type flip-flop 710, which is triggered by the clock signal C2B 419. One embodiment of the phase alignment circuit 602 optionally includes the fifth flip-flop 712, whose input is coupled to the inverted output \overline{Q}₅ 724 of the fifth D-type flip-flop 710.

Advantageously, the first D-type flip-flop 702 divides the C1 VCO output signal 416 and the second D-type flip-flop 704 drives the fourth D-type flip-flop 708 and the multiplexer 714, thereby allowing the loads driven by the second D-type flip-flop 704, the third D-type flip-flop 706, the fourth D-type flip-flop 708, and the fifth D-type flip-flop to be approximately balanced. The balanced loading of the phase generating flip-flops allows the flip-flops to generate the phases with reduced phase variance in comparison to phases generated with unbalanced loading of flip-flops.

The sixth D-type flip-flop 712 further advantageously loads the output of the fifth flip-flop 710 such that the loads imposed upon the second to the fifth D-type flip-flops 704, 706, 708, 710 are substantially the same. In addition, the output 726 of the fifth D-type flip-flop 712 is used to generate the data align clock signal 510.

Four of the eight relative phases generated by the second D-type flip-flop 704, the third D-type flip-flop 706, the fourth D-type flip-flop 708, and the fifth D-type flip-flop 710 are illustrated in FIG. 7B as Q₂ 718, Q₃ 720, \overline{Q}₄ 722, and \overline{Q}₅724. These four phases correspond to relative phases 0 degrees, 45 degrees, 90 degrees, and 135 degrees, respectively. The remaining four relative phases of 180 degrees, 225 degrees, 270 degrees, and 315 degrees are available at the inverted phase outputs of the D-type flip-flops (Q for \overline{Q} and \overline{Q} for Q), or by swapping the in-phase (Q) and out-of-phase outputs (\overline{Q}) where the phase alignment circuit 602 is implemented differentially. For reference, the VCO output signals C1 416, C2 417, C1B 418, and C2B 419 provided as inputs to the second D-type flip-flop 704, the third D-type flip-flop 706, the fourth D-type flip-flop 708, and the fifth D-type flip-flop 710, correspond to relative phases of 0 degrees, 90 degrees, 180 degrees, and 270 degrees.

The eight phases are applied as inputs to the multiplexer 714, which generates the eight-phase clock signals 606, 607, 608, 609, 610, 611, 612, 613. The eight phases of the eight-phase clock signals are approximately evenly spread over 360 degrees and are denoted herein as a first phase 8C1 606, a second phase 8C2 608, a third phase 8C3 610, a fourth phase 8C4 612, a fifth phase 8C1B 607, a sixth phase 8C2B 609, a seventh phase 8C3B 611, and an eighth phase 8C4B 613. The fifth phase 8C1B 607, the sixth phase 8C2B 609, the seventh phase 8C3B 611, and the eighth phase 8C4B 613 are approximately 180-degrees out-of-phase with respect to the first phase 8C1 606, the second phase 8C2 608, the third phase 8C3 610, and the fourth phase 8C4 612, respectively.

For illustrative purposes, the four relative phases from the second to the fifth D-type flip-flops 704, 706, 708, 710 of 180 degrees, 225 degrees, 270 degrees, and 315 degrees are indicated by the inverting bubble applied to inputs AB, BB, CB, and DB of the multiplexer 714. In response to a state of the nibble shift signal 352, the multiplexer 714 shifts the relative phase of the eight-phase clock signals 606, 607, 608, 609, 610, 611, 612, 613 by about 180 degrees by swapping the selection of the in-phase (0-degree) and the out-of-phase (180-degree) components of the eight-phase clocks. For example, in a first state of the nibble shift signal 352, the 8C1 606, 8C1B 607, 8C2 608, 8C2B 609, 8C3 610, 8C3B 611, 8C4 612, and 8C4B 613 eight-phase clock signals correspond to the relative phases of 0 degrees, 180 degrees, 45 degrees, 225 degrees, 90 degrees, 270 degrees, 135 degrees and 315 degrees, respectively. In a second state of the nibble shift signal 352, the 8C1 606, 8C1B 607, 8C2 608, 8C2B 609, 8C3 610, 8C3B 611, 8C4 612, and 8C4B 613 eight-phase clock signals correspond to the 180 degrees, 0 degrees, 225 degrees, 45 degrees, 270 degrees, 90 degrees, 315 degrees, and 135 degrees, respectively.

FIG. 7B is a timing diagram 750 of the phase alignment circuit 602 and further illustrates the operation of the phase alignment circuit 602. A first waveform 752, a second waveform 754, a third waveform 756, and a fourth waveform 758 correspond to the VCO output signals 416, 417, 418, 419 as indicated by C1, C2, C1B, and C2B, respectively.

A fifth waveform 760 corresponds to output \overline{Q}₁ 716 of the first D-type flip-flop 702. The fifth waveform 760 illustrates that the output \overline{Q}₁ 716 of the first D-type flip-flop 702 toggles at half the rate of the C1 VCO output signal 416.

A sixth waveform 762 corresponds to the output Q₂ 718 of the second D-type flip-flop 704. A seventh waveform 764 corresponds to the output Q₃ 720 of the third D-type flip-flop 706. An eighth waveform 766 corresponds to the output \overline{Q}₄ 722 of the fourth D-type flip-flop 708. A ninth waveform 768 corresponds to the output \overline{Q}₅ 724 of the fifth D-type flip-flop 710. The sixth waveform 762, the seventh waveform 764, the eighth waveform 766, and the ninth waveform 768 illustrate four of the eight phases generated by the second D-type flip-flop 704, the third D-type flip-flop 706, the fourth D-type flip-flop 708, and the fifth D-type flip-flop 710 as Q₂ 718, Q₃ 720, \overline{Q}₄ 722, and \overline{Q}₅ 724, respectively, that are described in connection with FIG. 7A and are applied as inputs to the multiplexer 714. The four phases correspond approximately to 0 degrees, 45 degrees, 90 degrees, and 135 degrees of relative phase shift.

In the illustrated embodiment, the second D-type flip-flop 704 triggers on the rising edge of the C1 VCO output signal 416 and latches the previous state of the output \overline{Q}₁ 716 of the first D-type flip-flop 702 as shown by a first arrow 772.

The fourth D-type flip-flop 708 triggers on the rising edge of the C1B VCO output signal 418 and latches the previous state of the output Q₂ 718 of the second D-type flip-flop 704 as shown by the second arrow 774. It will be understood by one of ordinary skill in the art that the rising edge of the C1B VCO output signal 418 and the rising edge of the C2B VCO output signal 419 can correspond to the falling edge of the C1 VCO output signal 416 and to the falling edge of the C1 VCO output signal 417, respectively, i.e., a change in polarity.

The third D-type flip-flop 706 triggers on the rising edge of the C2 VCO output signal 417 and latches the previous state of the output \overline{Q}₄ 722 of the fourth D-type flip-flop 708 as shown by the third arrow 776. The fifth D-type flip-flop 710 triggers on the rising edge of the C2B VCO output signal 418 and latches the previous state of the output Q₃ 720 of the third D-type flip-flop 706 as shown by the fourth arrow 778.

A tenth waveform 770 corresponds to the output Q₆ 726 of the sixth D-type flip-flop 712. The output Q₆ 726 of the sixth D-type flip-flop 712 is applied to the multiplexer 714 and is used to generate the data align clock signal 510.

FIG. 8 illustrates one embodiment of the phase detector and data demultiplexer circuit 604. The illustrated phase detector and data demultiplexer circuit 604 includes a plurality of D-type flip-flops 802, 804, 806, 808, 810, 812, 814, 816 to demultiplex the serial data and a plurality of digital multiplier circuits 836, 838, 840, 842, 844, 846, 848, 850 to generate the first error signal 412.

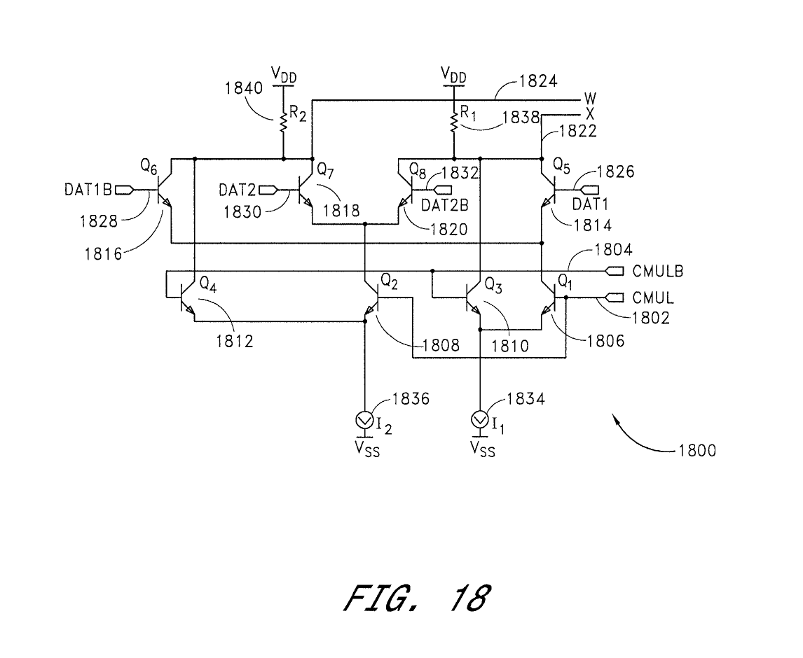

In one embodiment, a single to differential circuit 818 converts the serial data 320 RSDAT from single-ended to differential. The differential serial data 852, 853, represented by RSDAT(T) and RSDAT(F), is applied as an input to the plurality of D-type flip-flops 802, 804, 806, 808, 810, 812, 814, 816 and to the plurality of digital multiplier circuits 836, 838, 840, 842, 844, 846, 848, 850. One embodiment of the single to differential circuit 818 is described in greater detail later in connection with FIG. 19. Of course, the illustrated architecture can also be implemented in a single-ended system.

The plurality of D-type flip-flops 802, 804, 806, 808, 810, 812, 814, 816 demultiplex the differential serial data 852, 853 to the parallel data 508. A first D-type flip-flop 802 extracts a first data bit D1 820 and a complement to the first data bit D1B 821 from the serial data 820 by sampling the differential serial data 852, 853 at the rising edge of the first phase 8C1 606 of the eight-phase clock signals. The first data bit D1 820 and the complement to the first data bit D1B 821 are available at the in-phase (Q) and out of phase (\overline{Q}) outputs of the first D-type flip-flop 802. Of course, the first D-type flip-flop 802 can also sample the differential serial data 852, 853 at the falling edge of the fifth phase 8C1B 607, which occurs at approximately the same time as the rising edge of the first phase 8C1 606. For the purposes of illustration, the D-type flip-flops 802, 804, 806, 808, 810, 812, 814, 816 have been shown in FIG. 8 with a single-ended trigger. However, in one embodiment, the D-type flip-flops 802, 804, 806, 808, 810, 812, 814, 816 include differential clock trigger inputs so that the first D-type flip-flop 802 triggers on the rising edge of the difference between the first phase 8C1 606 and the fifth phase 8C1B 607.

Similarly, a second D-type flip-flop 804, a third D-type flip-flop 806, a fourth D-type flip-flop 808, a fifth D-type flip-flop 810, a sixth D-type flip-flop 812, a seventh D-type flip-flop 814, and an eighth D-type flip-flop 816 sample the differential serial data 852, 853 at a rising edge of the second phase 8C2 608, the third phase 8C3 610, the fourth phase 8C4 612, the fifth phase 8C1B 607, the sixth phase 8C2B 609, the seventh phase 8C3B 611, and the eighth phase 8C4B 613, respectively.

The second D-type flip-flop 804, the third D-type flip-flop 806, the fourth D-type flip-flop 808, the fifth D-type flip-flop 810, the sixth D-type flip-flop 812, the seventh D-type flip-flop 814, and the eighth D-type flip-flop 816 provide the second data bit D2 822, the third data bit D3 824, the fourth data bit D4 826, the fifth data bit D5 828, the sixth data bit D6 830, the seventh data bit D7 832, and the eighth data bit D8 834, respectively, as well as the complements of the respective data bits, 823, 825, 827, 829, 831, 833, 835.

The data bits 820, 821, 822, 823, 824, 825, 826, 827, 828, 829, 830, 831, 832, 833, 834, 835 are applied as inputs to the plurality of digital multiplier circuits 836, 838, 840, 842, 844, 846, 848, 850. The digital multiplier circuits integrate sample periods of the serial data 320 or differential serial data 852, 853, multiply the integration results with a variable or a weight related to the change in the serial data, and sum the multiplied integration results to generate the first error signal 412. The weight, or multiplier, is applied to the integrated sample, or the multiplicand, to allow the phase detector and data demultiplexer circuit 604 to combine multiple samples of integration results from both logic 0 to logic 1 transitions and logic 1 to logic 0 transitions. The phase detector and data demultiplexer circuit 604 determines the relative position of a transition within an integration window by comparing an amount of charge depleted in a first state to a charge depleted in a second state. Where a transition occurs in the center of the integration window, the depleted charges are substantially equal. Where a transition occurs offset in the integration window, the charges deplete unequally, thereby allowing the relative location of the transition within the integration window to be detected.

In one embodiment, where the serial data 320 transitions within the integration window from a first bit with a first state to a second bit with a second state, the variable is computed in accordance with Table I.

TABLE I

| first state | second state | variable |
|---|---|---|
| 0 | 0 | 0 |
| 0 | 1 | 1 |
| 1 | 0 | −1 |
| 1 | 1 | 0 |

In another embodiment, the value of the variable shown in Table I is −1 for the transition from 0 to 1 and is +1 for the transition from 1 to 0. It will be understood by one of ordinary skill in the art that a multiplication by negative one (−1) can be accomplished for a differential signal by interchanging the polarity, i.e., reversing the positive and the negative portions of the differential signal, and that no additional step or circuit is required to perform a multiplication by positive one.

The illustrated phase detector and data demultiplexer circuit 604 uses a digital multiplier circuit for each bit in a byte of data. The number of digital multipliers in a phase detector and data demultiplexer circuit can vary broadly. In another embodiment, a phase detector and data demultiplexer circuit uses a digital multiplier circuit for each bit in a nibble of data.

A first digital multiplier circuit 836 integrates a first portion of the serial data bitstream that includes a transition from a first bit portion and a second bit portion of the serial data bitstream. The first digital multiplier circuit 836 evaluates the change in state from the corresponding first data bit D1 820 to the second data bit D2 822, and applies the appropriate variable to the integrated value.

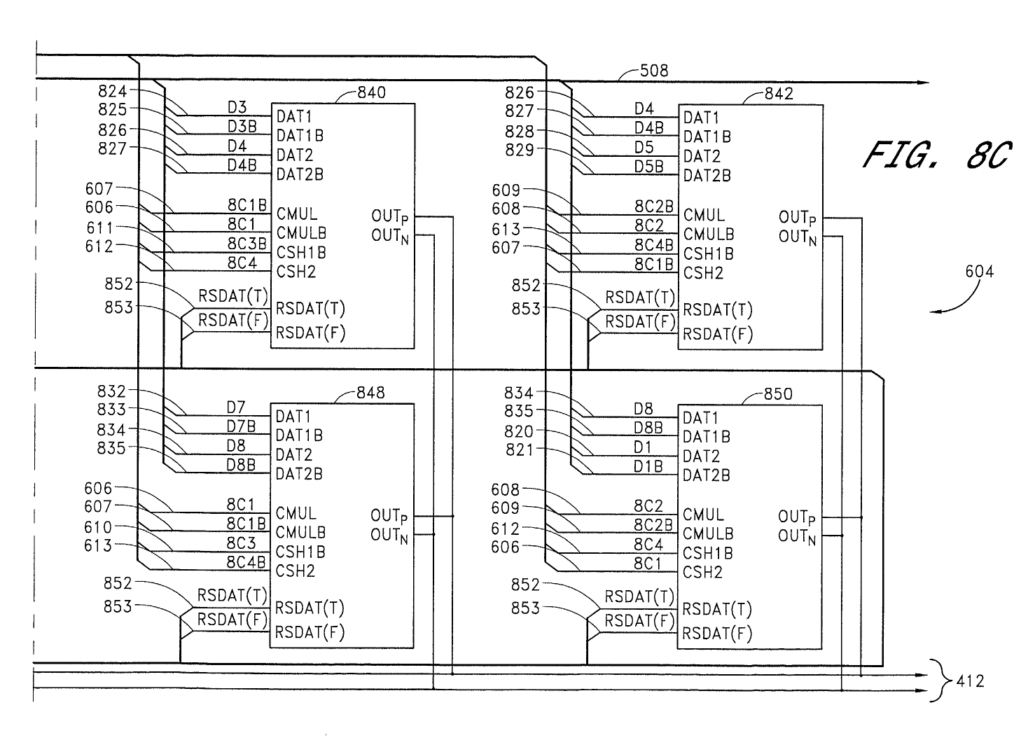

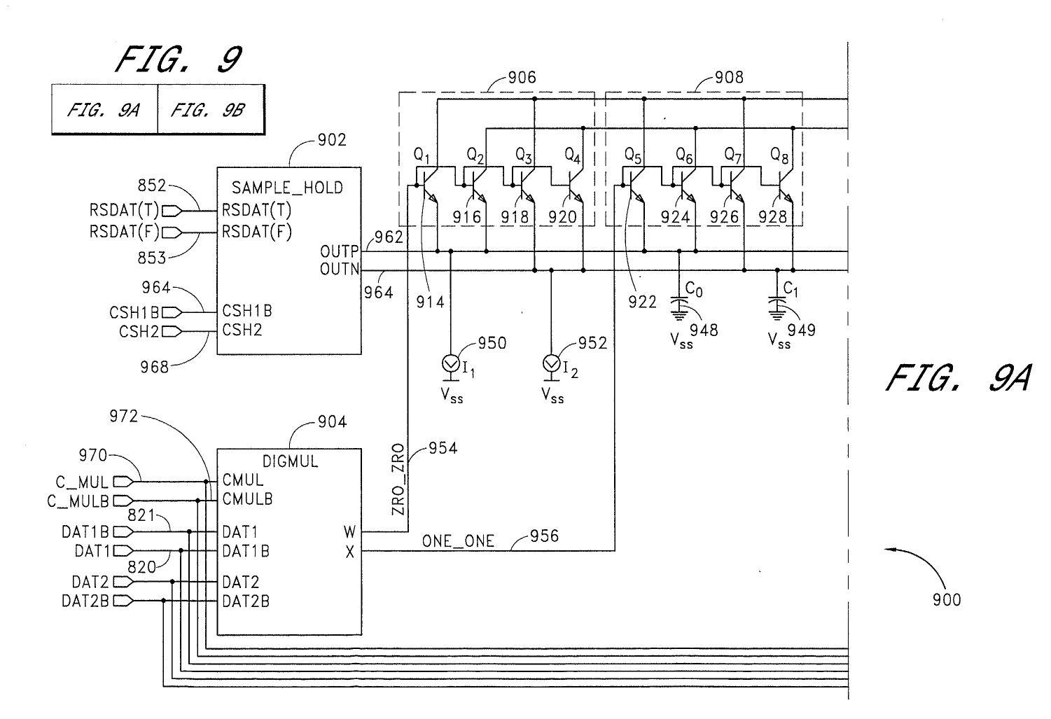

Inputs labeled CSH1B and CSH2 on a digital multiplier circuit accept timing signals that indicate the beginning and the end of the integration period. In one embodiment of a digital multiplier circuit, the integration period is the logical NOR of the inputs labeled CSH1B and CSH2. For the first digital multiplier circuit 836, the inputs labeled CSH1B and CSH2 correspond to the fifth phase 8C1B 607 and the second phase 8C2 608, respectively. Preferably, the eight-phase clock signals 606, 607, 608, 609, 610, 611, 612, 613 transition approximately in the center of the valid data portion of their respective data bits in the bitstream of the serial data 320 (RSDAT) or the differential serial data 852, 853. As will be described in greater detail later in connection with FIG. 9, the digital multiplier circuit advantageously integrates the serial data 320 or the differential serial data 852, 853 over a relatively fixed and relatively long period, i.e., approximately a 1-bit period of the serial data 320. By contrast, conventional circuits sample the transition of the data period with relatively narrow pulse widths, which are problematic at relatively high frequencies. In addition, the relatively narrow pulse widths of conventional circuits become progressively narrower the closer the phase is matched between the VCO output signals 416, 417, 418, 419 and embedded clock in the serial data 320.

Inputs labeled CMUL and CMULB on a digital multiplier circuit accept a timing signal to initiate the detection of transition in the state of the data bit and to compute the weight or value of the variable to be applied to the integrated sample. In the illustrated embodiment of the phase detector and data demultiplexer circuit 604, the first D-type flip-flop 802 and the second D-type flip-flop 804 provide the first data bit D1 820 and the second data bit D2 822, respectively. The first D-type flip-flop 802 activates in response to the rising edge of the first phase 8C1 606, and the first data bit D1 820 is available relatively shortly thereafter. The second D-type flip-flop 804 activates in response to the rising edge of the second phase 8C2 608, and the second data bit D2 822 is available relatively shortly thereafter. The first digital multiplier circuit 836 activates the transition-detecting portion of the multiplier circuit after the second data bit D2 822 is available. In the illustrated embodiment, the first digital multiplier circuit 836 is activated at the rising edge of the third phase 8C3 610. However, it will be understood by one of ordinary skill in the art that a later phase, such as the fourth phase 8C4 612 can also be used.

One embodiment of the digital multiplier circuit integrates the portion of the serial data bitstream as depleted charge in at least one capacitor and applies the appropriate variable upon retrieving the depleted charge and then combines the depleted charge by applying the depleted charge to a network of other digital multiplier circuits. Further details of a digital multiplier circuit are described later in connection with FIG. 9.

The second digital multiplier circuit 838 similarly integrates a second portion of the serial data bitstream that includes a transition from the second bit portion and a third bit portion of the serial data bitstream. The second digital multiplier circuit 838 evaluates the change in state from the corresponding second data bit D2 822 to the third data bit D3 824, and applies the appropriate variable or weight to the integrated value.

The third digital multiplier circuit 840 similarly integrates a third portion of the serial data bitstream that includes a transition from the third bit portion and a fourth bit portion of the serial data bitstream. The third digital multiplier circuit 840 evaluates the change in state from the corresponding third data bit D3 824 to the fourth data bit D4 826, and applies the appropriate variable or weight to the integrated value.

The fourth digital multiplier circuit 842 similarly integrates a fourth portion of the serial data bitstream that includes a transition from the fourth bit portion and a fifth bit portion of the serial data bitstream. The fourth digital multiplier circuit 842 evaluates the change in state from the corresponding fourth data bit D4 826 to the fifth data bit D5 828, and applies the appropriate variable or weight to the integrated value.

The fifth digital multiplier circuit 844 similarly integrates a fifth portion of the serial data bitstream that includes a transition from the fifth bit portion and a sixth bit portion of the serial data bitstream. The fifth digital multiplier circuit 844 evaluates the change in state from the corresponding fifth data bit D5 828 to the sixth data bit D6 830, and applies the appropriate variable or weight to the integrated value.

The sixth digital multiplier circuit 846 similarly integrates a sixth portion of the serial data bitstream that includes a transition from the sixth bit portion and a seventh bit portion of the serial data bitstream. The sixth digital multiplier circuit 846 evaluates the change in state from the corresponding sixth data bit D6 830 to the seventh data bit D7 832, and applies the appropriate variable or weight to the integrated value.

The seventh digital multiplier circuit 848 similarly integrates a seventh portion of the serial data bitstream that includes a transition from the seventh bit portion and an eighth bit portion of the serial data bitstream. The seventh digital multiplier circuit 848 evaluates the change in state from the corresponding seventh data bit D7 832 to the eighth data bit D8 834, and applies the appropriate variable or weight to the integrated value.

The eighth digital multiplier circuit 850 similarly integrates an eighth portion of the serial data bitstream that includes a transition from the eighth bit portion and a first bit portion of the next byte of the serial data bitstream. The eighth digital multiplier circuit 850 evaluates the change in state from the corresponding eighth data bit D8 834 to the first data bit D1 820, and applies the appropriate variable or weight to the integrated value.

Table II illustrates an exemplary timing configuration for the phase detector and data demultiplexer circuit 604.

TABLE II

| Digital | | | Digital Multiplier | Sample/Hold |
|---|---|---|---|---|
| Multiplier | Reference | Comparison | Clock | Clock |
| first | 836 | D1 to D2 | C3 or later | C1B, C2 |
| second | 838 | D2 to D3 | C4 or later | C2B, C3 |
| third | 840 | D3 to D4 | C1B or later | C3B, C4 |
| fourth | 842 | D4 to D5 | C2B or later | C4B, C1B |
| fifth | 844 | D5 to D6 | C3B or later | C1, C2B |
| sixth | 846 | D6 to D7 | C4B or later | C2, C3B |
| seventh | 848 | D7 to D8 | C1 or later | C3, C4B |
| eighth | 850 | D8 to next D1 | C2 or later | C4, C1 |

FIG. 9 illustrates one embodiment of a digital multiplier circuit 900. The illustrated digital multiplier circuit 900 can be used as a digital multiplier circuit in the plurality of digital multiplier circuits 836, 838, 840, 842, 844, 846, 848, 850. The digital multiplier circuit 900 includes a sample and hold circuit 902, a first stage 904, 905 of a multiplier circuit, a second stage of the digital multiplier circuit 906, 908, 910, 912, and integration capacitors C₀ 948 and C₁ 949. In one embodiment of the digital multiplier circuit 900, the integration capacitors C₀ 948 and C₁ 949 are “reset” by receiving a constant current charge from the receiver loop filter circuit 404 upon a “dumping” of the integration by the second stage of the multiplier circuit 906, 908, 910, 912, i.e., a reset is a charged condition. In one example, the integration capacitors C₀ 948 and C₁ 949 are about 2 picofarads (pF). In another embodiment, the integration capacitors C₀ 948 and C₁ 949 are about 8 pF. One of ordinary skill in the art will realize that a relatively wide range of capacitance can be used. An alternate embodiment of an integration circuit and a multiplier circuit for a phase detector is also described later in connection with FIGS. 14, 15, and 16.

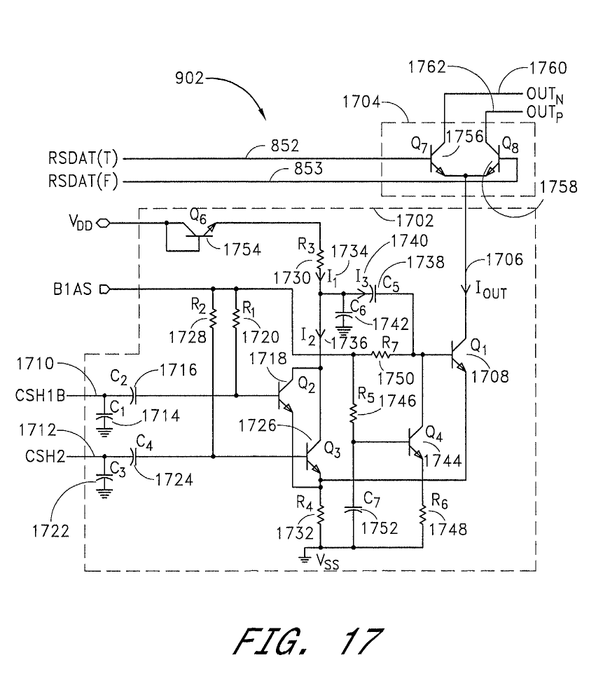

The sample and hold circuit 902 couples the differential serial data 852, 853 to the integration capacitors C₀ 948 and C₁ 949 in response to sample and hold control inputs CSH1B 964 and CSH2 968. One embodiment of the sample and hold circuit 902 couples the differential serial data 852, 853 to the integration capacitors C₀ 948 and C₁ 949 by switching a relatively constant current sink on and off in response to a time window defined by the sample and hold control inputs CSH1B 964 and CSH2 968 and in response to the state of the differential serial data 852, 853. It will be understood by one of ordinary skill in the art that the sourcing of current to and the sinking of the current from the integration capacitors C₀ 948 and C₁ 949 can be reversed. During the time window, a portion of the charge initially stored in the integration capacitors C₀ 948 and C₁ 949 is depleted by the current sinking of the sample and hold circuit 902. The amount of depletion of the stored charge represents the results of the integration of the transition. The sample and hold circuit 902 switches on a current sink coupled to the first integration capacitor C₀ 948 when the serial data 320 is at logic “1.” The sample and hold circuit 902 switches on a current sink coupled to the second integration capacitor C₁ 949 when the serial data 320 is at logic “0.” The proportion of the time that the serial data 320 was at logic “1” and at logic “0” is thereby stored as depleted charge across the first integration capacitor C₀ 948 and the second integration capacitor C1 949. Further details of the sample and hold circuit 902 are described later in connection with FIG. 17.

The more the integration capacitors C₀ 948 and C₁ 949 are discharged by the sample and hold circuit 902, the lower the corresponding voltage potential on the first error signal 412 when the integration capacitors C₀ 948 and C₁ 949 are coupled to the current source of the receiver loop filter circuit 404 by the second stage of the digital multiplier circuit 906, 908, 910, 912.

The depletion by the sample and hold circuit 902 of the charge stored in the integration capacitors C₀ 948 and C₁ 949 is selectively accumulated with other depleted charge from the remaining digital multiplier circuits to generate the first error signal 412, which is applied as an input to the receiver loop filter 404. In the illustrated embodiment, the first error signal 412 is a differential signal. The differential charge maintaining the integration values is coupled with other depleted charge by the second stage of the digital multiplier circuit 906, 908, 910, 912, which accumulates the depleted charge in current-mode by summing currents. In an alternative embodiment such as the integration circuit 1400 described in connection with FIG. 14, differential voltages of the integration values are combined. The formula expressed below indicates a differential voltage ΔV across a pair of integration capacitors C₀ 948 and C₁ 949 each with a capacitance of C, which have been depleted for a time period of t₀ and t₁, respectively by a switched constant current source after being evenly charged:

$$Δ V = \frac{I ( {t}_{0} - {t}_{1} )}{C}$$

The first stage of the multiplier circuit 904, 905 produces control signals 954, 956, 958, 960 that are used to activate a portion of the second stage 906, 908, 910, 912. The first stage 904, 905 detects whether adjacent bits in the serial data 320 corresponded to logic “0” and logic “0,” to logic “0” and logic “1,” to logic “1” and logic “0,” or to logic “1” and logic “1.” One embodiment of the first stage of the multiplier circuit is described later in connection with FIG. 18. The second stage of the multiplier circuit applies the variable to the depleted charge on the integration capacitors C₀ 948 and C₁ 949 to perform the multiplication operation. In an alternative embodiment, only one of the positive-going transition or the negative-going transition is integrated and the multiplier circuit is not needed.

Current sinks I₁ 950 and I₂ 952 bias second stage 906, 908, 910, 912 and the integration capacitors C₀ 948 and C₁ 949 by providing the integration capacitors with a trickle current sink. In one embodiment, the current sinks I₁ 950 and I₂ 952 are biased at about 25 microamps (μA).

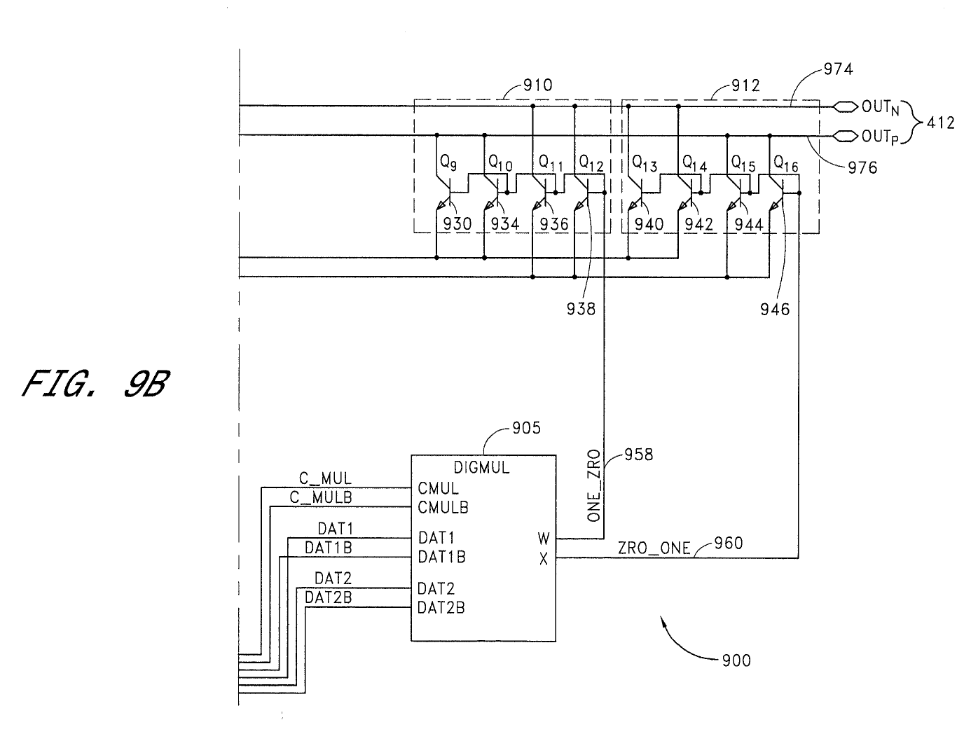

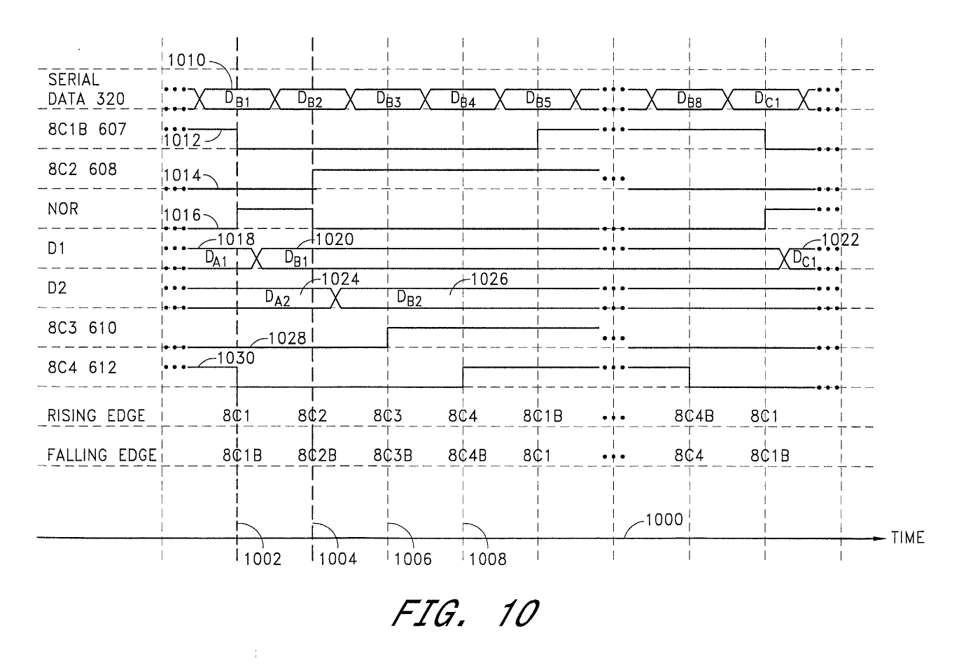

The first stage 904, 905 of the digital multiplier circuit 900 activates one of the zero-zero control signal 954, a one-one control signal 956, a one-zero control signal 958, and a zero-one control signal 960 in response to the activation by the digital multiplier clock. In the illustrated embodiment, the digital multiplier clock is a differential signal and is applied at inputs CMUL 970 and CMULB 972. In one embodiment, the signal selected to activate a digital multiplier circuit corresponds to a phase of the eight-phase clock signals 606, 607, 608, 609, 610, 611, 612, 613 that occurs one clock phase after the detection of the later of the two adjacent bits. Of course, a later clock phase may also be selected. FIGS. 10 through 14 further illustrate control signal timing.

The first stage 904, 905 selects the activation of the zero-zero control signal 954 when the adjacent bits in the serial data 320 correspond to logic “0” and logic “0.” Similarly, the first stage 904, 905 selects the activation of the one-one control signal 956, the one-zero control signal 958, and the zero-one control signal 960 when the adjacent bits in the serial data 320 correspond to logic “0” and logic “1,” logic “1” and logic “0,” and logic “1” and logic “1,” respectively. The plurality of D-type flip-flops 802, 804, 806, 808, 810, 812, 814, 816 detect the state of the bits of the serial data 320, and selected D-type flip-flops are coupled to the first stage 904, 905 of a digital multiplier circuit to allow the first stage to determine the state of the adjacent bits. For example, the first D-type flip-flop 802 and the second D-type flip-flop 804 are coupled to the first digital multiplier circuit 836 to allow the first digital multiplier circuit 836 to detect the logical state of the adjacent bits D1 820 and D2 822.

The zero-zero control signal 954 activates a first group 906 of transistors Q₁ 914, Q₂ 916, Q₃ 918, and Q₄ 920 from a portion of the second stage 906 of the digital multiplier circuit 900. The first group 906 of transistors 914, 916, 918, 920 is configured to effectively multiply the results of the integration stored in the integration capacitors C₀ 948 and C₁ 949 by zero (0) by coupling both of the integration capacitors C₀ 948 and C₁ 949 to both the non-inverting multiplier output 974 and the inverting multiplier output 976, and subsequently to the receiver loop filter circuit 404. Since both integration capacitors C₀ 948 and C₁ 949 are coupled to both the non-inverting multiplier output 974 and the inverting multiplier output 976, the difference in voltage between the non-inverting multiplier output 974 and the inverting multiplier output 976 for the integrated sample is zero and the digital multiplier circuit 900 has effectively multiplied the results of the integration by zero.

The coupling of the integration capacitors C₀ 948 and C₁ 949 to the receiver loop filter circuit 404 also recharges the integration capacitors C₀ 948 and C₁ 949 to reset and to prepare the integration capacitors C₀ 948 and C₁ 949 to integrate the next sample. The non-inverting multiplier output 974 and the inverting multiplier output 976 are combined with outputs of the other multiplier circuits to generate the first error signal 412.

When the data bits that are applied as inputs to the digital multiplier circuit 900 indicate that the serial data 320 for the integration window started at logic “1” and remained at logic “1,” the first stage 904, 905 activates the one-one control signal 956. The one-one control signal 956 activates a second group 908 of transistors Q₅ 922, Q_{6 924, Q}₇ 926, and Q₈ 928. The second group 908 of transistors Q₅ 922, Q₆ 924, Q₇ 926, and Q₈ 928 is also configured to effectively multiply the results of the integration stored in the integration capacitors C₀ 948 and C₁ 949 by zero by again coupling both of the integration capacitors C₀ 948 and C₁ 949 to both the non-inverting multiplier output 974 and the inverting multiplier output 976, and subsequently to the receiver loop filter circuit 404. It will be understood by one of ordinary skill in the art that a digital multiplier circuit 900 with the first group 906 of transistors 914, 916, 918, 920 and the second group 908 of transistors Q₅ 922, Q₆ 924, Q₇ 926, and Q₈ 928 corresponds to a “wired OR” configuration. Advantageously, the illustrated second stage of the digital multiplier circuit 906, 908, 910, 912 is load balanced and is symmetrical for matched delays. In another embodiment, the digital multiplier circuit 900 does not include the second group 908 of transistors Q₅ 922, Q₆ 924, Q₇ 926, and Q₈ 928, but rather, activates the first group 906 of transistors 914, 916, 918, 920 again in response to either activation of the one-one control signal 956 or activation of the zero-zero control signal 954. However, at relatively high frequencies, care must be taken to balance the loads and the timing of the control signals to the second stage of an alternative digital multiplier circuit.

When the data bits that are applied as inputs to the digital multiplier circuit 900 indicate that the serial data 320 for the integration window started at logic “1” and transitioned to logic “0,” the first stage 904, 905 activates the one-zero control signal 958. The one-zero control signal 958 activates a third group 910 of transistors Q₉ 930, Q₁₀ 934, Q₁₁ 936, and Q₁₂ 938. The third group 910 of transistors Q₉ 930, Q₁₀ 934, Q₁₁ 936, and Q₁₂ 938 is configured to effectively multiply the results of the integration stored in the integration capacitors C₀ 948 and C₁ 949 by negative 1 (-1) by coupling the first integration capacitor C₀ 948 and the second integration capacitor C₁ 949 to the inverting multiplier output 976 and to the non-inverting multiplier output 974, respectively, thereby inverting the polarity of the difference in voltage stored in the first integration capacitor C₀ 948 and the second integration capacitor C₁ 949. The receiver loop filter circuit 404 thus receives an inverted difference in voltage, where the voltage reflects the amount of integration of the serial data for a first state versus a second state within the integration window.

One embodiment of the digital multiplier circuit 900 uses approximately the same geometry transistors for the groups of transistors in the second stage 906, 908, 910, 912 to balance loads and to achieve matched timing. However, it will be understood by one of ordinary skill in the art that in another embodiment, transistors Q₉ 930 and Q₁₀ 934 can be combined to one transistor, and transistors Q₁₁ 936 and Q₁₂ 938 can also be combined to one transistor. Again, at relatively high frequencies, care must be taken to match loads and to match the switching timing within the second stage of the alternative digital multiplier circuit.

When the data bits that are applied as inputs to the digital multiplier circuit 900 indicate that the serial data 320 for the integration window started at logic “0” and transitioned to logic “1,” the first stage 904, 905 activates the zero-one control signal 960. The zero-one control signal 960 activates a fourth group 912 of transistors Q₁₃ 940, Q₁₄ 942, Q₁₅ 944, and Q₁₆ 946. The fourth group 912 of transistors Q₁₃ 940, Q₁₄ 942, Q₁₅ 944, and Q₁₆ 946 is configured to effectively multiply the results of the integration stored in the integration capacitors C₀ 948 and C₁ 949 by positive one (+1) by coupling the first integration capacitor C₀ 948 and the second integration capacitor C₁ 949 to the non-inverting multiplier output 974 and the inverting multiplier output 976, respectively, thereby maintaining the polarity of the difference in voltage stored in the first integration capacitor C₀ 948 and the second integration capacitor C₁ 949. The receiver loop filter circuit 404 thus receives an in-phase difference in voltage, where the voltage reflects the amount of integration of the serial data for a first state versus a second state within the integration window.

In one embodiment, the transistors in the fourth group 912 of transistors Q₁₃ 940, Q₁₄ 942, Q₁₅ 944, and Q₁₆ 946 are matched with the transistors in the third group 910 of transistors Q₉ 930, Q₁₀ 934, Q₁₁ 936, and Q₁₂ 938. Further, in an alternative embodiment, transistors Q₁₃ 940 and Q₁₄ 942 can be combined to one transistor and the transistors Q₁₅ 944, and Q₁₆ 946 can also be combined to one transistor.

In addition, it will be understood by one of ordinary skill in the art that in alternative embodiments, the configuration of the fourth group 912 of transistors Q₁₃ 940, Q₁₄ 942, Q₁₅ 944, and Q₁₆ 946 and the third group 910 of transistors Q₉ 930, Q₁₀ 934, Q₁₁ 936, and Q₁₂ 938 can be interchanged so that the fourth group 912 effectively multiplies by negative one (−1) and the third group 910 effectively multiplies by positive one (+1). The polarity of the phase detection can be inverted at another location in the circuit, such as in the receiver loop filter circuit 404.

FIG. 10 is a timing diagram of a portion of the phase detector and data demultiplexer circuit 604. FIGS. 11, 12, and 13 are timing diagrams that illustrate the integration of the transitions of the serial data 320.

With respect to FIG. 10, a horizontal axis 1000 indicates time. A first vertical line 1002 corresponds to a time with a rising edge of a first phase 8C1 606 of the eight-phase clock signals and also to a falling edge of a fifth phase 8C1B 607 of the eight-phase clock signals. A second vertical line 1004 corresponds to a time with a rising edge of a second phase 8C2 608 and to a falling edge of a sixth phase 8C2B 609. A third vertical line 1006 corresponds to a time with a rising edge of a third phase 8C3 610 and to a falling edge of a seventh phase 8C3B 611. A fourth vertical line 1008 corresponds to a time with a rising edge of a fourth phase 8C4 612 and to a falling edge of an eighth phase 8C4B 613, and so forth.

With reference to FIG. 10, a first waveform 1010 corresponds to the serial data 320. Data within the serial data 320 is carried one bit at a time. As illustrated in FIG. 10, the first waveform 1010 carries data bit 1 of byte “B” in a portion of the first waveform 1010 labeled D_{B1}, then carries data bit 2 of byte “B” in a portion of the first waveform 1010 labeled D_{B2}, and so forth. After carrying data bit 8 of byte “B” in a portion of the first waveform 1010 labeled D_{B8}, the serial data 320 carries data bit 1 of byte “C” in a portion of the first waveform 1010 labeled D_{C1}. Preferably, the multiple phases of the eight-phase clock signals 606, 607, 608, 609, 610, 611, 612, 613 are synchronized to transition approximately in the center of a data portion of the serial data 320 as opposed to near to or at a transition between data bits.

A second waveform 1012 corresponds to the fifth phase 8C1B 607 of the eight-phase clock signals. When the eight-phase clock signals are synchronized with the serial data 320, the fifth phase 8C1B 607 of the eight-phase clock signals transitions from high to low approximately in the center of the D_{B1} portion of the serial data 320 as indicated by the first vertical line 1002. A second waveform 1014 corresponds to a second phase 8C2 608 of the eight-phase clock signals. The second phase 8C2 608 transitions from low to high approximately in the center of the D_{B2} portion of the serial data 320 as indicated by the second vertical line 1004.

One embodiment of the phase detector and data demultiplexer circuit 604 performs an integration of the D_{B1} to D_{B2} transition of the serial data 320 in a window defined by a logical NOR of the fifth phase 8C1B 607 and the second phase 8C2 608 of the eight-phase clock signals. A fourth waveform 1016 illustrates the window defined by the logical NOR, which is active for the integration of the D_{B1} to D_{B2} transition as indicated by the time represented by the first vertical line 1002 to the time represented by the second vertical line 1004. Details of the integration of the transition are described later in connection with FIGS. 11, 12, and 13.

One embodiment of the phase detector and data demultiplexer circuit 604 uses the integrations of both positive-going transitions, e.g., logic “0” to logic “1” transitions, and negative-going transitions, e.g., logic “1” to logic “0” transitions. Where the integrations of both positive-going transitions and negative-going transitions are used, the integrations of positive-going transitions are combined with phase-inverted integrations of negative-going transitions, or vice-versa. This allows the phase detector portion of the phase detector and data demultiplexer circuit 604 to determine the relative position of a data transition between phases of the eight-phase clock signals 606, 607, 608, 609, 610, 611, 612, 613, which are derived from the VCO, and to thereby lock the VCO to recover the clock signal from the serial data 320.

A first portion 1018, a second portion 1020, and a third portion 1022 of a fifth waveform correspond to the first data bit D1 820 from the first D-type flip-flop 802. In the first portion 1018, the first data bit D1 820 maintains a data bit labeled D_{A1} demultiplexed from an earlier byte. At the time indicated by the first vertical line 1002, the first D-type flip-flop 802 latches the state of the serial data 320. Shortly thereafter, the data bit labeled D_{B1} is available at the output of the first D-type flip-flop 802 and is represented by the second portion 1020 of the fifth waveform. The first D-type flip-flop 802 continues to demultiplex the first bit from the serial data 320 as shown by the third portion 1022 of the fifth waveform.

A first portion 1024 and a second portion 1026 of a sixth waveform correspond to the second data bit D2 822 from the second D-type flip-flop 804. In the first portion 1024, the second data bit D2 822 maintains a data bit labeled D_{A2} demultiplexed from an earlier byte. At the time indicated by the second vertical line 1004, the second D-type flip-flop 804 latches the state of the serial data 320. Shortly thereafter, the data bit labeled D_{B2} is available at the output of the second D-type flip-flop 804 and is represented by the second portion 1026 of the sixth waveform.

When the adjacent data bits are ready to be read, the corresponding digital multiplier circuit can activate the first stage and the second stage to apply the results of the integration of the transition between adjacent bits to the receiver loop filter circuit 404. In the case of the transition between the first data bit represented by D_{B1} and the second data bit represented by D_{B2}, the data is ready to be read on the next phase of the eight-phase clock signal. In the illustrated embodiment, the first stage and the second stage of the first digital multiplier 826 are activated by the third phase 8C3 610, which is illustrated by a seventh waveform 1028. It will be understood by one of ordinary skill in the art however, that since the charge stored in the integration capacitors C₀ 948 and C₁ 949 persists and the data latched by the first and the second D-type flip-flops 802, 804 also persists, the first digital multiplier 826 can be activated on a later phase of the eight-phase clock, such as by the rising edge of the fourth phase 8C4 612 as shown by an eighth waveform 1030.

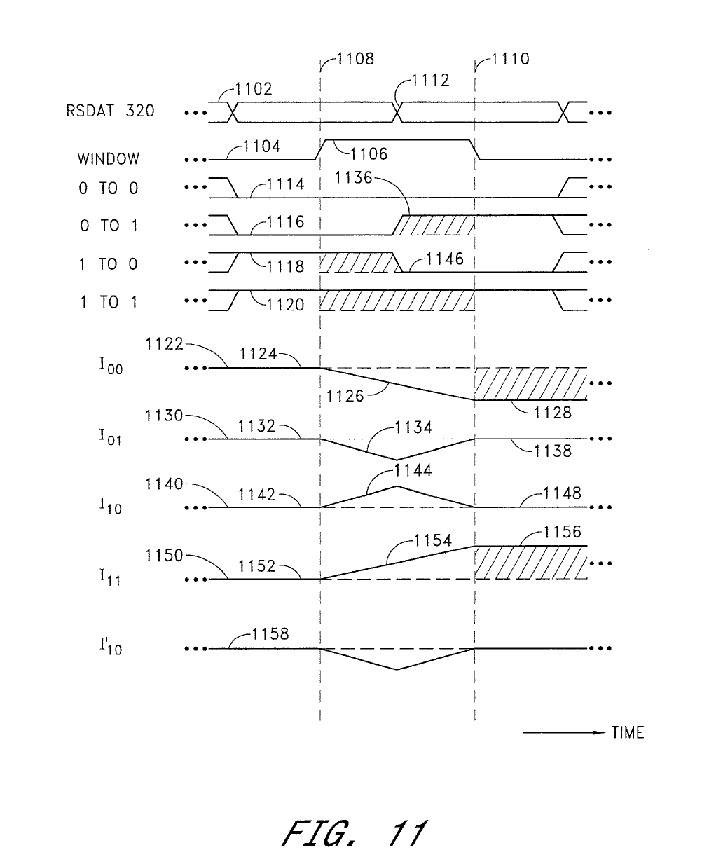

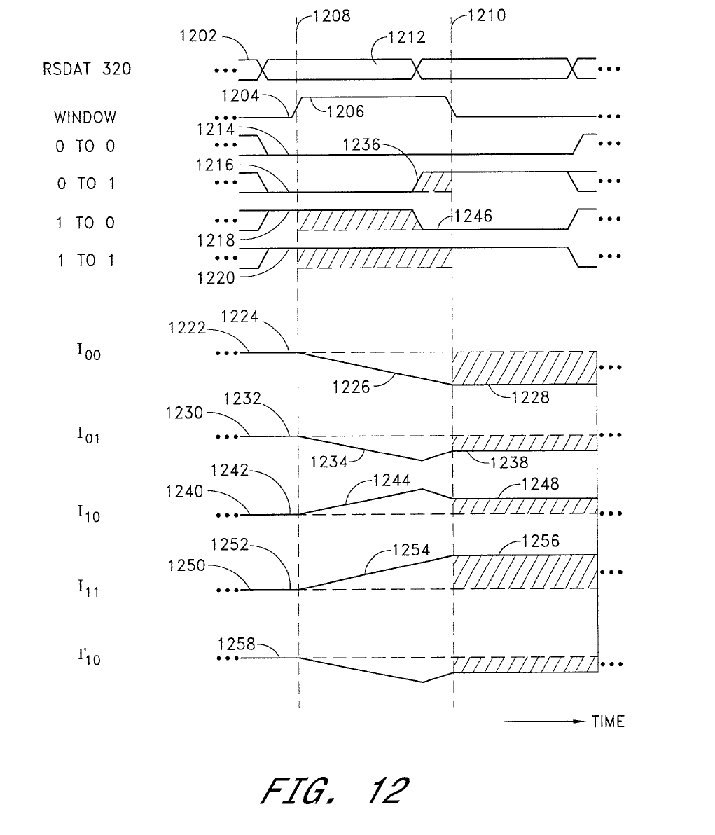

FIGS. 11, 12, and 13 illustrate integration by a digital multiplier circuit of a transition of the serial data 320. FIG. 11 illustrates integration by the digital multiplier circuit 900, where the serial data 320 and a clock signal generated from the VCO circuit 406 are relatively well matched or in relatively good lock. FIG. 12 illustrates integration by the digital multiplier circuit 900, where a clock signal generated from the VCO circuit 406 leads the serial data 320 by a relatively large amount. FIG. 13 illustrates integration by the digital multiplier circuit 900, where a clock signal generated from the VCO circuit 406 lags the serial data 320 by a relatively large amount.

With reference to FIG. 11, a first waveform 1102 corresponds to the serial data 320 (RSDAT). A second waveform 1104 illustrates an integration window when the serial data 320 is integrated by the integration capacitors C₀ 948 and C₁ 949. In one embodiment, the digital multiplier circuit 900 integrates the serial data upon the logical NOR of the inputs labeled CSH1B and CSH2 of the first stage 904, 905 of the multiplier circuit 900, as shown by an active portion 1106 of the second waveform 1104. A first vertical line 1108 and a second vertical line 1110 indicate a start time and a stop time, respectively, of the integration.

The timing of the active portion 1106 of the integration is selected to cover a transition 1112 of the serial data 320 between adjacent or consecutive data bits. Of course, the adjacent data bits can be the same value, such as both bits at logic “0” or logic “1,” in which case no actual “transition” of logic levels occurs. The adjacent data bits can correspond to one of four cases: logic “0” to logic “0,” logic “0” to logic “1,” logic “1” to logic “0,” and logic “1” to logic “1.”

A third waveform 1114 illustrates the case when the adjacent bits of the serial data 320 correspond to the logic “0” to logic “0” case during the integration period as shown by the active portion 1106 of the second waveform 1104. During the active portion 1106, the sample and hold circuit 902 couples the serial data 320 to the integration capacitors C₀ 948 and C₁ 949 by sinking current to reduce the charge previously stored in the integration capacitors C₀ 948 and C₁ 949 during a reset cycle. It will also be understood by one of ordinary skill in the art that the integrated serial data 320 can be either single-ended or differential.

A fourth waveform 1116 illustrates the case when the adjacent bits of the serial data 320 correspond to the logic “0” to logic “1” case during the integration period. A fifth waveform 1118 illustrates the case when the adjacent bits of the serial data 320 correspond to the logic “1” to logic “0” case during the integration period. A sixth waveform 1120 illustrates the case when the adjacent bits of the serial data 320 correspond to the logic “1” to logic “1” case during the integration period.

A seventh waveform 1122 illustrates the integration of differential serial data for the logic “0” to logic “0” case illustrated by the third waveform 1114. The seventh waveform 1122 corresponds to a voltage as measured from the first integration capacitor C₀ 948 to the second integration capacitor C₁ 949.

In a first portion 1124 of the seventh waveform 1122, the integration is reset by charging the integration capacitors C₀ 948 and C₁ 949 so that there is relatively little difference in the potential measured between the integration capacitors C₀ 948 and C₁ 949. The reset can occur anytime prior to the integration. In one embodiment, the dumping of the integration from the integration capacitors C₀ 948 and C₁ 949 to the receiver loop filter circuit 404 resets the integration by coupling the integration capacitors C₀ 948 and C₁ 949 to the current sources in the receiver loop filter circuit 404.

A second portion 1126 of the seventh waveform 1122 illustrates the integration of logic “0.” With integration of a differential signal at logic “0,” the integration gradually accumulates negatively as shown by the second portion 1126 of the seventh waveform 1122.

A third portion 1128 of the seventh waveform 1122 illustrates the result of the integration for the period. The result of the integration is available to be multiplied by the first and the second stages of the digital multiplier circuit 900. However, for the case of logic “0” to logic “0,” there is no logic level transition and therefore there is no information about a timing of a transition to be retrieved from the integration information stored by integration capacitors C₀ 948 and C₁ 949. In one embodiment, the result of the integration for the logic “0” to logic “0” case is multiplied by zero by the digital multiplier circuit 900.

An eighth waveform 1130 illustrates the integration of differential serial data for the logic “0” to logic “1” case illustrated by the fourth waveform 1116. In a first portion 1132 of the eighth waveform 1130, the integration is reset by charging the integration capacitors C₀ 948 and C₁ 949.

A second portion 1134 of the eighth waveform 1130 illustrates the integration of the logic “0” to logic “1” transition. When the serial data is at logic “0,” the integration accumulates negatively as shown by the second portion 1134 of the eighth waveform 1130. When the serial data transitions to logic “1,” as shown by a high portion 1136 of the fourth waveform 1116, the integration begins to accumulate positively, which negates from the previous negative accumulation as shown by the second portion 1134 of the eighth waveform 1130.

A third portion 1138 of the eighth waveform 1130 illustrates the result of the integration for the period. The result of the integration is available to be multiplied by the first and the second stages of the digital multiplier circuit 900. In one embodiment, the result of the integration for the logic “0” to logic “1” case is multiplied by one (1) by the digital multiplier circuit 900. When the eight-phase clock signals 606, 607, 608, 609, 610, 611, 612, 613 derived from the VCO are relatively well synchronized to the serial data, the edges of the eight-phase clock signals 606, 607, 608, 609, 610, 611, 612, 613 are positioned approximately in the centers of the data bits, as shown by the first vertical line 1108 and the second vertical line 1110 intersecting the serial data 320 (RSDAT) approximately in the middle of the respective data bits. The corresponding transition from logic “0” to logic “1” also occurs approximately in the center of the integration window, and the result of the integration approaches zero as the integration of the logic “0” and the integration of the logic “1” components cancel.

A ninth waveform 1140 illustrates the integration of differential serial data for the logic “1” to logic “0” case illustrated by the fifth waveform 1118. In a first portion 1142 of the ninth waveform 1140, the integration is reset by charging the integration capacitors C₀ 948 and C₁ 949.

A second portion 1144 of the ninth waveform 1140 illustrates the integration of the logic “1” to logic “0” transition. When the serial data is at logic “1,” the integration accumulates positively as shown by the second portion 1144 of the ninth waveform 1140. When the serial data transitions to logic “0,” as shown by a low portion 1146 of the fifth waveform 1118, the integration accumulates negatively, which negates from the previous positive accumulation as shown by the second portion 1144 of the ninth waveform 1140.

A third portion 1148 of the ninth waveform 1140 illustrates the result of the integration for the period. The result of the integration is available to be multiplied by the first and the second stages of the digital multiplier circuit 900. In one embodiment, the result of the integration for the logic “1” to logic “0” case is multiplied by negative one (−1) by the digital multiplier circuit 900. The transition from logic “0” to logic “1” illustrated in FIG. 11 occurs approximately in the center of the integration window, and the result of the integration approaches zero as the integration of the logic “1” and the integration of the logic “0” components cancel.

A tenth waveform 1150 illustrates the integration of differential serial data for the logic “1” to logic “1” case illustrated by the sixth waveform 1120. In a first portion 1152 of the tenth waveform 1150, the integration is reset by charging the integration capacitors C₀ 948 and C₁ 949.

A second portion 1154 of the tenth waveform 1150 illustrates the integration of logic “1.” The integration gradually accumulates positively as shown by the second portion 1154 of the tenth waveform 1122.

A third portion 1156 of the tenth waveform 1150 illustrates the result of the integration for the period. The result of the integration is available to be multiplied by the first and the second stages of the digital multiplier circuit 900. In one embodiment, the result of the integration for the logic “1” to logic “1” case is multiplied by zero by the digital multiplier circuit 900.

An eleventh waveform 1158 is the inverse (multiplication by negative one) of the logic “1” to logic “0” integration illustrated by the ninth waveform 1240. Where both the logic “0” to logic “1” transition and the logic “1” to logic “0” transition are used to detect the phase difference between a clock signal generated from the VCO circuit 406 and the serial data 320, an integration of a logic “1” to logic “0” transition is summed out of phase with respect to an integration of a logic “0” to logic “1” transition.

FIG. 12 illustrates integration by the digital multiplier circuit 900 where the eight-phase clock signals 606, 607, 608, 609, 610, 611, 612, 613 derived from the VCO circuit 406 lead the serial data 320 by a relatively large amount. With reference to FIG. 12, a first waveform 1202 corresponds to the serial data 320 (RSDAT). A second waveform 1204 illustrates an integration window when the serial data 320 is integrated by the integration capacitors C₀ 948 and C₁ 949. In one embodiment, the digital multiplier circuit 900 integrates the serial data in response to the logical NOR of the inputs labeled CSH1B and CSH2 of the first stage 904, 905 of the multiplier circuit 900, as shown by an active portion 1206 of the second waveform 1204. A first vertical line 1208 and a second vertical line 1210 indicate a start time and a stop time, respectively, of the integration.

The timing of the active portion 1206 of the integration is selected to cover a transition 1212 of the serial data 320 between adjacent data bits. Again, the adjacent data bits can correspond to one of four cases: logic “0” to logic “0,” logic “0” to logic “1” logic “1” to logic “0,” and logic “1” to logic “1.”

A third waveform 1214 illustrates the case when the adjacent bits of the serial data 320 correspond to the logic “0” to logic “0” case during the integration period as shown by the active portion 1206. During the active portion 1206, the sample and hold circuit 902 couples the serial data 320 to the integration capacitors C₀ 948 and C₁ 949 by sinking current to reduce the charge previously stored in the integration capacitors C₀ 948 and C₁ 949.

A fourth waveform 1216 illustrates the case when the adjacent bits of the serial data 320 correspond to the logic “0” to logic “1” case during the integration period. A fifth waveform 1218 illustrates the case when the adjacent bits of the serial data 320 correspond to the logic “1” to logic “0” case during the integration period. A sixth waveform 1220 illustrates the case when the adjacent bits of the serial data 320 correspond to the logic “1” to logic “1” case during the integration period.

A seventh waveform 1222 illustrates the integration of differential serial data for the logic “0” to logic “0” case illustrated by the third waveform 1214. In a first portion 1224 of the seventh waveform 1222, the integration is reset by charging the integration capacitors C₀ 948 and C₁ 949.

A second portion 1226 of the seventh waveform 1222 illustrates the integration of logic “0.” With integration of a differential signal at logic “0,” the integration gradually accumulates negatively as shown by the second portion 1226 of the seventh waveform 1222.

A third portion 1228 of the seventh waveform 1222 illustrates the result of the integration for the period. The result of the integration is available to be multiplied by the first and the second stages of the digital multiplier circuit 900. However, for the case of logic “0” to logic “0,” there is no logic level transition and therefore no information about a timing of a transition to be retrieved from the integration. In one embodiment, the result of the integration for the logic “0” to logic “0” case is multiplied by zero by the digital multiplier circuit 900.

An eighth waveform 1230 illustrates the integration of differential serial data for the logic “0” to logic “1” case illustrated by the fourth waveform 1216. In a first portion 1232 of the eighth waveform 1230, the integration is reset by charging the integration capacitors C₀ 948 and C₁ 949.

A second portion 1234 of the eighth waveform 1230 illustrates the integration of the logic “0” to logic “1” transition. When the serial data is at logic “0,” the integration accumulates negatively as shown by the second portion 1234 of the eighth waveform 1230. When the serial data transitions to logic “1,” as shown by a high portion 1236 of the fourth waveform 1216, the integration begins to accumulate positively, which partially negates from the previous negative accumulation as shown by the second portion 1234 of the eighth waveform 1230.

A third portion 1238 of the eighth waveform 1230 illustrates the result of the integration for the period. The result of the integration is available to be multiplied by the first and the second stages of the digital multiplier circuit 900. In one embodiment, the result of the integration for the logic “0” to logic “1” case is multiplied by one (1) by the digital multiplier circuit 900. When the eight-phase clock signals 606, 607, 608, 609, 610, 611, 612, 613 derived from the VCO circuit 406 lead the serial data as shown in FIG. 12, the edges of the eight-phase clock signals 606, 607, 608, 609, 610, 611, 612, 613 arrive earlier than the centers of the data bits, as shown by the first vertical line 1208 and the second vertical line 1210 intersecting the serial data 320 (RSDAT) relatively early in the respective data bits. The corresponding transition from logic “0” to logic “1” then occurs relatively late in the integration window, and as a result, the integration is negative as shown by the third portion 1238 of the eighth waveform 1230. The integrations of the logic “0” to logic “1” transitions are combined and applied to the input of the receiver loop filter circuit 404 and then applied to an input of the VCO circuit 406 to slow the VCO circuit 406 to more closely match the phase.

A ninth waveform 1240 illustrates the integration of differential serial data for the logic “1” to logic “0” case illustrated by the fifth waveform 1218. In a first portion 1242 of the ninth waveform 1240, the integration is reset by charging the integration capacitors C₀ 948 and C₁ 949.

A second portion 1244 of the ninth waveform 1240 illustrates the integration of the logic “1” to logic “0” transition. When the serial data is at logic “1,” the integration accumulates positively as shown by the second portion 1244 of the ninth waveform 1240. When the serial data transitions to logic “0,” as shown by a low portion 1246 of the fifth waveform 1218, the integration begins to accumulate negatively, which partially negates from the previous positive accumulation as shown by the second portion 1244 of the ninth waveform 1240.

A third portion 1248 of the eighth waveform 1240 illustrates the result of the integration for the period. The result of the integration is available to be multiplied by the first and the second stages of the digital multiplier circuit 900. In one embodiment, the result of the integration for the logic “1” to logic “0” case is multiplied by negative one (−1) by the digital multiplier circuit 900.

When the eight-phase clock signals 606, 607, 608, 609, 610, 611, 612, 613 derived from the VCO circuit 406 lead the serial data as shown in FIG. 12, a transition from logic “1” to logic “0” occurs relatively late in the integration window. As a result, the result of the integration is positive as shown by the third portion 1248 of the ninth waveform 1240. To allow the integrations of the logic “1” to logic “0” transitions to be combined with the integrations of the logic “0” to logic “1” transitions, the integrations of the logic “1” to logic “0” transitions are summed out of phase with respect to the logic “0” to logic “1” transitions. The multiplication by negative one (−1) of a logic “1” to logic “0” transition converts the integration of the logic “1” to logic “0” transition out of phase with respect to of the integration of a logic “0” to logic “1” transition.

A tenth waveform 1250 illustrates the integration of differential serial data for the logic “1” to logic “1” case illustrated by the sixth waveform 1220. In a first portion 1252 of the tenth waveform 1250, the integration is reset by charging the integration capacitors C₀ 948 and C₁ 949.

A second portion 1254 of the tenth waveform 1250 illustrates the integration of logic “1.” The integration gradually accumulates positively as shown by the second portion 1254 of the tenth waveform 1222.

A third portion 1256 of the tenth waveform 1250 illustrates the result of the integration for the period. The result of the integration is available to be multiplied by the first and the second stages of the digital multiplier circuit 900. In one embodiment, the result of the integration for the logic “1” to logic “1” case is multiplied by zero by the digital multiplier circuit 900.

An eleventh waveform 1258 represents the inverse (multiplication by negative one) of the logic “1” to logic “0” integration illustrated by the ninth waveform 1240. Where both the logic “0” to logic “1” transition and the logic “1” to logic “0” transition are used to detect the phase difference between a clock signal generated from the VCO circuit 406 and the serial data 320, the integration of a logic “1” to logic “0” transition is summed out of phase with respect to the integration of a logic “0” to logic “1” transition.

FIG. 13 illustrates integration by the digital multiplier circuit 900 where the eight-phase clock signals 606, 607, 608, 609, 610, 611, 612, 613 derived from the VCO circuit 406 lag the serial data 320 by a relatively large amount. With reference to FIG. 13, a first waveform 1302 corresponds to the serial data 320 (RSDAT). A second waveform 1304 illustrates an integration window when the serial data 320 is integrated by the integration capacitors C₀ 948 and C₁ 949. In one embodiment, the digital multiplier circuit 900 integrates the serial data in response to the logical NOR of the inputs labeled CSH1B and CSH2, as shown by an active portion 1306 of the second waveform 1304. A first vertical line 1308 and a second vertical line 1310 indicate a start time and a stop time, respectively, of the integration.

The timing of the active portion 1306 of the integration is selected to cover a transition 1312 of the serial data 320 between adjacent data bits. Again, the adjacent data bits can correspond to one of four cases: logic “0” to logic “0,” logic “0” to logic “1” logic “1” to logic “0,” and logic “1” to logic “1.”

A third waveform 1314 illustrates the case when the adjacent bits of the serial data 320 correspond to the logic “0” to logic “0” case during the integration period as shown by the active portion 1306. During the active portion 1306, the sample and hold circuit 902 couples the serial data 320 or the differential serial data 852, 853 to the integration capacitors C₀ 948 and C₁ 949 by sinking current to reduce the charge previously stored in the integration capacitors C₀ 948 and C₁ 949.

A fourth waveform 1316 illustrates the case when the adjacent bits of the serial data 320 correspond to the logic “0” to logic “1” case during the integration period. A fifth waveform 1318 illustrates the case when the adjacent bits of the serial data 320 correspond to the logic “1” to logic “0” case during the integration period. A sixth waveform 1320 illustrates the case when the adjacent bits of the serial data 320 correspond to the logic “1” to logic “1” case during the integration period.

A seventh waveform 1322 illustrates the integration of differential serial data for the logic “0” to logic “0” case illustrated by the third waveform 1314. In a first portion 1324 of the seventh waveform 1322, the integration is reset by charging the integration capacitors C₀ 948 and C₁ 949.

A second portion 1326 of the seventh waveform 1322 illustrates the integration of logic “0.” With integration of a differential signal at logic “0,” the integration gradually accumulates negatively as shown by the second portion 1326 of the seventh waveform 1322.

A third portion 1328 of the seventh waveform 1322 illustrates the result of the integration for the period. The result of the integration is available to be multiplied by the first and the second stages of the digital multiplier circuit 900. However, for the case of logic “0” to logic “0,” there is no logic level transition and therefore no information about a timing of a transition to be retrieved from the integration capacitors C₀ 948 and C₁ 949. In one embodiment, the result of the integration for the logic “0” to logic “0” case is multiplied by zero by the digital multiplier circuit 900.

An eighth waveform 1330 illustrates the integration of differential serial data for the logic “0” to logic “1” case illustrated by the fourth waveform 1316. In a first portion 1332 of the eighth waveform 1330, the integration is reset by charging the integration capacitors C₀ 948 and C₁ 949.

A second portion 1334 of the eighth waveform 1330 illustrates the integration of the logic “0” to logic “1” transition. When the serial data is at logic “0,” the integration accumulates negatively as shown by the second portion 1334 of the eighth waveform 1330. When the serial data transitions to logic “1,” as shown by a high portion 1336 of the fourth waveform 1316, the integration begins to accumulate positively, which initially negates from the previous negative accumulations and then continues to accumulate positively as shown by the second portion 1334 of the eighth waveform 1330.

A third portion 1338 of the eighth waveform 1330 illustrates the result of the integration for the period. The result of the integration is available to be multiplied by the first and the second stages of the digital multiplier circuit 900. In one embodiment, the result of the integration for the logic “0” to logic “1” case is multiplied by one (1) by the digital multiplier circuit 900. When the eight-phase clock signals 606, 607, 608, 609, 610, 611, 612, 613 derived from the VCO circuit 406 lag the serial data as shown in FIG. 13, the edges of the eight-phase clock signals 606, 607, 608, 609, 610, 611, 612, 613 arrive later than the centers of the data bits, as shown by the first vertical line 1308 and the second vertical line 1310 intersecting the serial data 320 (RSDAT) relatively late in the respective data bits. The corresponding transition from logic “0” to logic “1” then occurs relatively early in the integration window, and as a result, the integration is positive as shown by the third portion 1338 of the eighth waveform 1330. The integrations of the logic “0” to logic “1” transitions are combined and applied to the input of the receiver loop filter circuit 404 and then applied to an input of the VCO circuit 406 to slow the VCO circuit 406 to more closely match the phase.

A ninth waveform 1340 illustrates the integration of differential serial data for the logic “1” to logic “0” case illustrated by the fifth waveform 1318. In a first portion 1342 of the ninth waveform 1340, the integration is reset by charging the integration capacitors C₀ 948 and C₁ 949.

A second portion 1344 of the ninth waveform 1340 illustrates the integration of the logic “1” to logic “0” transition. When the serial data is at logic “1,” the integration accumulates positively as shown by the second portion 1344 of the ninth waveform 1340. When the serial data transitions to logic “0,” as shown by a low portion 1346 of the fifth waveform 1318, the integration accumulates negatively, which first negates the previous positive accumulations and then continues to accumulate negatively as shown by the second portion 1344 of the ninth waveform 1340.

A third portion 1348 of the eighth waveform 1340 illustrates the result of the integration for the period. The result of the integration is available to be multiplied by the first and the second stages of the digital multiplier circuit 900. In one embodiment, the result of the integration for the logic “1” to logic “0” case is multiplied by negative one (−1) by the digital multiplier circuit 900.

When the eight-phase clock signals 606, 607, 608, 609, 610, 611, 612, 613 derived from the VCO circuit 406 lag the serial data as shown in FIG. 13, a transition from logic “1” to logic “0” occurs relatively early in the integration window. As a result, the result of the integration is negative as shown by the third portion 1348 of the ninth waveform 1340. To allow the integrations of the logic “1” to logic “0” transitions to be combined with the integrations of the logic “0” to logic “1” transitions, the integrations of the logic “1” to logic “0” transitions are summed out of phase with respect to the logic “0” to logic “1” transitions. The multiplication by negative one (−1) of a logic “1” to logic “0” transition converts the integration of the logic “1” to logic “0” transition out of phase with respect to of the integration of a logic “0” to logic “1” transition.

A tenth waveform 1350 illustrates the integration of differential serial data for the logic “1” to logic “1” case illustrated by the sixth waveform 1320. In a first portion 1352 of the tenth waveform 1350, the integration is reset by charging the integration capacitors C₀ 948 and C₁ 949.

A second portion 1354 of the tenth waveform 1350 illustrates the integration of logic “1.” The integration gradually accumulates positively as shown by the second portion 1354 of the tenth waveform 1322.

A third portion 1356 of the tenth waveform 1350 illustrates the result of the integration for the period. The result of the integration is available to be multiplied by the first and the second stages of the digital multiplier circuit 900. In one embodiment, the result of the integration for the logic “1” to logic “1” case is multiplied by zero by the digital multiplier circuit 900.

An eleventh waveform 1358 represents the inverse (multiplication by negative one) of the logic “1” to logic “0” integration illustrated by the ninth waveform 1340. Where both the logic “0” to logic “1” transition and the logic “1” to logic “0” transition are used to detect the phase difference between a clock signal generated from the VCO circuit 406 and the serial data 320, the integration of a logic “1” to logic “0” transition is summed out of phase with respect to the integration of a logic “0” to logic “1” transition.

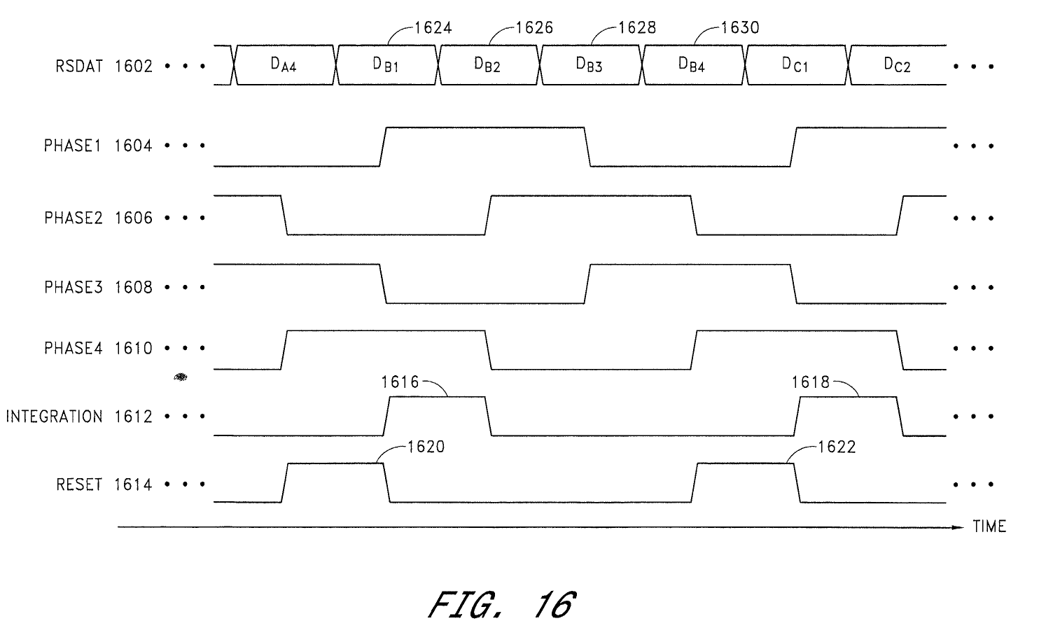

FIG. 14 illustrates an alternative embodiment of an integration circuit 1400. The integration circuit 1400 can be used in a phase detector to detect the phase difference between a serial data bitstream and a clock signal by integrating over data bit transitions in the serial data. A four-phase VCO clock is used to illustrate the operation of the integration circuit 1400 in FIG. 14 and in the accompanying timing diagram shown in FIG. 16. However, it will be understood by one of ordinary skill in the art that the integration circuit 1400 can be with VCOs with a number of different phases. One embodiment of the phase detector includes multiple embodiments of the integration circuit 1400 whose outputs are eventually combined to generate the phase detection. In one embodiment, the phase detector includes one embodiment of the integration circuit 1400 for each phase of a VCO in a PLL.

With reference to FIG. 14, the integration circuit 1400 includes a first integration capacitor C₁ 1402 and a second integration capacitor C₂ 1404, both of which store integration results as accumulated charge. A first transistor Q₁ 1406 and a second transistor Q₂ 1408 integrate the serial data 320 by accumulating charge in the first integration capacitor C₁ 1402 and in the second integration capacitor C₂ 1404. A NOR circuit 1410 activates the first transistor Q₁ 1406 and the second transistor Q₂ 1408 to integrate over an integration period that includes a data bit transition in the serial data 320 bitstream. A reset circuit 1426 activates a third transistor Q₃ 1422 and a fourth transistor Q₄ 1424 to reset the first integration capacitor C₁ 1402 and the second integration capacitor C₂ 1404.

The first integration capacitor C₁ 402 and the second integration capacitor C₂ 1404 store the results of the integration of the transition. The emitters of the first transistor Q₁ 1406 and of the second transistor Q₂ 1408 are coupled together and are also coupled to an output 1412 of the NOR circuit 1410. When the NOR circuit 1410 sinks a relatively large amount of current at the output 1412, the first transistor Q₁ 1406 and the second transistor Q₂ 1408 can charge the first capacitor C₁ 1402 and the second capacitor C₂ 1404, respectively, to integrate the serial data 320 over the integration period. When the NOR circuit 1410 is not sinking a relatively large amount of current at the output 1412, the first transistor Q₁ 1406 and the second transistor Q₂ 1408 each sink relatively little current, so that the integration result is held by the first integration capacitor C₁ 1402 and by the second integration capacitor C₂ 1404.

In the illustrated embodiment, a bitstream from the serial data 320 is applied differentially at a non-inverting input INₚ 1414 and an inverting input IN_{N} 1416. When the serial data 320 is high, the base of the first transistor Q₁ 1406 is at a higher potential than the base of the second transistor Q₂ 1408. Further, when the first transistor Q₁ 1406 and the second transistor Q₂ 1408 are enabled by the sinking of a relatively large amount of current in the output 1412 of the NOR circuit 1410, the first transistor Q₁ 1406 sinks a relatively large amount of current from the first capacitor C₁ 1402 and the second transistor Q₂ 1408 sinks a relatively small amount of current from the second capacitor C₂ 1404. As charge is drawn from the first capacitor C₁ 1402 by the current sinking of the first transistor Q₁ 1406, the voltage at an inverted output signal IOUT_{N} 1420 falls. The inverted output signal IOUT_{N} 1420 is an analog signal. The difference in voltage between a non-inverted output signal IOUT_{P} 1418 and the inverted output signal IOUT_{N} 1420 grows more positive when the serial data 320 is high during the integration period.

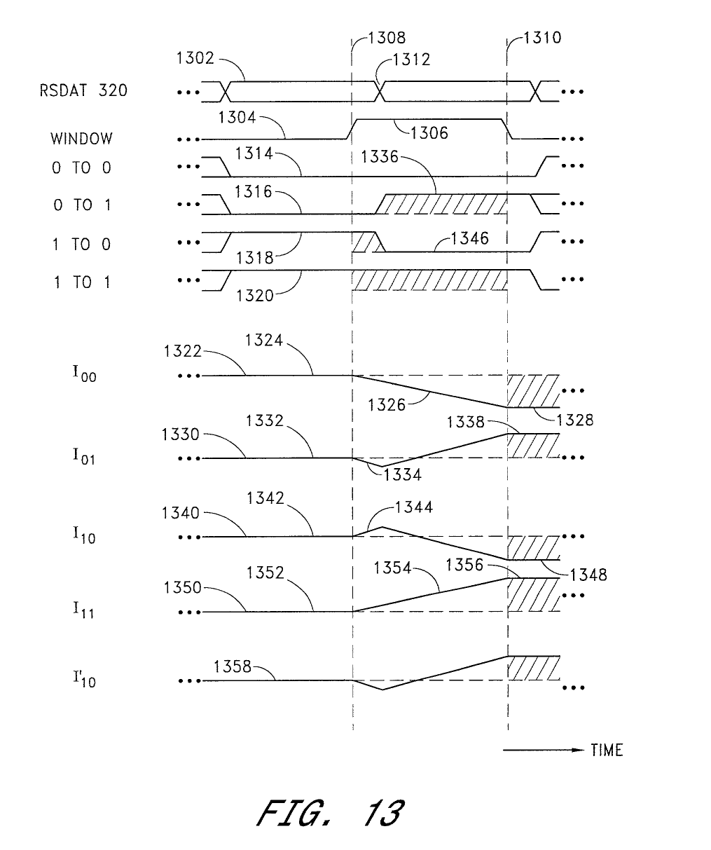

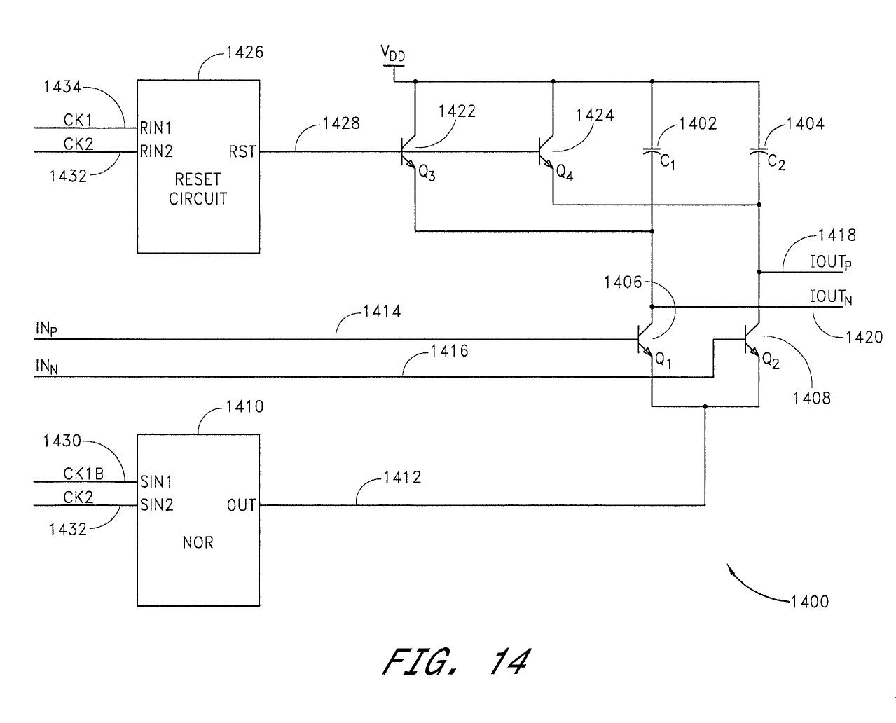

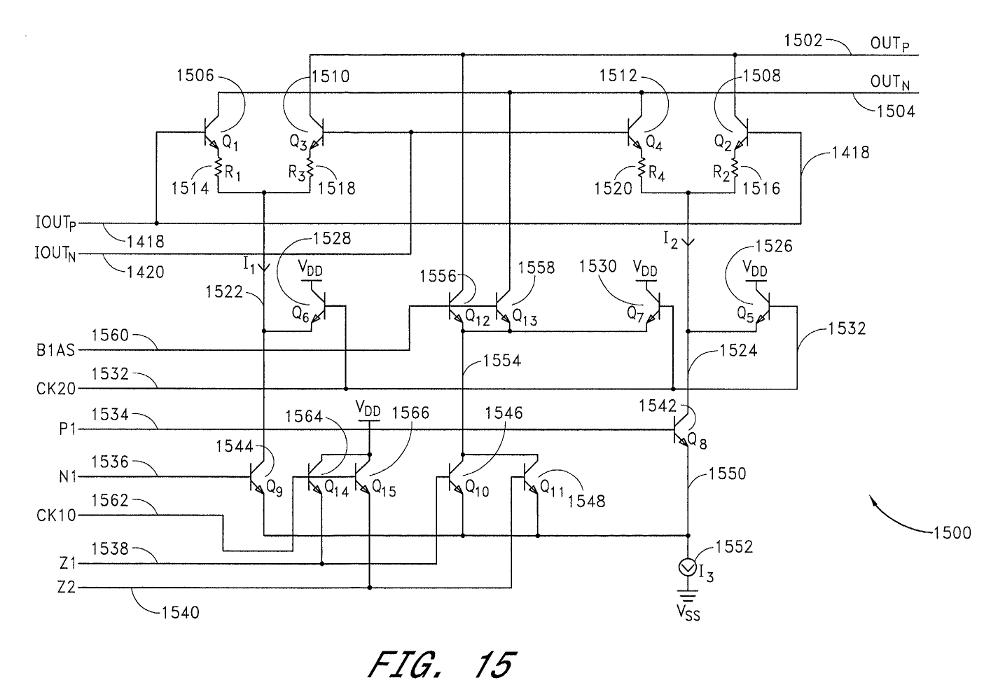

When the serial data 320 is low and the first transistor Q₁ 1406 and the second transistor Q₂ 1408 are enabled by a relatively large current sink in the output 1412 of the NOR circuit 1410, the second transistor Q₂ 1408 sinks a relatively large amount of current from the second capacitor C₂ 1404 and the first transistor Q₁ 1406 sinks a relatively small amount of current from the first capacitor C₁ 402. As charge is drawn from the second capacitor C₂ 1404 by the current sinking of the second transistor Q₂ 1408, the voltage at the non-inverted output signal IOUT_{P} 1418 falls. The non-inverted output signal IOUT_{P} 1418 is also an analog signal. The difference in voltage between the non-inverted output signal IOUT_{P} 1418 and the inverted output signal IOUT_{N} 1420 grows more negative. The non-inverted output signal IOUT_{P} 1418 and the inverted output signal IOUT_{N} 1420 are applied as inputs to a multiplier circuit 1500 described later in connection with FIG. 15.

The NOR circuit 1410 sinks current at the output 1412 during the integration period. The NOR circuit 1410 sinks current when the logical NOR of the SIN1 and SIN2 inputs is true. For example, for a transition between a first data bit and a second data bit of the serial data 320 bitstream, one embodiment couples an inverse of the clock phase associated with the first data bit to the SIN1 input and couples the clock phase associated with the second data bit to the SIN2 input. In the illustrated embodiment of the integration circuit 1400 shown in FIG. 14, the NOR circuit 1410 sinks current upon the logical NOR of a CKLB clock phase 1430, which corresponds to a third phase and also to the inverse of a first phase, and a CK2 clock phase 1432, which corresponds to a second phase. A timing diagram further illustrating the integration of a selected pair of data bits is described later in connection with FIG. 16.

The third transistor Q₃ 1422 and the fourth transistor Q₄ 1424 reset the first integration capacitor C₁ 1402 and the second integration capacitor C₂ 1404, respectively, by discharging the charge stored during integration. To discharge the first integration capacitor C₁ 1402 and the second integration capacitor C₂ 1404, the reset circuit applies a reset signal 1428 to the base of the third transistor Q₃ 1422 and to the base of the fourth transistor Q₄ 1424. In response to the reset signal 1428, the third transistor Q₃ 1422 and the fourth transistor Q₄ increase conductivity between their respective collectors and emitters, thereby providing the first integration capacitor C₁ 1402 and the second integration capacitor C₂ 1404 with a discharge path. In one embodiment, the first integration capacitor C₁ 1402 and the second integration capacitor C₂ 1404 have about 582 femtofarads (fF) of capacitance.

The reset circuit 1426 can activate the third transistor Q₃ 1422 and the fourth transistor Q₄ 1424 to reset the first integration capacitor C₁ 1402 and the second integration capacitor C₂ 1404, respectively, in a variety of states relative to the clock phases. The reset signal 1428 can be active anytime after the integration results have been read and anytime prior to the integration of the next data bit transition intended for the integration circuit 1400. The illustrated integration circuit 1400 activates the third transistor Q₃ 1422 and the fourth transistor Q₄ 1424 in response to a logical NOR of a RIN1 input and a RIN2 input. For the transition between a first data bit and a second data bit, a first clock phase CK1 1434 and the second clock phase CK2 1432 are provided as inputs to the RIN1 input and the RIN2 input. The timing diagram described later in connection with FIG. 16 illustrates further details of a sample timing of the reset circuit 1426.

FIG. 15 illustrates an alternate embodiment of a multiplier circuit 1500. The multiplier circuit 1500 receives the results of the integration from the integration circuit 1400 and applies the appropriate multiplication factor so that results of multiple integrations can be summed. The illustrated multiplier circuit 1500 multiplies an integration result by one, negative one, or by zero, and provides the multiplied result as an output on a non-inverted output OUT_{P} 1502 and an inverted output OUT_{N} 1504.

With reference to FIG. 15, the multiplier circuit 1500 includes a first transistor Q₁ 506, a second transistor Q₂ 1508, a third transistor Q₃ 1510, and a fourth transistor Q₄ 1512, which receive the non-inverted output signal IOUT_{P} 1418 and the inverted output signal IOUT_{N} 1420 from the integration circuit 1400 as inputs. The non-inverted output signal IOUT_{P} 1418 is applied as an analog input to the base of the first transistor Q₁ 1506 and to the base of the second transistor Q₂ 1508. The inverted output signal IOUT_{N} 1420 is applied as an analog input to the base of the third transistor Q₃ 1510 and to the base of the fourth transistor Q₄ 1512.

The first transistor Q₁ 1506 and the third transistor Q₃ 1510 are coupled together in a first emitter coupled pair with emitter degeneration provided by a first resistor R₁ 1514 and a third resistor R₃ 1518. The emitter degeneration improves the linearity of the first emitter coupled pair in response to the analog signals at the input of the first emitter coupled pair, which are the non-inverted output signal IOUT_{P} 1418 and the inverted output signal IOUT_{N} 1420. When activated by a first common current I₁ on a first emitter pair signal 1522, the first transistor Q₁ 1506 and the third transistor Q₃ 1510 multiply the integration result by negative one (−1).

Similarly, the second transistor Q₂ 1508 and the fourth transistor Q₄ 1512 are coupled together in a second emitter coupled pair with emitter degeneration provided by a second resistor R₂ 1516 and a fourth resistor R₄ 1520. The emitter degeneration again improves the linearity of the second emitter-coupled pair. In one embodiment, the first resistor R₁ 1514, the second resistor R₂ 1516, the third resistor R₃ 1518, and the fourth resistor R₄ 1520 have about 491 ohms of resistance. When activated by a second common current I₂ on a second emitter pair signal 1524, the second transistor Q₂ 1508 and the fourth transistor Q₄ 1512 multiply the integration result by positive one (+1).

The multiplier circuit 1500 includes a fifth transistor Q₅ 1526, a sixth transistor Q₆ 1528, and a seventh transistor Q₇, which receive a ck20 input signal 1532, which, when high, applies a bias to the second emitter pair signal 1524, to the first emitter pair signal 1522, and to a multiplication by zero pair signal 1554 that substantially prevents the unintended activation of the multiplication by one, negative one, and zero of the integration results provided by the non-inverted output signal IOUT_{P} 1418 and the inverted output signal IOUT_{N} 1420. In one embodiment, the ck20 input signal 1532 applies the bias when a phase associated with the second of the two consecutive bits is high. Further details of a possible timing for the ck20 signal are described later in connection with the timing diagram provided in FIG. 16.

The multiplier circuit 1500 receives an indication of the logic states associated with the integrated bits. In one embodiment, where the consecutive integrated bits corresponded to logic zero and to logic one, a P1 signal line 1534 is activated, which biases an eighth transistor Q₈ 1542, which in turn activates the second common current I₁₂ by coupling the second emitter pair signal 1524 to a current sink I₃ 1552. The application of the second common current I₂ to the current sink I₃ 1552 also tends to deactivate a ninth transistor Q₉ 1544, a tenth transistor Q₁₀ 1546, and an eleventh transistor Q₁₁ 1548 by raising the voltage on an emitter sum signal 1550. In one embodiment, the current sink I₃ 1552 sinks approximately 325 microamps (μA).

Where the consecutive integrated bits corresponded to a logic one and to a logic zero, an N1 signal line 1536 is activated, which biases a ninth transistor Q₉ 1544, which in turn activates the first common current I₁ by coupling the first emitter pair signal 1522 to the current sink I₂ 1552.

When the consecutive integrated bits corresponded to a logic one and to a logic one, a Z1 signal line 1538 is activated, which activates a tenth transistor Q₁₀ 1546, which activates both a twelfth transistor Q₁₂ 1556 and a thirteenth transistor Q₁₃ 1558. The twelfth transistor Q₁₂ 1556 and the thirteenth transistor Q₁₃ 1558 couple both the non-inverted output OUT_{P} 1502 and the inverted output OUT_{N} 1504, respectively, to the current sink I₃ 1552 to effectively multiply the integration result by zero. The twelfth transistor Q₁₂ 1556 and the thirteenth transistor Q₁₃ 1558 receive a relatively constant bias through a bias input 1560 so that either the tenth transistor Q₁₀ 1546 or an eleventh transistor Q₁₁ 1548 can activate the twelfth transistor Q₁₂ 1556 and the thirteenth transistor Q₁₃ 1558 by sinking current on the zero pair signal 1554 through the emitters of the twelfth transistor Q₁₂ 1556 and the thirteenth transistor Q₁₃ 1558.

When the consecutive integrated bits corresponded to a logic zero and to a logic zero, a Z2 signal line 1540 is activated, which activates the eleventh transistor Q₁₁ 1548. The eleventh transistor Q₁₁ 1548 is wired-OR'd with the tenth transistor Q₁₀ 1546 so that activation of the eleventh transistor Q₁₁ also multiplies the integration result by zero.

One embodiment of a circuit that provides an indication of the states of the consecutive bits was introduced earlier in connection with FIG. 9 and is also described later in connection with FIG. 18. However, it will be understood by one of ordinary skill in the art that the embodiment illustrated in FIG. 15 receives the indication of the logic states in an active high or sourced current format and the embodiments described in connection with FIGS. 9 and 18 provide an indication for the logic states in an active low or current sinking format.

In addition, the multiplier circuit 1500 further includes a fourteenth transistor Q₁₄ 1564 and a fifteenth transistor Q₁₅ 1566, which are activated by a ck10 signal 1562 to force a multiplication by zero result by providing a bias to the Z1 signal line 1538 and to the Z2 signal line 1540. Activation of the ck10 signal 1562 allows the non-inverted output OUT_{P} 1502 and the inverted output OUT_{N} 1504 to couple to the current sink I₃ and prevents the undesired application of incomplete or invalid integration results during times such as the integration of a transition.

FIG. 16 is a timing diagram of the alternate embodiment of the integration circuit 1400 illustrated in FIG. 14. The timing diagram illustrates operation of the integration circuit 1400 with a four-phase VCO clock so that each phase of the VCO clock operates at about one-fourth of the serial data 320 bit rate when the VCO is locked to the serial data 320.

With respect to FIG. 16, a first waveform 1602 corresponds to the serial data 320 bitstream. The four phases of the VCO clock are represented a second waveform 1604 corresponding to a first phase, a third waveform 1606 corresponding to a second phase, a fourth waveform 1608 corresponding to a third phase, and a fifth waveform 1610 corresponding to a fourth phase. A rising edge of each phase of the VCO clock corresponds to a data bit from the serial data 320 so that four bits, i.e., a nibble, of serial data are received by the receiver 302 for each cycle of the VCO clock. For example, a rising edge of the first phase 1604 corresponds to a first data bit 1624 of a “B” nibble, a rising edge of the second phase 1606 corresponds to a second data bit 1626 of the “B” nibble, a rising edge of the third phase 1608 corresponds to a third data bit 1628 of the “B” nibble, and a rising edge of the fourth phase 1610 corresponds to a fourth data bit 1630 of the “B” nibble. The pattern then repeats for a “C” nibble and so on.

In one embodiment, a phase detector includes four integration circuits corresponding to the integration circuit 1400 for each data bit transition in a VCO clock cycle, i.e., one integration circuit per phase of the VCO clock. The timing diagram in FIG. 16 illustrates timing for integration of a transition from a first data bit of the serial data, such as the first data bit 1624 of the “B” nibble, to a second data bit of the serial data, such as the second data bit 1626 of the “B” nibble.

A sixth waveform 1612 illustrates the integration period of the transition between the first data bit 1624 of the “B” nibble and the second data bit 1626 of the “B” nibble. Of course, the serial data 320 is continuously sent and the integration period is re-applied continuously to integrate the first data bit and the second data bit transition of other nibbles. The high level portions 1616, 1618 of the sixth waveform 1612 illustrate when the integration period is active and the NOR circuit 1410 sinks current at the output 1412 to enable the first transistor Q₁ 1406 and the second transistor Q₂ 1408 of FIG. 14 to integrate the serial data 320 as represented by the first waveform 1602. In one embodiment, the NOR circuit 1410 sinks current at the output 1412 and the sixth waveform 1612 is correspondingly high upon a logical NOR of the third phase as represented by the fourth waveform 1608 and the second phase as represented by the third waveform 1608.

A sixth waveform 1614 illustrates the reset period that prepares the first integration capacitor C₁ 1402 and the second integration capacitor C₂ 1404 to integrate a subsequent data bit transition. The high level portions 1620, 1622 of the sixth waveform 1614 correspond to when the reset signal 1428 from the reset circuit 1426 is a high level or is sourcing current to activate the third transistor Q₃ 1422 and the fourth transistor Q₄ 1424, which reset the first integration capacitor C₁ 1402 and the second integration capacitor C₂ 1404 by discharging the first integration capacitor C₁ 1402 and the second integration capacitor C₂ 1404. In the illustrated embodiment, the reset circuit 1426 resets the integration value upon a logical NOR of the first phase as represented by the second waveform 1604 and the second phase as represented by the third waveform 1606.

FIG. 17 illustrates one embodiment of a sample and hold circuit 902. The sample and hold circuit 902 includes a trigger circuit 1702 and an output switch circuit 1704.

With reference to FIG. 17, the trigger circuit 1702 enables and disables a current sink output I_{OUT} 1706 provided by an output transistor Q₁ 1708 in response to input signals applied at a first input CSH1B 1710 and a second input CSH2 1712. The trigger circuit 1702 is alternating current (AC) coupled, thereby isolating biases to stages of the trigger circuit 1702 and allowing relatively high-frequency operation of the trigger circuit 1702. When the first input CSH1B 1710 and the second input CSH2 1712 transition at relatively high speed, the current sink output I_{OUT} 1706 performs in accordance with Table III.

TABLE III

| CSH1B | CSH2 | I_{OUT} |
|---|---|---|
| 0 | 0 | Constant Current Sink |
| 0 | 1 | Off or Floating |
| 1 | 0 | Off or Floating |
| 1 | 1 | Off or Floating |

The first input CSH1B 1710 and the second input CSH2 1712 are level driven and are coupled to phases of the eight-phase clock signals 606, 607, 608, 609, 610, 611, 612, 613. As illustrated by Table III, the output sinks current upon the logical NOR of the first input CSH1B 1710 and the second input CSH2 1712. In one embodiment, the first input CSH1B 1710 is coupled to the inverse of the phase adjacent to the phase coupled to the second input CSH2 1712.

The first input CSH1B 1710 couples to a second capacitor C₂ 1716. In one embodiment, the second capacitor C₂ 1716 is about 100 femtofarads (fF). A first capacitor C₁ 714 illustrated in FIG. 17 is a parasitic capacitor that, in one embodiment, is about 17 fF of capacitance. The second capacitor C₂ 1716 alternating current (AC) couples the first input CSH1B 1710 as an input to a second transistor Q₂ 1718. The AC coupling provided by the second capacitor C₂ 1716 allows a first resistor R₁ 720 to bias the second transistor Q₂ 1718 independently of the first input CSH1B 1710. In one embodiment, the first resistor R₁ 720 is about 5.0 kiloohms (kohms). In another embodiment, the first resistor R₁ is selected from about 4.0 kohms to about 6.0 kohms.

Similarly, the second input CSH2 1712 couples to a fourth capacitor C₄ 1724. An illustrated third capacitor C₃ 1722 also models a parasitic capacitance, and the fourth capacitor C₄ 1724 AC couples the first input CSH1B 1710 as an input to a third transistor Q₃ 1726. A second resistor R₂ 1728 biases the third transistor Q₃ 1726. In one embodiment, the fourth capacitor C₄ 1724, the second resistor R₂ 1728, and the third transistor Q₃ 1726 are selected to match the second capacitor C₂ 1716, the first resistor R₁ 720, and the second transistor Q₂ 1718.

When either the second transistor Q₂ 1718 or the third transistor Q₃ is activated by a high logic level at either of the first input CSH1B 1710 or from the second input CSH2 1712, respectively, a first current I₁ 1734 from a third resistor R₃ 1730 is bypassed to a fourth resistor R₄ 1732 as illustrated by a second current I₂ 1736. The second current I₂ 1736, along with base current from the second transistor Q₂ 1718 or the third transistor Q₃ 1726, is coupled to the fourth resistor R₄ 1732 thereby raising the voltage potential at a first terminal of the fourth resistor R₄ 1732. The first terminal of the fourth resistor R₄ 1732 is also tied to the emitter of the output transistor Q₁ 708 so that an increase in the voltage potential at the first terminal of the fourth resistor R₄ 1732 tends to shut the output transistor Q₁ 1708 off, thereby providing positive feedback in a manner analogous to a Schmitt trigger and speeding the response of the sample and hold circuit 902. In one embodiment, the third resistor R₃ 1730 is about 800 ohms and the fourth resistor R₄ 1732 is about 300 ohms.

When both the second transistor Q₂ 1718 and the third transistor Q₃ 1726 are deactivated, at least a portion of the first current I₁ 1734 from the third R₃ 1730 couples through a fifth capacitor C₅ 1738 as illustrated by the third current I₃ 1740. The AC coupling provided by the fifth capacitor C₅ 1738 advantageously allows the second transistor Q₂ 1718 or the third transistor Q₃ 1726 to provide the output transistor Q₁ 1708 with a relatively large amount of drive during an on or an off transition for fast transitions, and yet, prevents the output transistor Q₁ 1708 from receiving the relatively large drive current for a relatively long time, thereby keeping the output transistor Q₁ 1708 in the linear region and out of the cutoff region or the saturation region. FIG. 17 also illustrates a sixth capacitor C₆ 1742, which models a parasitic capacitance.

The third current I₃ 1740 is AC coupled by the fifth capacitor C₁ 738 and is applied as an input to the base of the output transistor Q₁ 1708, which activates the current sink output I_{OUT} 1706 in response. The current sink output is of relatively constant current when activated. In one embodiment, the constant current when active is about 3 milliamps and is at least partially determined by the fourth resistor R₄ 1732. In addition, as the output transistor Q₁ 1708 conducts relatively more current through the fourth resistor R₄ 1732, the voltage potential of the fourth resistor R₄ rises, which also raises the voltage at the emitters of the second transistor Q₂ 1718 and the third transistor Q₃ 1726 thereby again providing positive feedback to shut the second transistor Q₂ 1718 and the third transistor Q₃ 1726 towards a less conductive state relatively quickly.

A fourth transistor Q₄ 1744 is biased by a fifth resistor R₅ 1746 and provides a trickle current sink from the base of the output transistor Q₁ 1708. This allows the output transistor Q₁ 1708 to shut off or diminish the current sink output I_{OUT} 1706 when either the second transistor Q₂ 1718 or the third transistor Q₃ is activated. The current through the fourth transistor Q₄ 1744 is limited by the sixth resistor R₆ 1748 and the seventh resistor R₇ 1750. In one embodiment, the sixth resistor R₆ 1748 is about 7 kohms and the seventh resistor R₇ 1750 is about 5 kohms. A seventh capacitor C₇ 1752 can be applied to the base of the fourth transistor Q₄ 1744 to reduce the sensitivity of the fourth transistor Q₄ 1744 to noise. In one embodiment, the seventh capacitor C₇ 1752 is about 200 fF. In one embodiment, a bias voltage applied to the first resistor R₁ 1720, the second resistor R₂ 1728, the fifth resistor R₅ 1746 and the seventh resistor R₇ 1750 is sourced from a current mirror and is about 0.9 volts to 1.0 volts so that the quiescent current through the fourth resistor R₄ 1732 is about 333 μA and the trickle current sink from the fourth resistor Q₄ 1744 is about 14.3 μA. The bias voltage provides bias to the transistors to keep the transistors out of the cutoff region.

A sixth transistor Q₆ 1754 configured as a diode by connecting the base and the collector can be included in the trigger circuit 1702 to provide a voltage drop to a terminal of the third resistor R₃ 1730.

The output switch circuit 1704 includes a seventh transistor Q₇ 1756 and an eighth transistor Q₈ 1758. The bases of the seventh transistor Q₇ 1756 and of the eighth transistor Q₈ 1758 are coupled to the differential serial data RSDAT(T) 852 and RSDAT(F) 853, respectively. When the serial data 320 is a logic “1,” RSDAT(T) 852 is high and RSDAT(F) 853 is low. This increases the conductance of the seventh transistor Q₇ 1756 and decreases the conductance of the eighth transistor Q₈ 1758, thereby coupling the OUTN output 1760 to the current sink output I_{OUT} 1706. In the digital multiplier circuit 900 illustrated in FIG. 9, a current sink at the OUTN output 1760 of the sample and hold circuit 902 sinks current from the second integration capacitor C₁ 949 through the otn signal 964. Sinking current from the second integration capacitor C₁ 949 lowers the voltage on the second integration capacitor C₁ 949, thereby increasing the differential voltage as measured from the first integration capacitor C₀ 948 to the second integration capacitor C₁ 949.

When the serial data 320 is a logic “0,” RSDAT(T) 852 is low and RSDAT(F) 853 is high. This decreases the conductance of the seventh transistor Q₇ 1756 and increases the conductance of the eighth transistor Q₈ 1758, thereby coupling the OUTP output 1762 to the current sink output I_{OUT} 1706. In the digital multiplier circuit 900 illustrated in FIG. 9, a current sink at the OUTP output 1762 of the sample and hold circuit 902 sinks current from the first integration capacitor C₀ 948 through the otp signal 962. Sinking current from the first integration capacitor C₀ 948 lowers the voltage on the first integration capacitor C₀ 948, thereby decreasing the differential voltage as measured from the first integration capacitor C₀ 948 to the second integration capacitor C₁ 949.

In one embodiment of the sample and hold circuit 902, the first transistor Q₁ 1708, the second transistor Q₂ 1718, the third transistor Q₃ 1726, the fourth transistor Q₄ 1744, the seventh transistor Q₇ 1756, and the eighth transistor Q₁ 1758 are about a first size, and the sixth transistor Q₆ 1754 that is configured as a diode is about 2.7 times larger than the first size.

FIG. 18 illustrates an embodiment of a data sequence identifier circuit 1800 that can be used in the first stage 904, 905 of the digital multiplier circuit 900 described in connection with FIG. 9. The data sequence identifier circuit 1800 detects and identifies a sequence of data between two bits, such as a transition from a first bit at logic 0 to a second bit at logic 1, on the serial data 320. Advantageously, the data sequence identifier circuit 1800 can detect the sequence of data with relatively little delay and can be used to identify a data sequence in real time at relatively high data rates such as OC-192 data rates. In addition, two of the same data sequence identifier circuits 1800 can be used to detect the four possible data sequences with substantially matched delay to allow operation at relatively high frequencies.

Inputs CMUL 1802 and CMULB 1804 are differential inputs that control the enabling of the data sequence identifier circuit 1800, i.e., the signal applied to the input CMULB 1804 is selected to be the logical inverse of the signal applied to the input CMUL 1802. The data sequence identifier circuit 1800 is enabled, i.e., is responsive to data inputs, when the input CMUL 1802 is high and the input CMULB 1804 is low. A high logic level on the input CMUL 1802 activates a first transistor Q₁ 1806 and a second transistor Q₂ 1808. A low logic level on the input CMULB 1804 deactivates a third transistor Q₃ 1810 and a fourth transistor Q₄ 1812. The activation of the first transistor Q₁ 1806 and the second transistor Q₂ 1808 bias and enable a fifth transistor Q₅ 1814, a sixth transistor Q₆ 1816, a seventh transistor Q₇ 1818, and an eighth transistor Q₈ 1820.

The data sequence identifier circuit 1800 is disabled when the input CMUL 1802 is low and the input CMULB 1804 is high. When the input CMUL 1802 is low, the first transistor Q₁ 1806 and the second transistor Q₂ 1808 are deactivated and the fifth transistor Q₅ 1814, the sixth transistor Q₆ 1816, the seventh transistor Q₇ 1818, and the eighth transistor Q₈ 1820 are unbiased. When the input CMULB 1804 is high, the third transistor Q₃ 1810 and the fourth transistor Q₄ 1812 are biased on and produce a low on an X output 1822 and a W output 1824, respectively, by sinking current to a first current sink I₁ 834 and a second current sink I₂ 1836.

The data sequence identifier circuit 1800 receives a first data bit at a dat1 input 1826 and a logical inverse of the first data bit at a dat1b input 1828. The data sequence identifier circuit 1800 receives a second data bit at a dat2 input 1830 and a logical inverse of the second data bit at a dat2b input 1832. Of course, the first data bit and the second data bit can be any adjacent bits in a serial data bitstream, including for example, the last transmitted bit of a byte and the first transmitted bit of the next byte.

Table IV illustrates the response of the data sequence identifier circuit 1800 to inputs. Inputs CMULB, dat1b, and dat2b are the logical inverses of CMUL, dat1, and dat2, respectively, and are not shown in Table IV for clarity.

TABLE IV

| | |
|---|---|
| Inputs | Outputs |

| CMUL | dat1 | dat2 | W | X |
|---|---|---|---|---|
| 0 | don't care | don't care | low | low |
| 1 | 0 | 0 | low | low |
| 1 | 0 | 1 | low | high |
| 1 | 1 | 0 | high | low |
| 1 | 1 | 1 | low | low |

In the illustrated embodiment of the data sequence identifier circuit 1800, a low output is a current sink state to the first current sink I₁ 1834 and the second current sink I₂ 1836 for the X output 1822 and the W output 1824, respectively. A high state indicates detection of the particular sequence selected. In one embodiment, the high state is a pull-up state through a first resistor R₁ 838 and a second resistor R₂ 1840, respectively, for the X output 1822 and the W output 1824. In one embodiment, the first resistor R₁ 838 and the second resistor R₂ 1840 have about 300 ohms of resistance.

Table V illustrates one set of input connections to the data sequence identifier circuit 1800 to detect a data sequence from the first data bit to the second data bit. The input connections to the data sequence identifier circuit 1800 are selected depending upon which data sequence is detected by the data sequence identifier circuit 1800.

TABLE V

| desired | input connection | | | |
|---|---|---|---|---|
| sequence | dat1 | dat1b | dat2 | dat2b |
| 0 to 0 | inverted | inverted | non-inverted | non-inverted |
| 0 to 1 | non-inverted | non-inverted | non-inverted | non-inverted |
| 1 to 0 | non-inverted | non-inverted | non-inverted | non-inverted |
| 1 to 1 | inverted | inverted | non-inverted | non-inverted |

In one embodiment, the first data bit coupled to the dat1 1826 and the dat1b 1828 inputs is inverted to detect a 0 to 0 transition or a 1 to 1 transition as illustrated by Table V, e.g., a true portion of the first data bit couples to the dat1b 1828 input, a false portion of the first data bit couples to the dat1 1826 input, a true portion of the second data bit couples to the dat2 1830 input, and a false portion of the second data bit couples to the dat2b 1832 input. When the first data bit is inverted, the X output 1822 goes high upon a 1 to 1 sequence and the W output 1824 is low. Upon a 0 to 0 detection, the W output 1824 goes high and the X output 1822 is low. When the data has transitioned from 0 to 1 or 1 to 0, both the X output 1822 and the W output 1824 are low.

In another embodiment, the second data bit is inverted and the first data bit is non-inverted to detect a 0 to 0 sequence or a 1 to 1 sequence. In the digital multiplier circuit 900, the X output 1822 and the W output 1824 of a 0 to 0 sequence detection or a 1 to 1 sequence detection both result in a multiplication by zero operation, and hence the X output 1822 and the W output 1824 of a data sequence identifier circuit 1800 used to detect a 0 to 0 sequence or a 1 to 1 sequence can be freely interchanged.

The same sequence identifier circuit 1800 can be configured to detect a 0 to 1 transition or a 1 to 0 transition. To detect a 0 to 1 transition or a 1 to 0 transition, the first data bit and the second data bit are applied as inputs to the data sequence identifier circuit 1800 so that a true portion of the first data bit couples to the dat1 input 1826, a false portion of the first data bit couples to the dat1b input 1828, a true portion of the second data bit couples to the dat2 input 1830, and a false portion of the second data bit couples to the dat2b input 1832. When the data has transitioned from a 0 to 1, i.e., the first data bit is 0 and the second data bit is 1, the X output 1822 goes high and the W output 1824 is low. When the data has transitioned from a 1 to a 0, i.e., the first data bit is 1 and the second data bit is 0, the W output 1824 goes high and the X output 1822 is low. When the data has remained at 0 or remained at 1, both the X output 1822 and the W output 1824 are low.

FIG. 19 illustrates one embodiment of a single-ended to differential input buffer 1900 that can be used, for example, for the single to differential circuit 818. The single-ended to differential input buffer 1900 receives a single-ended signal as an input IN 1902, and produces differential outputs OUT_{P} 1904 and OUT_{N} 1906. Conventional circuits disadvantageously feature a relatively large amount of differential delay between the noninverting and the inverting differential outputs. When the amount of differential delay becomes significant, a differential signal is no longer differential. Advantageously, the single-ended to differential input buffer 1900 has relatively little differential delay between differential outputs OUT_{P} 1904 and OUT_{N} 1906 and can be used at relatively high frequencies.

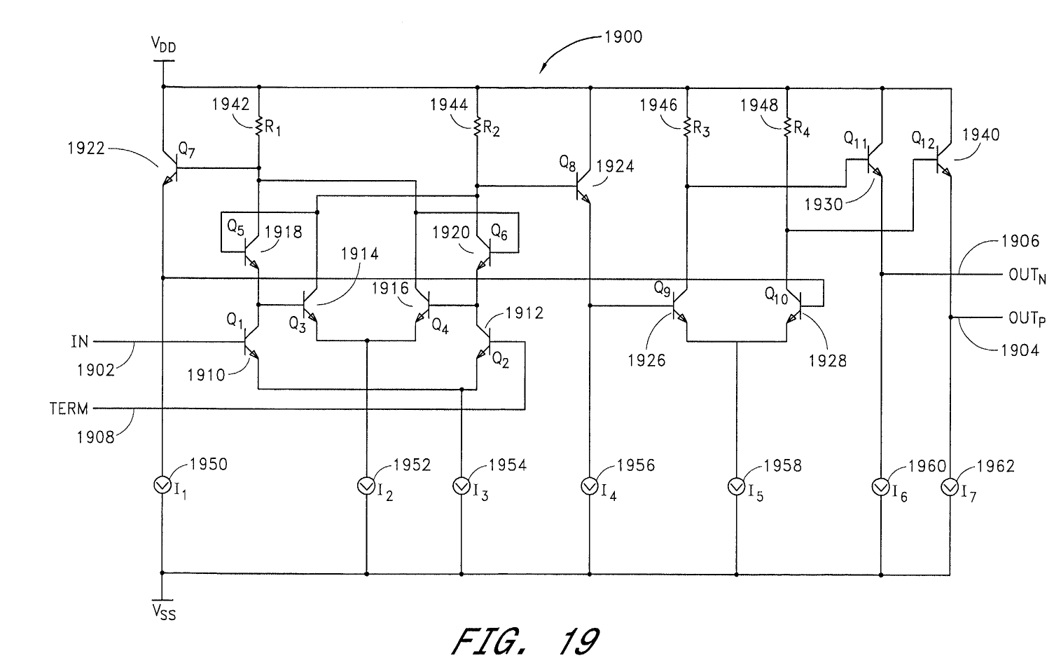

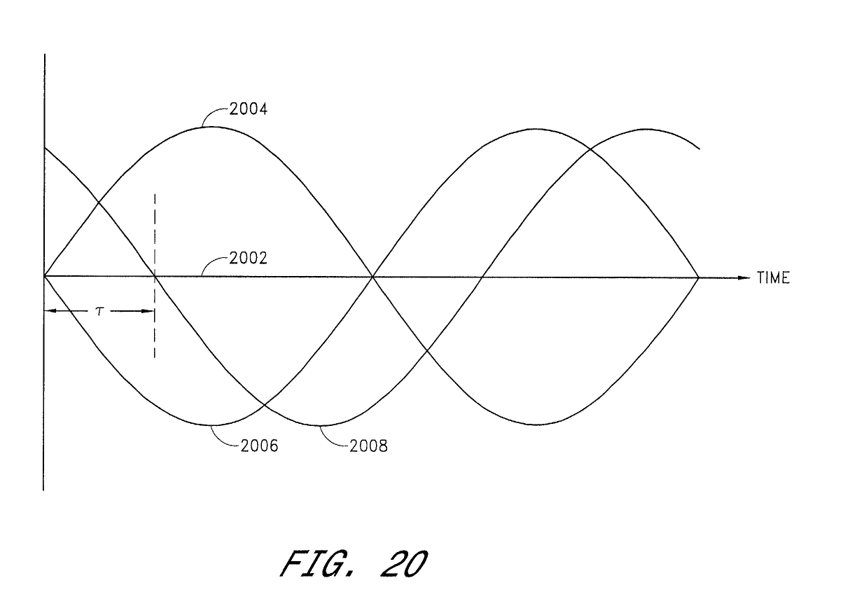

FIG. 20 is a timing diagram that illustrates the disadvantages of differential delay in a single-ended to differential input buffer. A horizontal axis 2002 indicates time. The timing diagram illustrates a first waveform 2004, a second waveform 2006, and a third waveform 2008. In relatively high-frequency systems, an actual digital waveform can take on a sinewave shape as shown in FIG. 20.

For a differential signal, an inverted output is ideally 180 degrees out of phase with respect to a non-inverted output. For example, the second waveform 2006 is 180 degrees out of phase with respect to the first waveform 2004. However, in an actual conventional single-ended to differential buffer, a first time delay in a path from the input to the non-inverting output, and a second time delay in a path from the input to the inverting output, can vary by a relatively large amount relative to the period of the input signal. The differential between the first time delay and the second time delay is illustrated in FIG. 20 by a differential time τ. At relatively high frequencies, the differential time τ can give rise to significant phase shifts and cause the non-inverting output and the inverting output to deviate from the ideal 180-degree phase relationship. The third waveform 2008 illustrates an inverted output that is delayed by a differential time τ from the ideal 180-degree phase relationship with the non-inverted output illustrated by the first waveform 2004.

In contrast to conventional single-ended to differential buffers that have a relatively large differential delay between the non-inverting output and the inverting output, the single-ended to differential input buffer 1900 advantageously has a relatively small differential delay between the non-inverting output OUT_{P} 1904 and the inverting output OUT_{N} 1906. The single-ended to differential input buffer 1900 advantageously closely matches delays to the non-inverting output OUT_{P} 1904 and the inverting output OUT_{N} 1906 to reduce the differential delay over a conventional single-ended to differential buffer and can be used at relatively high frequencies while maintaining an acceptable differential relationship between the non-inverting output OUT_{P} 1904 and the inverting output OUT_{N} 1906.

With reference to FIG. 19, the illustrated single-ended to differential input buffer 1900 receives the single-ended signal as an input IN 1902, and produces a non-inverting output OUT_{P} 1904 and an inverting output OUT_{N} 1906. The single-ended to differential input buffer 1900 also provides an input termination TERM 1908 that allows the single-ended to differential input buffer 1900 to accept a single-ended signal applied to the input IN 1902 in a relatively wide DC bias range by allowing the input termination TERM 1908 to bias a differential input stage to the same DC bias.

An input signal is applied at the input IN 1902, which is the base of a first transistor Q₁ 1910, and propagates to the non-inverting output OUT_{P} 1904 and to the inverting output OUT_{N} 1906. A main non-inverting signal path within the single-ended to differential input buffer 1900 includes the base to the collector of the first transistor Q₁ 1910, the emitter to the collector of a fifth transistor Q₅ 1918, the base to the emitter of a seventh transistor Q₇ 1922, the base to the collector of a tenth transistor Q₁₀ 1928, and the base to the emitter of a twelfth transistor Q₁₂ 1940. Similarly, a main inverting signal path within the single-ended to differential input buffer 1900 includes the second transistor Q₂ 1912, the emitter to the collector of a sixth transistor Q₆ 1920, the base to the emitter of an eighth transistor Q₈ 1924, the base to the collector of a ninth transistor Q₉ 1926, and the base to the emitter of an eleventh transistor Q₁₁ 1930. A third transistor Q₃ 1914 and a fourth transistor Q₄ 1916 provide compensation for stability.

The first transistor Q₁ 1910 and the second transistor Q₂ 1912 define an emitter coupled differential input stage. The differential pair formed by the first transistor Q₁ 1910 and the second transistor Q₂ 1912 generate the phase splitting for the single-ended to differential conversion. It will be understood by one of ordinary skill in the art that although the second transistor Q₂ 1912 has no input signal other than a bias, the emitter coupling of the second transistor to the first transistor Q₁ 1910 causes the collector current of the second transistor Q₂ 1912 to change in an opposite direction to the collector current of the first transistor Q₁ 1910 so that the output currents are about 180 degrees out of phase with respect to each other.

The fifth transistor Q₅ 1918 and the sixth transistor Q₆ 1920 are coupled to the first transistor Q₁ 1910 and the second transistor Q₂ 1912 to provide the collectors of the first transistor Q₁ 1910 and the second transistor Q₂ 1912 with a relatively low impedance for a relatively high frequency response. The fifth transistor Q₅ 1918 and the sixth transistor Q₆ 1920 sink current from a first terminal of a first resistor R₁ 942 and a first terminal of a second resistor R₂ 1944, respectively. A voltage measured between the first terminal of a first resistor R₁ 942 and the first terminal of a second resistor R₂ 1944 is differential with respect to the single-ended input IN 1902, but the signals available at the first terminal of a first resistor R₁ 942 and the first terminal of a second resistor R₂ 1944 are later buffered to produce the differential outputs OUT_{P} 1904 and OUT_{N} 1906.

The difference in speed at which the collector currents of the first transistor Q₁ 1910 and the fifth transistor Q₅ 1918, and the collector currents of the second transistor Q₂ 1912 and the sixth transistor Q₆ 1920 change is a component in the amount of differential delay between the differential outputs OUT_{P} 1904 and OUT_{N} 1906.

The configuration of the first transistor Q₁ 1910 and the fifth transistor Q₅ 1918, and the configuration of the second transistor Q₂ 1912 and the sixth transistor Q₆ 1920, as well, is similar to that of a cascode configuration. However, the base of the fifth transistor Q₅ 1918 and the base of the sixth transistor Q₆ 1920 are further coupled to the inverted output of the opposing stage, thereby providing cross coupling across the single-ended to differential input buffer 1900. The cross-coupling provides positive feedback, dramatically increasing the speed of the differential phase generation and decreasing the amount of differential delay between the differential outputs OUT_{P} 1904 and OUT_{N} 1906.

A relatively large amount of positive feedback can cause an undesirable amount of hysteresis and/or induce the cross-coupled stage to assume an undesirable latched state. The third transistor Q₃ 1914 and the fourth transistor Q₄ 1916 advantageously compensate for the positive feedback by shunting or diverting a portion of the cross coupling away from the bases of the fifth transistor Q₅ 1918 and the sixth transistor Q₆ 1920. For example, a portion of a current from the second resistor R₂ 1944, which would otherwise drive the base of the fifth transistor Q₅ 1918, is diverted by the collector of the third transistor Q₃ 1914. Similarly, a portion of a current from the first resistor R₁ 1942, which would otherwise drive the base of the sixth transistor Q₆ 1920, is diverted by the collector of the fourth transistor Q₄ 1916. The compensation for the cross coupling allows the single-ended to differential input buffer 1900 to advantageously split the phase of the input relatively quickly without latching such that the differential outputs exhibit relatively little phase deviation from the ideal 180 degrees even at relatively high frequencies such as 10 gigahertz (GHz).

The seventh transistor Q₇ 1922 buffers the voltage at the first terminal of the first resistor R₁ 1942 and drives a tenth transistor Q₁₀ 1928, which is configured to provide gain. The output of the tenth transistor Q₁₀ 1928 is applied to the twelfth transistor Q₁₂ 1940, which is buffers the output to the non-inverting output OUT_{P} 1904. Similarly, the eighth transistor Q₈ 1924 buffers the voltage at the first terminal of the second resistor R₂ 1944 and drives a ninth transistor Q₉ 1926. The ninth transistor Q₉ 1926 provides voltage gain and is part of another differential pair formed with the tenth transistor Q₁₀ 1928. The output of the ninth transistor Q₉ 1926 is applied to the eleventh transistor Q₁₁ 1930.

The single-ended to differential input buffer 1900 includes a plurality of current sinks for biasing. The plurality of current sinks include a first current sink I₁ 1950, a second current sink I₂ 1952, a third current sink I₃ 1954, a fourth current sink I₄ 1956, a fifth current sink I₅ 1958, a sixth current sink I₆ 1960, and a seventh current sink I₇ 1962. In one embodiment, the second current sink I₂ 1952 sinks more current than the third current sink I₃ 1954. In the illustrated embodiment of the single-ended to differential input buffer 1900, the first current sink I₁ 1950, the second current sink I₂ 1952, the third current sink I₃ 1954, the fourth current sink I₄ 1956, the fifth current sink I₅ 1958, the sixth current sink I₆ 1960, and the seventh current sink I₇ 1962 respectively sink about 500 microamps (μA), 500 μA, 1.5 milliamps (mA), 500 μA, 2 mA, 8 mA, and 8 mA. In alternate embodiments, the current sinks are selected to be within about ±20% and ±10% of the current levels in the illustrated embodiment. However, it will be understood by one of ordinary skill in the art that the amount of current that is sunk in the illustrated embodiment or sourced in a complementary embodiment, can vary greatly depending on the application dependent parameters such as the load for the single-ended to differential input buffer 1900.

In one embodiment, the first resistor R₁ 1942 and the second resistor R₂ 1944 have about 400 ohms of resistance, and the third resistor R₃ 1946 and the fourth resistor R₄ 1948 have about 150 ohms of resistance. In one embodiment, the first transistor Q₁ 1910, the second transistor Q₂ 1912, the third transistor Q₃ 1914, the fourth transistor Q₄ 1916, the fifth transistor Q₅ 1918, the sixth transistor Q₆ 1920, the seventh transistor Q₇ 1922 and the eighth transistor Q₈ 1924 are about a same first size, the ninth transistor Q₉ 1926 and the tenth transistor Q₁₀ 1928 are about a second size, and the eleventh transistor Q₁₁ 1930 and the twelfth transistor Q₁₂ 1940 are about a third size, and the second size is about 2.375 times as large as the first size, and the third size is about 6.5 times as large as the first size.

FIG. 21 illustrates a process 2100 of comparing the clock frequencies of two different clocks. The process can advantageously detect an absence of phase lock between a clock from a voltage controlled oscillator (VCO) that is generated from serial data and from a reference clock. For example, interruptions to the serial data may cause a phase locked loop (PLL) including the VCO to oscillate outside a lock range so that when the connection to the serial data is re-established, the PLL is unable to regain a lock to the serial data. The process 2100 allows the PLL to detect a loss of synchronization to the serial data and to instead synchronize to a reference clock signal that allows the PLL to remain within the lock range of the serial data. In one embodiment, the reference clock signal is from an external crystal controlled source.

In a first step 2110, the process receives the two clock signals. For example, a first clock signal can be a clock signal from the VCO and a second signal can be the reference clock. When the PLL is locked to the serial data, the first clock signal and the second clock signal are not synchronized, but are relatively close in frequency. The process advances from the first step 2110 to a second step 2120.

In the second step 2120, the process generates a beat frequency, which is the difference between first clock signal and the second clock signal. The process advances from the second step 2120 to a third step 2130.

In the third step 2130, the process measures the interval between beats of the beat frequency. In one embodiment, the process measures the interval with a timer or a counter synchronized to the reference clock signal or to a derivative of the reference clock signal such as a divide-by-two version of the reference clock signal. The process advances from the third step to a decision block 2140.

In the decision block 2140, the process determines whether the interval between beats exceeds a predetermined time or a predetermined count. A relatively long interval indicates that the beat frequency is relatively low and that the two clock signals are relatively close in frequency. The value selected for the predetermined time or the predetermined count can be selected in accordance with the lock range of the applicable PLL. The process proceeds to a fifth step 2150 when the interval exceeds the predetermined time. The process proceeds to a sixth step 2160 when the interval fails to exceed the predetermined time.

In the fifth step 2150, the exceeding of the predetermined time by the interval indicates that the two frequencies are relatively close in frequency and can indicate that the VCO is locked to the serial data. The process can clear error bits and the like. In addition, where the PLL had been synchronized to the reference clock, the process can change the feedback path to synchronize the VCO to the serial data in response to the exceeding of the predetermined time.

In the fifth step 2160, the process detects that the interval between beats is relatively short and that the two frequencies are not relatively closely matched. This situation can occur where, for example, there has been an interruption in the serial data. The process can set error flags and the like to provide a warning to interfacing systems, and can change the feedback path to synchronize the VCO to the reference clock signal to maintain the VCO within the lock range of the serial data.

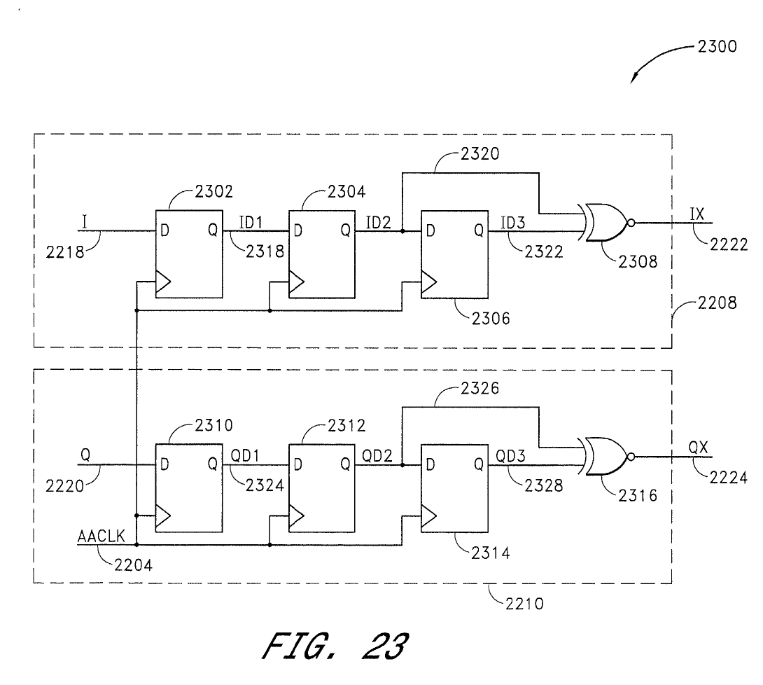

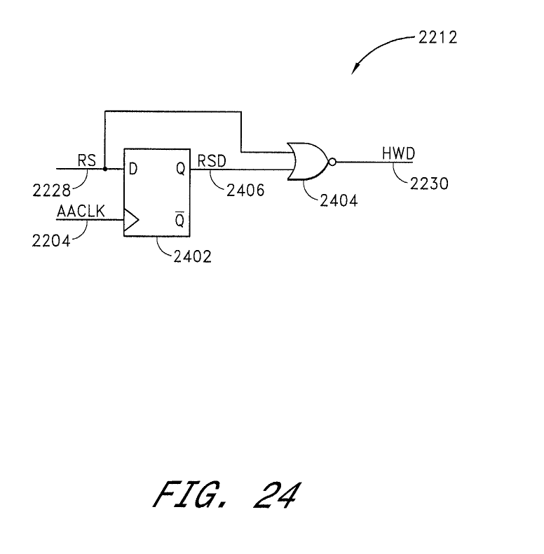

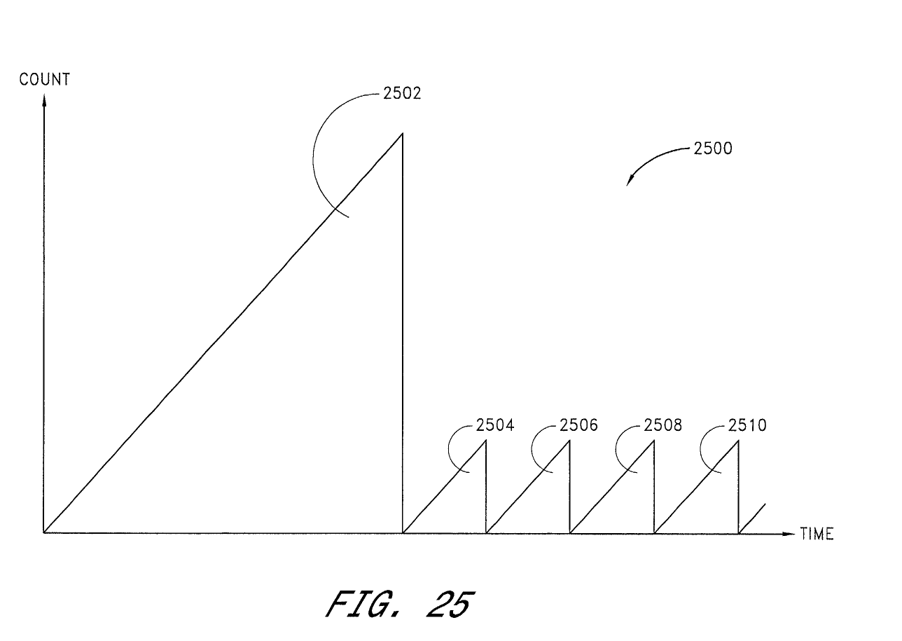

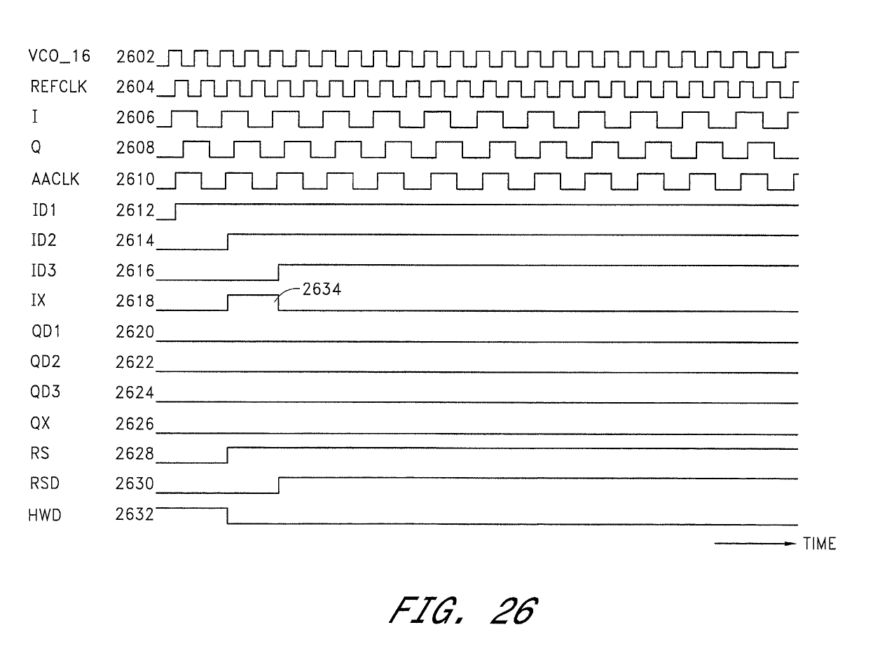

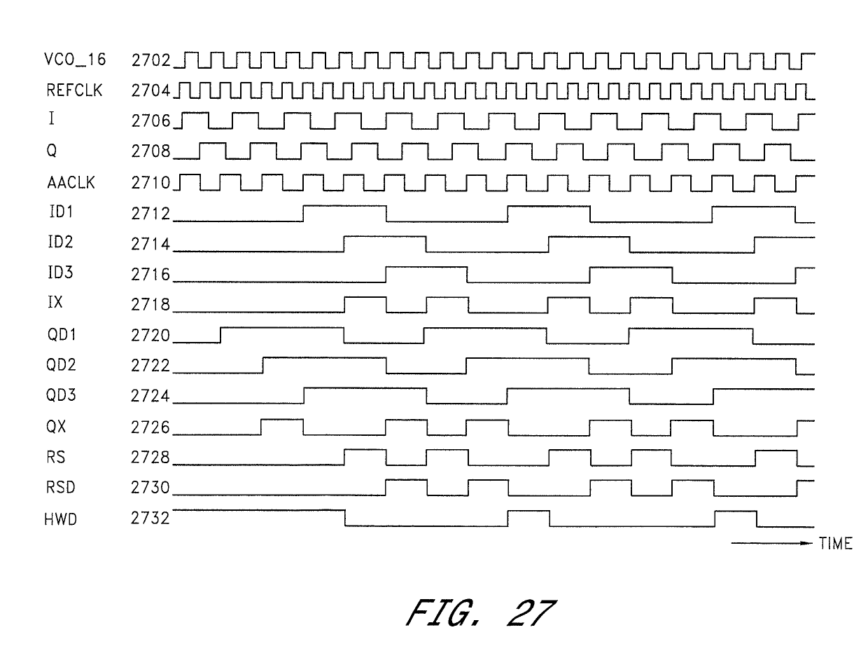

FIG. 22 illustrates one embodiment of an acquisition aid circuit 308. FIGS. 23 and 24 illustrate subcircuits of the acquisition aid circuit 308. FIG. 25 illustrates contents of a timer or a counter in the acquisition aid circuit 308 under a variety of conditions. FIGS. 26 and 27 are timing diagrams of the acquisition aid circuit 308 and associated sub-circuits. With reference to FIG. 22, the acquisition aid circuit 308 receives the reference clock signal 332 to a first D-type flip-flop 2202, which is configured as a toggle to divide the reference clock signal 332 by two to an acquisition aid clock signal (AACLK) 2204. The acquisition aid clock signal 2204 is applied as an input to a timer 2206, an in-phase full-wave differentiator circuit 2208, a quadrature-phase full-wave differentiator circuit 2210, and a half-wave differentiator circuit 2212 as a timing input. The acquisition aid clock signal 2204 is divided to reduce the power consumed by the acquisition aid circuit 308. It will be understood by one of ordinary skill in the art that in another embodiment, the reference clock signal 332 does not have to be divided and that in another embodiment, the reference clock signal 332 can be further divided to further save power.

The receiver clock signal 326 from the VCO circuit 406 is applied as an input to a second D-type flip-flop 2214 and a third D-type flip-flop 2216, both of which are configured as toggles to divide the receiver clock signal 326 by two. However, the second D-type flip-flop 2214 toggles on the rising edge of the receiver clock signal 326 and the third D-type flip-flop 2216 toggles on the falling edge of the receiver clock signal 326, such that an output of the second D-type flip-flop 2214 and an output of the third D-type flip-flop 2216 are separated by 90 degrees of phase shift. The output of the second D-type flip-flop 2214 is the in-phase (1) clock signal 2218. The output of the third D-type flip-flop 2216 is the quadrature-phase (Q) clock signal 2220. In another embodiment, the third D-type flip-flop 2216 is not configured as a toggle, but rather samples the output of the second D-type flip-flop 2214 on the opposite edge to which the second D-type flip-flop 2214 is triggered to produce the quadrature-phase (Q) clock signal 2220. In one embodiment, the reference clock is about 622 MHz and the receiver clock signal 326 is also about 622 MHz when the clocks are relatively close in frequency.

The in-phase full-wave differentiator circuit 2208 and the quadrature-phase full-wave differentiator circuit 2210 receive the in-phase (I) clock signal 2218 and the quadrature-phase (Q) clock signal 2220, respectively, and compare the in-phase (I) clock signal 2218 and the quadrature-phase (Q) clock signal 2220 to the acquisition aid clock signal 2204. The in-phase full-wave differentiator circuit 2208 and the quadrature-phase full-wave differentiator circuit 2210 generate beat frequencies that are twice the difference in frequency between their respective data inputs and the acquisition aid clock signal 2204. In one embodiment, the in-phase full-wave differentiator circuit 2208 and the quadrature-phase full-wave differentiator circuit 2210 generate beat frequencies for the in-phase (I) clock signal 2218 and the quadrature-phase (Q) clock signal 2220 when the in-phase (I) clock signal 2218 and the quadrature-phase (Q) clock signal 2220 are in a range of about half the acquisition aid clock signal 2204 frequency to about double the acquisition aid clock signal 2204 frequency.

In the illustrated embodiment of the acquisition aid circuit 308, the in-phase (I) clock signal 2218, the quadrature-phase (Q) clock signal 2220, and the acquisition aid clock signal 2204 are already divided by two from source signals so that the beat frequency from the outputs IX 2222 and QX 2224 of the in-phase full-wave differentiator circuit 2208 and the quadrature-phase full-wave differentiator circuit 2210, respectively, which double the difference in frequency, corresponds to the difference between the receiver clock signal 326 and the reference clock signal 332. One embodiment of the in-phase full-wave differentiator circuit 2208 and the quadrature-phase full-wave differentiator circuit 2210 is described in greater detail later in connection with FIG. 23.

An RS flip-flop 2226 or SR latch receives the outputs IX 2222 and QX 2224 of the in-phase full-wave differentiator circuit 2208 and the quadrature-phase full-wave differentiator circuit 2210, respectively, as inputs. The RS flip-flop 2226 filters spurious clocking from the outputs IX 2222 and QX 2224 of the in-phase full-wave differentiator circuit 2208 and the quadrature-phase full-wave differentiator circuit 2210 by cycling through from a first state to a second state, and back to the first state only when both full-wave differentiators 2208, 2210 have changed state. This advantageously reduces falsing due to timing glitches or metastability. In the illustrated embodiment of the acquisition aid circuit 308, the IX signal 2222 is coupled to a set input of the RS flip-flop 2226 and the QX signal 2224 is coupled to a reset input of the RS flip-flop 2226. The RS flip-flop 2226 sets an output signal RS 2228 to a high state when the IX signal 2222 received at the set input is high and resets the output signal RS 2228 to a low state when the QX signal 2224 received at the reset input is high. In an alternative embodiment, the QX signal 2224 is coupled to the set input of the RS flip-flop 2226 and the IX signal 2222 is coupled to the reset input of the RS flip-flop 2226.

The half-wave differentiator circuit 2212 samples the output RS 2228 of the RS flip-flop 2226 with the acquisition aid clock signal 2204 and generates a pulse after a stream of frequency beats has propagated through the RS flip-flop 2226. The in-phase full-wave differentiator circuit 2208 and the quadrature-phase full-wave differentiator circuit 2210 generate at least two beats each time the in-phase full-wave differentiator circuit 2208 and the quadrature-phase full-wave differentiator circuit 2210 detect that one clock has overrun the other, i.e., that one clock has “lapped” the other. The output HWD 2230 of the half-wave differentiator circuit 2212 maintains a first state, such as a low logic level, with an interval or duration approximately corresponding to the period of the beat frequency between the in-phase (I) clock signal 2218 and the acquisition aid clock signal 2204 or the quadrature-phase (Q) clock signal 2220 and the acquisition aid clock signal 2204. One embodiment of the half-wave differentiator circuit 2212 is described in greater detail later in connection with FIG. 24.

The timer 2206 tracks the interval corresponding to the period of the beat frequency between the in-phase (I) clock signal 2218 and the acquisition aid clock signal 2204 or the quadrature-phase (Q) clock signal 2220 and the acquisition aid clock signal 2204. In the illustrated embodiment of the acquisition aid circuit 308, the timer 2206 receives the HWD signal 2230 and tracks the interval when the HWD signal 2230 is low and resets the timing of the interval in response to a high level of the HWD signal 2230. When the interval exceeds a predetermined time, the timer 2206 activates a timer output 2232, which is applied as an input to an anti-falsing circuit 2240. The activation of the timer output 2232 indicates a relatively close match between the reference clock signal 332 and the receiver clock signal 326. In one embodiment, the timer 2206 is implemented with an 11-bit up counter triggered by the acquisition aid clock 2204. The timer output 2232 can be generated by a toggling of the 11^{th} bit of the 11-bit counter, but it will be understood by one of ordinary skill in the art that other techniques can be used such as generating overflows, generating underflows in down counters, decoding specific counts, and the like.

The anti-falsing circuit 2240 receives the HWD signal 2230 and the timer output 2232. The anti-falsing circuit 2240 reduces false alarms by requiring a predetermined number of consecutive indications of relatively poor matches between the reference clock signal 332 and the receiver clock signal 326 prior to deactivation of the AA signal 328. In the illustrated embodiment, a high level on the AA signal 328 indicates that there is a relatively poor match between the reference clock signal 332 and the receiver clock signal 326. A low level on the AA signal 328 indicates that there is a relatively good match between the reference clock signal 332 and the receiver clock signal 326.

In the illustrated embodiment, the acquisition aid circuit 308 deactivates the AA signal 328 by setting the AA 328 signal high upon the occurrence of three consecutive indications of a relatively poor match between the reference clock signal 332 and the receiver clock signal 326. The illustrated anti-falsing circuit 2240 counts three occurrences of activations of the HWD signal 2230 to deactivate the AA signal 328 and resets upon the activation of the timer output 2232. The anti-falsing circuit 2240 shown in FIG. 22 includes a fourth D-type flip-flop 2234, a fifth D-type flip-flop 2236, and a sixth D-type flip-flop 2238. The fourth D-type flip-flop 2234, the fifth D-type flip-flop 2236, and the sixth D-type flip-flop 2238 are reset upon activation of the timer output 2232. Thus, when the interval has reached the predetermined time and the reference clock signal 332 and the receiver clock signal 326 are relatively close in frequency, the anti-falsing circuit 2240 produces a low at the AA signal 328.

FIG. 25 is a diagram 2500 that illustrates content of the timer 2206 measuring the interval time under varying conditions. The timer output 2232 activates in response to a relatively long interval, as demonstrated by a relatively large count 2502, to reset the fourth D-type flip-flop 2234, the fifth D-type flip-flop 2236, and the sixth D-type flip-flop 2238.

By contrast, when the reference clock signal 332 and the receiver clock signal 326 are relatively poorly matched, the interval between beats is relatively short and the HWD signal 2230 resets the timer 2206 before the timer reaches the predetermined count as indicated by the relatively small counts 2504, 2506, 2508, 2510. With three successive HWD signal 2230 pulses and no activation of the timer output 2232, a high logic level coupled to the data input of the fourth D-type flip-flop 2234 propagates to the fifth D-type flip-flop 2236, and then to the sixth D-type flip-flop 2238. Of course, the logic levels used can be inverted so that the timer sets the D-type flip-flops 2234, 2236, 2238 and a zero propagates to the output with successive pulses of the HWD signal 2230. In addition, the number of consecutive indications can be easily varied by including fewer or more D-type flip-flops in the anti-falsing circuit 2240. In another embodiment, the anti-false circuit 2240 is implemented by a counter that is triggered by the HWD signal 2230, reset or loaded by the timer output 2232, and activates/deactivates the AA signal 328 in response to a decoded count.

FIG. 23 illustrates one embodiment of a full-wave differentiator circuit 2300. The full-wave differentiator circuit includes the in-phase full-wave differentiator circuit 2208 and the quadrature-phase full-wave differentiator circuit 2210. With reference to FIG. 23, the illustrated in-phase full-wave differentiator circuit 2208 includes a first D-type flip-flop 2302, a second D-type flip-flop 2304, a third D-type flip-flop 2306, and a first exclusive-OR (XOR) gate 2308. The quadrature-phase full-wave differentiator circuit 2210 includes a fourth D-type flip-flop 2310, a fifth D-type flip-flop 2312, a sixth D-type flip-flop 2314, and a second XOR gate 2316.

The first, the second, the third, the fourth, the fifth, and the sixth D-type flip-flops 2302, 2304, 2306, 2310, 2312, 2314 are triggered by the acquisition aid clock signal 2204. However, the in-phase (I) clock signal 2218 and the quadrature-phase (Q) clock signal 2220, which are applied as inputs to the in-phase full-wave differentiator circuit 2208 and the quadrature-phase full-wave differentiator circuit 2210 are asynchronous with respect to the acquisition aid clock signal 2204. The first D-type flip-flop 2302 and the fourth D-type flip-flop 2310 synchronize the in-phase (I) clock signal 2218 and the quadrature-phase (Q) clock signal 2220 to an ID1 signal 2318 and a QDI signal 2324, respectfully, to the acquisition aid clock signal 2220.

The second D-type flip-flop 2304 and the fifth D-type flip-flop 2312 compensate for metastability in the ID1 signal 2318 and the QD1 signal 2324 induced by the synchronization of the asynchronous inputs by the first D-type flip-flop 2302 and by the fourth D-type flip-flop 2310, respectively. The output signal ID2 2320 of the second D-type flip-flop 2306 is applied as an input to the third D-type flip-flop 2306 and the first XOR gate 2308. Similarly, the output signal QD2 2326 of the fifth D-type flip-flop 2312 is applied as an input to the sixth D-type flip-flop 2314 and the second XOR gate 2316.

The signal ID2 2320 contains one pulse for each beat of the difference in frequency between the acquisition aid clock signal 2204 and the in-phase (I) clock signal 2218. The signal QD2 2326 similarly contains one pulse for each beat of the difference in frequency between the acquisition aid clock signal 2204 and the quadrature-phase clock signal 2220. The signals ID2 2320 and QD2 2326 are further described in connection with the timing diagrams found in FIGS. 26 and 27.

The third D-type flip-flop 2306 and the sixth D-type flip-flop 2314 delay the signals ID2 2320 and QD2 2326 to outputs signals ID3 2322 and QD3 2328, respectfully, by a clock cycle of the acquisition aid clock signal 2204. The ID3 signal 2322 and the QD3 signal 2328 allow the first XOR gate 2308 and the second XOR gate 2316, respectfully, to generate a first pulse from a 0 to 1 transition and a second pulse from a 1 to 0 transition of the ID2 signal 2320 and the QD2 signal 2326, respectfully. Further details of the output IX 2222 of the first XOR gate 2308 and the output QX 2224 of the second XOR gate 2316 are described in connection with the timing diagrams found in FIGS. 26 and 27.

FIG. 24 illustrates one embodiment of the half-wave differentiator circuit 2212. With reference to FIG. 24, the half-wave differentiator circuit 2212 includes a D-type flip-flop 2402 and a NOR gate 2404. The D-type flip-flop 2402 delays the RS signal 2228 by a clock cycle of the acquisition aid clock signal 2204 to an RSD signal 2406, which is applied as an input to the NOR gate 2404. The NOR gate 2404 compares the RS signal 2228 and the RSD signal 2406 and produces a high at an HWD signal 2230 when both the RS signal 2228 and the RSD signal 2406 are low. The timing diagrams found in FIGS. 26 and 27 further illustrate the operation of the half-wave differentiator circuit 2212.

FIG. 26 is a timing diagram of the acquisition aid circuit 308 of FIG. 22 with a relatively close match between a VCO signal and a reference clock signal. The horizontal axis indicates time, with time increasing to the right. For clarity, the waveforms in FIGS. 26 and 27 are drawn with relatively sharp edges. It will be understood by one of ordinary skill in the art that actual waveforms of timing signals at relatively high frequencies are considerably more rounded and can resemble sine waves. With reference to FIG. 26, a first waveform 2602 corresponds to the receiver clock signal 326 from the VCO circuit 406. A second waveform 2604 corresponds to the reference clock signal 332. In the timing diagram shown in FIG. 26, the receiver clock signal 326 and the reference clock signal 332 are at the same frequency.

The second D-type flip-flop 2214 and the third D-type flip-flop 2216 divide the receiver clock signal 326 by two into the in-phase (I) clock signal 2218 and the quadrature-phase (Q) clock signal 2220. A third waveform 2606 corresponds to the in-phase (I) clock signal 2218 and a fourth waveform 2608 corresponds to the quadrature-phase (Q) clock signal 2220. It does not matter whether the quadrature-phase (Q) clock signal 2220 leads or lags the in-phase (I) clock signal 2218 by 90 degrees.

A fifth waveform 2610 corresponds to the acquisition aid clock signal 2204, which in the illustrated embodiment is divided by two by the first D-type flip-flop 2202 from the reference clock signal 332.

A sixth waveform 2612 corresponds to the ID1 signal 2318 of the first D-type flip-flop 2302 of the in-phase full-wave differentiator circuit 2208. The first D-type flip-flop 2302 of the in-phase full-wave differentiator circuit 2208 synchronizes the in-phase (I) clock signal 2218 with the acquisition aid clock signal 2204. In the timing diagram shown in FIG. 26, the sixth waveform 2612 remains at a consistent logic state because the reference clock signal 332 and the receiver clock signal 326 are relatively closely matched, and the relationship between a state of the in-phase (I) clock signal 2218, as shown by the third waveform 2606, and the rising edge of the acquisition aid clock 2204, as shown by the fifth waveform 2204, remains relatively constant.

A seventh waveform 2614 and an eighth waveform 2616 correspond to the ID2 signal 2320 of the second D-type flip-flop 2304 and to the ID3 output 2322 of the third D-type flip-flop 2306, respectively, of the in-phase full-wave differentiator circuit 2208. The second D-type flip-flop 2304 produces the ID2 signal 2320 shown in the seventh waveform 2614 by sampling the ID1 signal 2318 shown by the sixth waveform 2612 to compensate for metastability induced by the synchronization of an asynchronous signal. The eighth waveform 2616 illustrates that the ID3 output 2322 of the third D-type flip-flop 2306 is delayed from the ID2 signal 2320 by a clock cycle of the acquisition aid clock signal 2204, which is illustrated by the fifth waveform 2610.

A ninth waveform 2618 corresponds to the IX signal 2222, which is the logical XOR of the ID2 signal 2320 illustrated by the seventh waveform 2614 and the ID3 signal 2322 illustrated by the eighth waveform 2616. The IX signal 2222 pulses high when one of the ID2 signal 2320 or the ID3 signal 2322 is a high level and the other is a low level as illustrated by the pulse 2634.

A tenth waveform 2620, an eleventh waveform 2622, and a twelfth waveform 2624 correspond to the QD1 signal 2324, the QD2 signal 2326, and the QD3 signal 2328, respectively. The QD1 signal 2324 illustrated by the tenth waveform 2620 is synchronized from the quadrature-phase (Q) signal 2240 by the fourth D-type flip-flop 2310. The QD2 signal 2326 illustrated by the eleventh waveform 2622 is sampled from the QD1 signal 2324 to compensate for metastability in the QD1 signal 2324. The QD3 signal 2328 illustrated by the twelfth waveform 2624 is sampled from the QD2 signal 2326 to delay the QD2 signal 2326 by one clock cycle of the acquisition aid clock signal 2204, which is illustrated by the fifth waveform.

The QX signal 2224 illustrated by a thirteenth waveform 2626 corresponds to the logical XOR of the QD2 signal 2326 illustrated by the eleventh waveform 2622 and to the QD3 signal 2624 illustrated by the twelfth waveform 2624. In the timing diagram drawn in FIG. 26, the QD2 signal 2326 and the QD3 signal 2328 signals are consistently low, and the XOR-ing of the signals is also low as shown by the thirteenth waveform 2626.

The IX signal 2222 illustrated by the ninth waveform 2618 and the QX signal 2224 illustrated by the thirteenth waveform 2626 are applied as inputs to the RS flip-flop 2226 shown in FIG. 22. The RS flip-flop 2226 sets the RS signal 2228 to a high state when the IX signal 2204 is a high state, and the RS flip-flop 2226 sets the RS signal 2228 to a low state when the QX signal 2224 is a high state. A fourteenth waveform 2628 illustrates the RS signal 2228. The RS signal 2228 goes high, as illustrated by the fourteenth waveform 2628, in response to the pulse 2634 from the IX signal 2204, as shown by the ninth waveform 2618.

The RS signal 2228 is applied as an input to the half-wave differentiator 2212 described earlier in connection with FIG. 24. With respect to FIGS. 24 and 26, a fifteenth waveform 2630 corresponds to the RSD signal 2406 output of the D-type flip-flop 2402. The RSD signal 2406 is delayed from the RS signal 2228 by one clock cycle of the acquisition aid clock signal 2204.

A sixteenth waveform 2632 corresponds to the HWD signal 2230, which is the logical NOR of the RS signal 2228 and the RSD signal 2406. Since the reference clock signal 332 and the receiver clock signal 326 are relatively close in frequency in the example drawn in FIG. 26, the HWD signal 2230 has a relatively long duration as shown by the sixteenth waveform 2632. The relatively long duration eventually causes the timer 2206 to reach the predetermined time. The timer 2206 activates the timer output 2232 to clear or reset the fourth D-type flip-flop 2234, the fifth D-type flip-flop 2236, and the sixth D-type flip-flop 2238, thereby resetting the AA signal 328 to a low, which indicates that the reference clock signal 332 and the receiver clock signal 326 are relatively close in frequency.

FIG. 27 is a timing diagram of the acquisition aid circuit 308 of FIG. 22 with a relatively poor match between a VCO signal and a reference clock signal. Again, the horizontal axis indicates time, with time increasing to the right. With reference to FIG. 27, a first waveform 2702 corresponds to the receiver clock signal 326 from the VCO circuit 406. A second waveform 2704 corresponds to the reference clock signal 332. In the timing diagram shown in FIG. 27, the receiver clock signal 326 is slightly slower in frequency than the reference clock signal 332.

The second D-type flip-flop 2214 and the third D-type flip-flop 2216 divide the receiver clock signal 326 by two into the in-phase (I) clock signal 2218 and the quadrature-phase (Q) clock signal 2220. A third waveform 2706 corresponds to the in-phase (I) clock signal 2218 and a fourth waveform 2708 corresponds to the quadrature-phase (Q) clock signal 2220.

A fifth waveform 2710 corresponds to the acquisition aid clock signal 2204, which in the illustrated embodiment is divided by two by the first D-type flip-flop 2202 from the reference clock signal 332.

A sixth waveform 2712 corresponds to the ID1 signal 2318 of the first D-type flip-flop 2302 of the in-phase full-wave differentiator circuit 2208. The first D-type flip-flop 2302 of the in-phase full-wave differentiator circuit 2208 synchronizes the in-phase (I) clock signal 2218 with the acquisition aid clock signal 2204. During the course of the synchronization, the mismatch in frequency between the acquisition aid clock signal 2204 and the in-phase (I) clock signal 2218 results in the first D-type flip-flop 2302 sampling the in-phase (I) clock signal 2218 when the in-phase (I) clock signal 2218 is both low and high. As a result, the ID1 signal 2318 from the first D-type flip-flop 2302 oscillates or beats at a frequency approximately equal to the difference between the frequency of the acquisition aid clock signal 2204 and the in-phase (I) clock signal 2218 as shown by the sixth waveform 2712.

A seventh waveform 2714 and an eighth waveform 2716 correspond to the ID2 signal 2320 of the second D-type flip-flop 2304 and the ID3 output 2322 of the third D-type flip-flop 2306, respectively, of the in-phase full-wave differentiator circuit 2208. The second D-type flip-flop 2304 samples the ID1 signal 2318 to produce the ID2 signal 2320 shown in the seventh waveform 2714 to compensate for metastability. The eighth waveform 2716 illustrates that the ID3 output 2322 of the third D-type flip-flop 2306 is delayed from the ID2 signal 2320 by a clock cycle of the acquisition aid clock signal 2204.

A ninth waveform 2718 corresponds to the IX signal 2222, which is the logical XOR of the ID2 signal 2320 illustrated by the seventh waveform 2714 and the ID3 signal 2322 illustrated by the eighth waveform 2716. The IX signal 2222 pulses high when one of the ID2 signal 2320 or the ID3 signal 2322 is a high level and the other is a low level as illustrated by the ninth waveform 2718. This typically results in the IX signal 2222 oscillating at twice the frequency of the ID2 signal 2320 or the ID3 signal 2322 by pulsing at both the rising edge and the falling edge of the ID2 signal 2320.

A tenth waveform 2720, an eleventh waveform 2722, and a twelfth waveform 2724 correspond to the QD1 signal 2324, the QD2 signal 2326, and the QD3 signal 2328, respectively. The QD1 signal 2324 illustrated by the tenth waveform 2720 is synchronized from the quadrature-phase (Q) signal 2240 by the fourth D-type flip-flop 2310. The mismatch in frequency between the acquisition aid clock signal 2204 and the quadrature-phase (Q) clock signal 2220 results in the fourth D-type flip-flop 2310 sampling the quadrature-phase (Q) clock signal 2220 when the quadrature-phase (Q) clock signal 2220 is both low and high. As a result, the QD1 signal 2318 from the fourth D-type flip-flop 2310 oscillates or beats at a frequency approximately equal to the difference between the frequency of the acquisition aid clock signal 2204 and the quadrature-phase (Q) clock signal 2220 as shown by the tenth waveform 2720.

The QD2 signal 2326 illustrated by the eleventh waveform 2722 is sampled from the QD1 signal 2324 to compensate for metastability in the QD1 signal 2324. The QD3 signal 2328 illustrated by the twelfth waveform 2724 is sampled from the QD2 signal 2326 to delay the QD2 signal 2326 by one clock cycle of the acquisition aid clock signal 2204.

The QX signal 2224 illustrated by a thirteenth waveform 2726 corresponds to the logical XOR of the QD2 signal 2326 illustrated by the eleventh waveform 2722 and the QD3 signal 2724 illustrated by the twelfth waveform 2724. The QX signal 2224 pulses high when one of the QD2 signal 2326 or the QD3 signal 2328 is a high level and the other is a low level. This typically results in the QX signal 2224 oscillating at twice the frequency of the QD2 signal 2326 or the QD3 signal 2328 by pulsing at both the rising edge and the falling edge of the QD2 signal 2326.

The IX signal 2222 illustrated by the ninth waveform 2718 and the QX signal 2224 illustrated by the thirteenth waveform 2726 are applied as inputs to the RS flip-flop 2226 shown in FIG. 22. The RS flip-flop 2226 sets the RS signal 2228 to a high state when the IX signal 2204 is a high state, and the RS flip-flop 2226 sets the RS signal 2228 to a low state when the QX signal 2224 is a high state. A fourteenth waveform 2728 illustrates the RS signal 2228. The RS signal 2228 goes high, as illustrated by the fourteenth waveform 2728, in response to a high level of the IX signal 2204, which is shown by the ninth waveform 2718.

The RS signal 2228 is applied as an input to the half-wave differentiator 2212 described earlier in connection with FIG. 24. With respect to FIGS. 24 and 27, a fifteenth waveform 2730 corresponds to the RSD signal 2406 output of the D-type flip-flop 2402. The RSD signal 2406 is delayed from the RS signal 2228 by one clock cycle of the acquisition aid clock signal 2204.

A sixteenth waveform 2732 corresponds to the HWD signal 2230, which is the logical NOR of the RS signal 2228 and the RSD signal 2406. Since the reference clock signal 332 and the receiver clock signal 326 are relatively close in frequency in the example drawn in FIG. 27, the HWD signal 2230 has a relatively short low duration as shown by the sixteenth waveform 2732. The relatively short duration resets the timer 2206 before the timer 2206 reaches the predetermined time. Where the timer 2206 is reset repeatedly before the timer 2206 reaches the predetermined time, a high logic level propagates through the fourth D-type flip-flop 2234, through the fifth D-type flip-flop 2236, and through the sixth D-type flip-flop 2238, all of FIG. 22, and sets the AA signal 328 to a high logic level. In the illustrated embodiment of the acquisition aid circuit 308, a high on the AA signal 328 indicates that the reference clock signal 332 and the receiver clock signal 326 are relatively far apart in frequency. In one embodiment, the Rx PLL and CDR circuit 306 switches from the first path 424 to a second path 426 at least partly in response to a high on the AA signal 328.

FIG. 28 illustrates one embodiment of a framer circuit 312. The framer circuit 312 receives the fully demultiplexed data 338 from the demultiplexer circuit 310 and uses the frame headers within the data to align the data in accordance with a predetermined standard, such as the SONET standard. The framer circuit 312 also performs data integrity checking operations such as parity checking and run length limited operations, and extracts the raw data and the frame header components from the fully demultiplexed data 338.

The illustrated framer circuit 312 includes a first set of D-type flip-flops 2802, a second set of D-type flip-flops 2804, a run length limited circuit 2806, a pattern search circuit 2808, a parity check circuit 2810, a first multiplexer set 2812, a second multiplexer set 2814, a first decoder 2816, a second decoder 2818, a third set of D-type flip-flops 2820, a fourth set of D-type flip-flops 2822, and a byte detect circuit 2824.

The first set of D-type flip-flops 2802 samples the fully demultiplexed data 338, which is a 16-bit wide data path, with the receiver clock signal 326. In one embodiment, the first set of D-type flip-flops 2802 includes 16 D-type flip-flops, each of which are configured to sample a bit of the fully demultiplexed data 338 at the rising edge of the receiver clock signal 326. An output of the first set of D-type flip-flops 2802 is an A data bus 2826, which is 16 bits wide in the illustrated embodiment and is labeled A[15:0] on the schematic. Of course, the A data bus 2826 can be single-ended or differential.

The A data bus 2826 is applied as an input to the second set of D-type flip-flops 2804, the run length limited circuit 2806, the pattern search circuit 2808, the first multiplexer set 2812 and the second multiplexer set 2814. The second set of D-type flip-flops 2804 samples the A data bus 2826 at the rising edge of the receiver clock signal 326 to generate a B data bus 2828, which is delayed from the A data bus 2826 by one receiver clock signal 326 clock cycle. The B data bus 2828 is also 16 bits wide. By accessing both the A data bus 2826 and the B data bus 2828, the framer circuit 312 can access 32 contiguous bits of data.

The run length limited circuit 2806 receives the A data bus 2826, the AA signal 328, and a receiver data valid signal 333. The AA signal 328 from the acquisition aid circuit 308 indicates whether the reference clock signal 332 and the receiver clock signal 326 are relatively closely matched. The receiver data valid signal 333 is received from a downstream external circuit, such as a circuit in the local interface 214, which performs error checking operations on the parallel output data, RPDAT 344 and indicates via the receiver data valid signal 333 whether the data received matches with checksums, cyclic redundancy codes (CRCs) and the like. The run length limited circuit 2806 also inspects the A data bus 2826 for strings of continuous ones or zeroes. When data is properly received, the serial data (RSDAT) 320 includes both ones and zeroes. Where, for example, a fiber optic cable, a laser, or an optical receiver has been rendered inoperable, the serial data 320 may contain a relatively large number of continuous ones or zeroes. In one embodiment, the run length limited circuit 2806 detects an error when a run of at least 16 consecutive zeroes or 16 consecutive ones has been detected.

Where the serial data 320 includes more than a predetermined number of ones and zeroes, or the receiver data valid signal 333 indicates that the downstream data is flawed, or the AA signal 328 indicates a relatively large mismatch in synchronization between the serial data 320 and the reference clock signal 332, the run length limited circuit 2806 deactivates a lock signal 358. The run length limited circuit 2806 activates the lock signal 358 in response to the receiver data valid signal 333 indicating an absence of detected errors in the parallel output data 344, the AA signal 328 indicating a relatively close match between the reference clock signal 332 and a clock signal generated by the VCO circuit 406, and the run length limited circuit 2806 itself not detecting a problem with a string of continuous ones or zeroes. Of course, the run length limited circuit 2806 can also inspect data at another point, such as at the B data bus 2828.

The lock signal 358 is applied as an input to the output register circuit 314, which activates and deactivates the receiver lock detected signal 330 in response to an activation and deactivation of the lock signal 358. When the receiver lock detected signal 330 is activated, the Rx PLL and CDR circuit 306 selects the first path 424 to synchronize the VCO circuit 406 to the serial data 320. When the receiver lock detected signal 330 is deactivated, the Rx PLL and CDR circuit 306 selects the second path 426 to synchronize the VCO circuit 406 to the reference clock 332.

The pattern search circuit 2808 receives bits 5 through 14 of the A data bus 2826 to search for an F6(h) pattern or a 6F(h) pattern. The detection of the F6(h) pattern or the 6F(h) pattern in bits 5 through 14 of the A data bus 2826 indicates that the fully demultiplexed data 338 received by the first set of D-type flip-flops 2802 is misaligned by 1, 2, 3, 5, 6, or 7 bits. The absence of the detection of the F6(h) pattern or the 6F(h) pattern in bits 5 through 14 of the A data bus 2826 indicates that the fully demultiplexed data 338 is aligned or that the fully demultiplexed data 338 is misaligned by 4 bits.

The F6(h) and/or the 6F(h) are part of the message header in the SONET format and are used to align the serial data 320 to byte boundaries so that the synchronized aligned data 336 (POUT[15:0]) is provided in a predictable format. The pattern search circuit 2808 generates control signals e1 2840, e0 2838, c1 2844, and c0 2842 as outputs as will be described in greater detail later in connection with Table VI. The control signals e1 2840, e0 2838, c1 2844, and c0 2842 provide shift information to the first decoder 2816 and to the second decoder 2818, which further control the second multiplexer set 2814 and the first multiplexer set 2812, respectively, to shift the data by 0, 1, 2, or 3 bits to align the synchronized aligned data 336. Of course, shifting the data by 0 bits is the same as not shifting the data.

The first decoder 2816 receives the control signals e1 2840 and e0 2838 as inputs and generates a 4-bit shifta[3:0] signal 2846. In one embodiment, in response to a low and a low on the control signals e1 2840 and e0 2838, respectively, the first decoder 2816 activates bit 0 of the shifta[3:0] signal 2846, which is applied as an input to the second multiplexer set 2814. In response to activation of bit 0 of the shifta[3:0] signal 2846, the second multiplexer set 2814 allows data to pass directly from the B data bus 2828 to a D data bus 2832 without a bit shift.

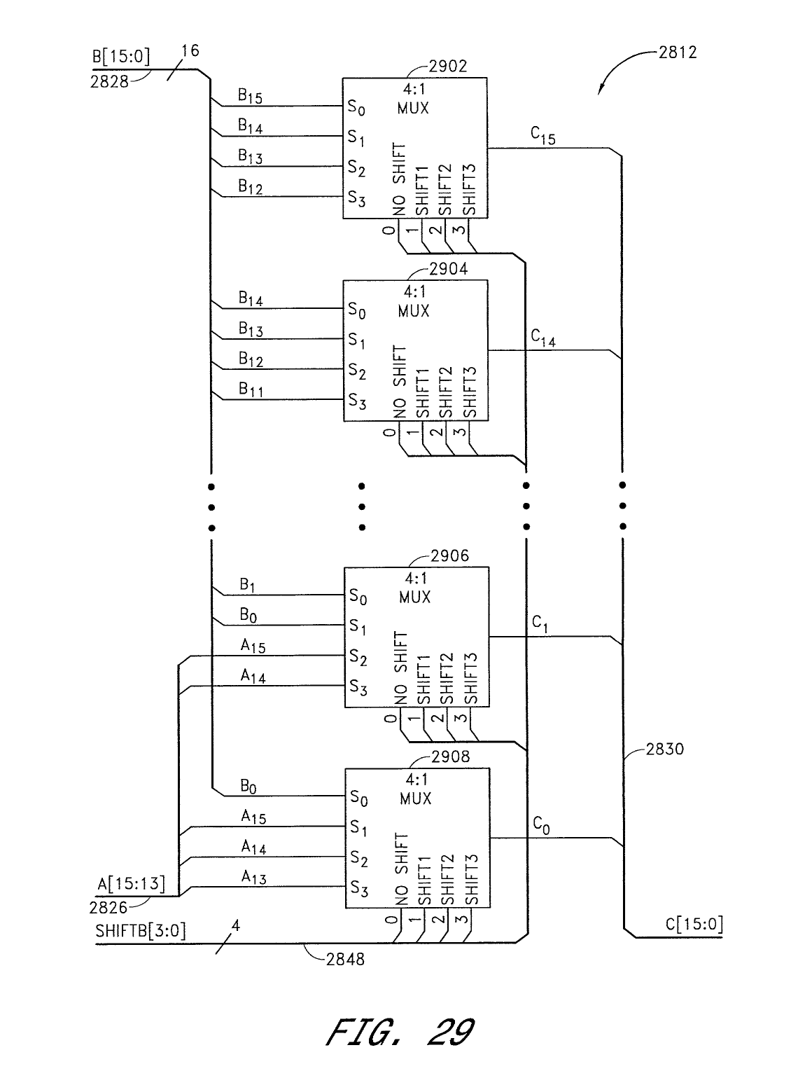

Similarly, when the first decoder 2816 receives a low and a high, a high and a low, and a high and a high on the control signals e1 2840 and e0 2838, the first decoder 2816 activates bit 3 of the shifta[3:0] signal 2846, bit 1 of the shifta[3:0] signal 2846, and bit 2 of the shifta[3:0] signal 2846, respectively. In response to activation of bit 3, bit 1, and bit 2 of the shifta[3:0] signal 2846, the second multiplexer set 2814 shifts a combined data from a portion of the A data bus 2826 and a portion of the B data bus 2828 by 3 bits to the right, 1 bit to the right, and 2 bits to the right, respectively, to generate the D data bus 2832. Further details of the bit shifting are described later in connection with FIG. 29.

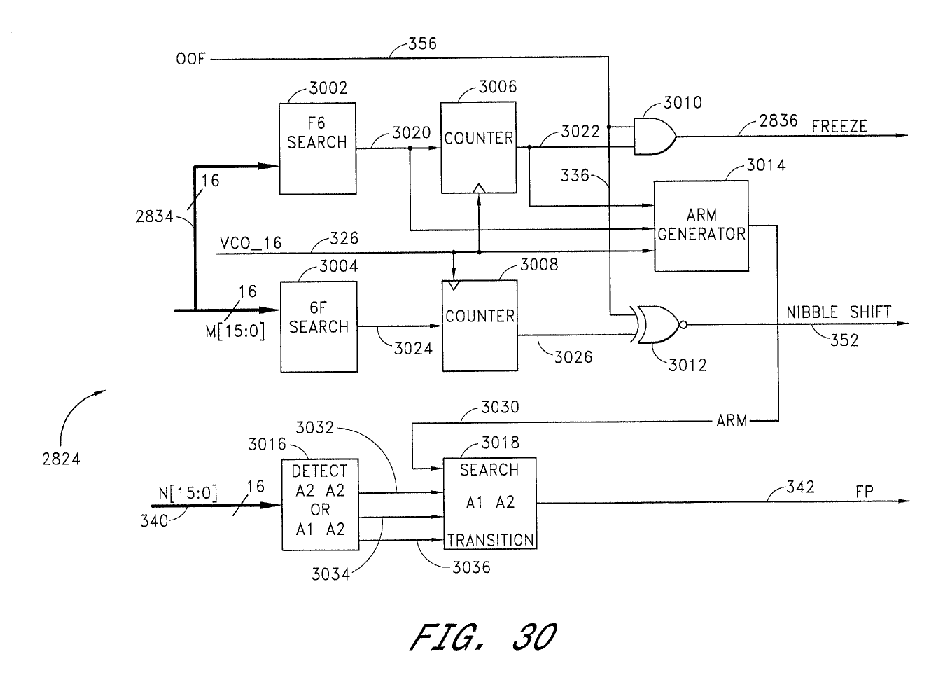

In the illustrated embodiment of the receiver 302, larger shifts of data for alignment, i.e., shifts by 4 bits or a nibble, are performed by the Rx PLL and CDR circuit 306 in response to a nibble shift signal 352 from the byte detect circuit 2824. Further details of the byte detect circuit 2824 including generation of the nibble shift signal 352 will be described later in connection with FIG. 30.

The pattern search circuit 2808 searches multiple bit patterns for the F6(h) or 6F(h) pattern. Table VI illustrates a truth table of the pattern search circuit 2808, the first decoder 2816, and the second decoder 2818.

TABLE VI

| | State | State | State | State | State | State | |
|---|---|---|---|---|---|---|---|
| data bit | 1 | 2 | 3 | 4 | 5 | 6 | Other |
| A₁₄ | 1 | X | X | 0 | X | X | — |
| A₁₃ | 1 | 1 | X | 1 | 0 | X | |
| A₁₂ | 1 | 1 | 1 | 1 | 1 | 0 | — |
| A₁₁ | 1 | 1 | 1 | 0 | 1 | 1 | — |
| A₁₀ | 0 | 1 | 1 | 1 | 0 | 1 | |
| A₉ | 1 | 0 | 1 | 1 | 1 | 0 | — |
| A₈ | 1 | 1 | 0 | 1 | 1 | 1 | — |
| A₇ | 0 | 1 | 1 | 1 | 1 | 1 | — |
| A₆ | X | 0 | 1 | X | 1 | 1 | |
| A₅ | X | X | 0 | X | X | 1 | — |
| Shift Right | 1 | 2 | 3 | 1 | 2 | 3 | 0 |
| by (bits): | | | | | | | |
| e1 | 1 | 1 | 0 | 1 | 1 | 0 | 0 |
| e0 | 0 | 1 | 1 | 0 | 1 | 1 | 0 |
| No Shift | 0 | 0 | 0 | 0 | 0 | 0 | 1 |
| Shift1 | 1 | 0 | 0 | 1 | 0 | 0 | 0 |
| Shift2 | 0 | 1 | 0 | 0 | 1 | 0 | 0 |
| Shift3 | 0 | 0 | 1 | 0 | 0 | 1 | 0 |

As illustrated by Table VI, the pattern search circuit 2808 generates a high on the e1 signal 2840 and a low on the e0 signal 2838 in response to a detection of State 1 or State 4, which results in a shift to the right by one bit. An “X” in Table VI indicates a don't care. Similarly, the pattern search circuit 2808 generates a high on both the e1 signal 2840 and on the e0 signal 2838 in response to a detection of State 2 or State 5, which results in a shift to the right by two bits. The pattern search circuit 2808 generates a low on the e1 signal 2840 and a high on the e0 signal 2838 in response to a detection of State 3 or State 6, which results in a shift to the right by three bits. Where none of States 1 through 6 are detected, the fully demultiplexed data 338 is aligned or is misaligned by a nibble and the pattern search circuit 2808 generates a low on both the e1 signal 2840 and the e0 signal 2838, which results in no shift.

In one embodiment, State 1 is detected by detecting that bits A₁₁ to A₁₄ are high, State 2 is detected by detecting that bits A₁₀ to A₁₃ are high, State 3 is detected by detecting that bits A₉ to A₁₂ are high, State 4 is detected by detecting that bits A₇ to A₁₀ are high, State 5 is detected by detecting that bits A₆ to A₉ are high, and State 6 is detected by detecting that bits A₅ to A₈ are high.

In one embodiment, the e1 signal 2840 and the e0 signal 2838 are generated by computation of the Boolean formulas expressed in Equations 1 and 2, respectively.

e1=A₁₄·A₁₃·A₁₂·A₁₁+A₁₃·A₁₂·A₁₁·A₁₀+A₁₀·A₉·A₈·A₇+A₉·A₈·A₇·A₆ Eq. 1

e0=A₁₃·A₁₂·A₁₁·A₁₀+A₁₂·A₁₁·A₁₀·A₁₉+A₉·A₈·A₇·A₆+A₈·A₇·_{A}₆·A₅ Eq. 2

The pattern search circuit 2808 also receives a freeze signal 2836 as an input from the byte detect circuit 2824. Upon activation of the freeze signal 2836, the pattern search circuit 2808 mirrors the control signals c1 2844 and c0 2842 with the control signals e1 2840 and e0 2838, respectively, so that the first multiplexer set 2812 and the second multiplexer set 2814 shift by the same amount. The second decoder 2818 receives the control signals c1 2844 and c0 2842 as inputs and generates a 4-bit shiftb[3:0] signal 2848 to decode the c1 2844 and c0 2842 control signals. One embodiment of the second decoder 2818 decodes the c1 2844 and c0 2842 control signals to the shiftb[3:0] signal 2848 in the same manner as described for the e1 2840 and c1 2844 control signals for the shifta[3:0] signal 2846.

Where the freeze signal 2836 is not activated, the pattern search circuit 2808 maintains the control signals c1 2844 and c0 2842 at their previous states prior to deactivation of the freeze signal 2836. In one embodiment, the second decoder 2818 is a copy of the circuit used for the first decoder 2816, and the second multiplexer set 2814 is a copy of the circuit used for the first multiplexer set 2812.

The parity check circuit 2810 computes the parity (odd or even) of the serial data by computing the parity of the B data bus 2828. Of course, the parity of the data can be computed by receiving the data at another point, such as by computing the parity of the A data bus 2826 or at a C data bus 2830. In one embodiment, computation of an odd parity activates a parity error signal 334, which is synchronized to a parity output signal 354 (PAROUT) by the output register circuit 314, and indicates that the data provided by the receiver 300 is corrupted.

The first multiplexer set 2812 receives the B data bus 2828 and bits 13 to 15 of the A data bus 2826 as inputs, receives the shiftb[3:0] signal 2848 as a control input, and generates the C data bus 2830 as an output. With bits 0, 1, 2, and 3 of control input shiftb[3:0] 2848 corresponding to no shift, shift right 1 bit, shift right 2 bits, and shift right 3 bits, respectively, Table VII illustrates the mapping from the B data bus 2828 and bits 13 to 15 of the A data bus 2826 to the C data bus 2830 in response to the control inputs. One embodiment of the first multiplexer set 2812 is described in further detail later in connection with FIG. 29.

TABLE VII

| Mux Input | No Shift | Shift 1 | Shift 2 | Shift 3 |
|---|---|---|---|---|
| B₁₅ | C₁₅ | — | — | — |
| B₁₄ | C₁₄ | C₁₅ | — | — |
| B₁₃ | C₁₃ | C₁₄ | C₁₅ | — |
| B₁₂ | C₁₂ | C₁₃ | C₁₄ | C₁₅ |
| B₁₁ | C₁₁ | C₁₂ | C₁₃ | C₁₄ |
| B₁₀ | C₁₀ | C₁₁ | C₁₂ | C₁₃ |
| B₉ | C₉ | C₁₀ | C₁₁ | C₁₂ |
| B₈ | C₈ | C₉ | C₁₀ | C₁₁ |
| B₇ | C₇ | C₈ | C₉ | C₁₀ |
| B₆ | C₆ | C₇ | C₈ | C₉ |
| B₅ | C₅ | C₆ | C₇ | C₈ |
| B₄ | C₄ | C₅ | C₆ | C₇ |
| B₃ | C₃ | C₄ | C₅ | C₆ |
| B₂ | C₂ | C₃ | C₄ | C₅ |
| B₁ | C₁ | C₂ | C₃ | C₄ |
| B₀ | C₀ | C₁ | C₂ | C₃ |
| A₁₅ | — | C₀ | C₁ | C₂ |
| A₁₄ | — | — | C₀ | C₁ |
| A₁₃ | — | — | — | C₀ |

The second multiplexer set 2814 receives the B data bus 2828 and bits 13 to 15 of the A data bus 2826 as inputs, and the second multiplexer set 2814 maps the inputs to a D data bus 2832 in response to shifta[3:0] 2846 control inputs. In one embodiment, the second multiplexer set 2814 is a duplicate of the first multiplexer set 2812. Table VIII illustrates the mapping from the B data bus 2828 and bits 13 to 15 of the A data bus 2826 to the C data bus 2830 in response to the control inputs. With bits 0, 1, 2, and 3 of control input shiftb[3:0] 2848 corresponding to no shift, shift right 1 bit, shift right 2 bits, and shift right 3 bits, respectively, Table VII illustrates the mapping from the B data bus 2828 and bits 13 to 15 of the A data bus 2826 to the C data bus 2830 in response to the control inputs.

TABLE VIII

| Mux Input | No Shift | Shift 1 | Shift 2 | Shift 3 |
|---|---|---|---|---|
| B₁₅ | D₁₅ | — | — | — |
| B₁₄ | D₁₄ | D₁₅ | — | — |
| B₁₃ | D₁₃ | D₁₄ | D₁₅ | — |
| B₁₂ | D₁₂ | D₁₃ | D₁₄ | D₁₅ |
| B₁₁ | D₁₁ | D₁₂ | D₁₃ | D₁₄ |
| B₁₀ | D₁₀ | D₁₁ | D₁₂ | D₁₃ |
| B₉ | D₉ | D₁₀ | D₁₁ | D₁₂ |
| B₈ | D₈ | D₉ | D₁₀ | D₁₁ |
| B₇ | D₇ | D₈ | D₉ | D₁₀ |
| B₆ | D₆ | D₇ | D₈ | D₉ |
| B₅ | D₅ | D₆ | D₇ | D₈ |
| B₄ | D₄ | D₅ | D₆ | D₇ |
| B₃ | D₃ | D₄ | D₅ | D₆ |
| B₂ | D₂ | D₃ | D₄ | D₅ |
| B₁ | D₁ | D₂ | D₃ | D₄ |
| B₀ | D₀ | D₁ | D₂ | D₃ |
| A₁₅ | — | D₀ | D₁ | D₂ |
| A14 | — | — | D₀ | D₁ |
| A13 | — | — | — | D₀ |

The third set of D-type flip-flops 2820 and the fourth set of D-type flip-flops 2822 generate an N data bus 340 and an M data bus 2834, respectively, by synchronizing the C data bus 2830 and the D data bus 2832, respectively, to the receiver clock signal 326. The N data bus 340 is applied as an input to the byte detect circuit 2824 and to the output register circuit 314. The M data bus 2834 is applied as an input to the byte detect circuit 2824.

FIG. 29 illustrates one embodiment of the first multiplexer set 2812. The illustrated first multiplexer set 2812 includes sixteen 4:1 multiplexers so that there is one 4:1 multiplexer for each bit of the C data bus 2828. Each 4:1 multiplexer is configured to receive a contiguous 4-bit portion of the B data bus 2828 and bits 13 to 15 of the A data bus 2826. With reference to FIG. 29, a first multiplexer 2902 is configured to receive the first 4 bits of the B data bus 2828, i.e., configured to receive bits B₁₅, B₁₄, B₁₃, and B₁₂. The first multiplexer 2902 receives the shiftb[3:0] signal 2848 as a control input, and selects bit B₁₅, B₁₄, B₁₃, or B₁₂ for bit C₁₅ in response to activation of shiftb₀, shiftb₁, shiftb₂, or shiftb₃, respectively.

Similarly, a second multiplexer 2904 is configured to receive the next 4 bits of the B data bus 2828, where 3 of the next 4 bits overlap with the 4 bits applied to the first multiplexer 2902. The second multiplexer 2904 also receives the shiftb[3:0] signal 2848 as a control input, and selects bit B₁₄, B₁₃, B₁₂, or B₁₁ for bit C₁₄ in response to activation of shiftb₀, shiftb₁, shiftb₂, or shiftb₃, respectively.

The remaining multiplexers in the first multiplexer set 2812 are similarly configured. To illustrate, a third multiplexer 2906 generates bit C₁ and a fourth multiplexer 2908 generates bit C₀. The bits B₁ and B₀ of the B data bus 2828 and the bits A₁₅ and A₁₄ of the A data bus 2826 are applied as inputs to the third multiplexer 2906. In response to activation of control inputs shiftb₀, shiftb₁, shiftb₂, or shiftb₃, the third multiplexer 2906 selects the bit B₁, B₀, A₁₅, or A₁₄ to generate bit C₁.

With respect to the fourth multiplexer 2908, the B₀ bit of the B data bus 2828 and the bits A₁₅, A₁₄, and A₁₃ of the A data bus 2826 are applied as inputs. In response to activation of control inputs shiftb₀, shiftb₁, shiftb₂, or shiftb₃, the fourth multiplexer 2908 selects the bit B₀, A₁₅, A₁₄, or A₁₃ to generate bit C₀.

FIG. 30 illustrates one embodiment of the byte detection circuit 2824. The byte detection circuit 2824 detects whether the D data bus 2832 aligned by the second multiplexer set 2814 is aligned or is misaligned by a nibble, enables realignment by the first multiplexer set 2812 and the second multiplexer set 2814 by generation of the freeze signal 2836, and decodes frame header information to indicate A1 and A2 frame transitions.

With reference to FIG. 30, the illustrated byte detection circuit 2824 includes an F6 search circuit 3002, a 6F search circuit 3004, a first counter 3006, a second counter 3008, an AND gate 3010, an XNOR gate 3012, an ARM generator 3014, an A1A2/A2A2 detect circuit 3016, and an A1A2 transition circuit 3018.

The F6 search circuit 3002 receives the M data bus 2834 from the fourth set of D-type flip-flops 2822. In a SONET system, each frame contains A1 and A2 framing bytes. The A1 byte and the A2 byte are encoded as F6(h) and 28(h), respectively. The A1 and A2 framing bytes indicate the beginning of frames. The number of A1 and A2 framing bytes per frame depends on the speed of the SONET system. In an OC-48 system, each frame starts with 48 A1 bytes and then transitions to 48 A2 bytes. In an OC-192 system, each frame starts with 192 A1 bytes and then transitions to 192 A2 bytes.

The contents of the 16-bit M data bus 2834 can be shifted by the second multiplexer set 2814. The F6 search circuit 3002 activates an F6 detect signal 3020 in response to a detection of an F6(h) pattern in bits M₁₅ to M₈ in the M data bus 2834, i.e., M[15:0]=1111 0110 XXXX XXXX (b). The F6 detect signal 3020 is applied as an input to the first counter 3006 and to the ARM generator 3014.

The first counter 3006 is triggered by the receiver clock signal 326 and counts consecutive instances of the F6(h) pattern detected by the F6 search circuit 3002. When the F6 search circuit 3002 detects an absence of the F6(h) pattern and deactivates the F6 detect signal 3020, the first counter 3006 resets. When the F6 detect signal 3020 remains active in response to the detection of at least a predetermined number of consecutive F6(h) patterns detected by the F6 search circuit 3002, the first counter 3006 activates a consecutive F6 signal 3022. In one embodiment, the first counter 3006 activates the consecutive F6 signal 3022 in response to a count of 16 consecutive F6 detections. Of course, where only every other byte is detected, 16 consecutive F6 detections will correspond to approximately 32 consecutive F6 detections. The first counter 3006 applies the consecutive F6 signal 3022 as an input to the AND gate 3010 and the ARM generator 3014.

The AND gate 3010 receives an out of frame (OOF) signal 356 and the consecutive F6 signal 3022 as inputs. The out of frame signal 356 is provided from an external circuit, such as from a circuit in the local interface 214, and is activated upon the detection of an error in the framing pattern and deactivated in response to a detection of correct framing. In one embodiment, the out of frame signal 356 is active high in response to a detection of correct framing and is active low in response to an out of frame condition.

The AND gate 3010 receives a high state indicating correct framing of the out of frame signal 356 and in response, activates the freeze signal 2836. Activation of the freeze signal 2836, which is applied as an input to the pattern search circuit 2808, prevents the pattern search circuit 2808 from shifting bits by one, two, or three bits, as the bits are aligned within the byte.

Similarly, a low state of the out of frame signal 356, which indicates correct framing, causes the XNOR gate 3012 to deactivate the nibble shift signal 352. Correct framing, as indicated by the high state of the out of frame signal 356, prevents the inadvertent detection of multiple 6F patterns from activating the nibble shift signal 352.

The ARM generator 3014 receives as inputs the consecutive F6 signal 3022, the F6 detect signal 3020, and the receiver clock signal 326. In the illustrated embodiment, the ARM generator 3014 activates an ARM signal 3030 one receiver clock signal 326 clock cycle after the consecutive F6 signal 3022 is asserted, and deactivates the ARM signal 3030 one receiver clock signal 326 clock cycle after a detection of an absence of the F6(h) pattern by the F6 search circuit.

The 6F search circuit 3004 also receives the M data bus 2834 from the fourth set of D-type flip-flops 2822. The 6F search circuit 3004 activates a 6F detect signal 3024 in response to a detection of a 6F(h) pattern in bits M₁₅ to M₈ in the M data bus 2834, i.e., M[15:0]=0110 1111 XXXX XXXX (b). The detection of the 6F(h) pattern indicates that the data is misaligned by a nibble or 4 bits. The 6F detect signal 3024 is applied as an input to the second counter 3008.

The second counter 3008 is triggered by the receiver clock signal 326 and counts consecutive instances of the 6F(h) pattern detected by the 6F search circuit 3004. When the 6F search circuit 3004 detects an absence of the 6F(h) pattern and deactivates the 6F detect signal 3024, the second counter 3008 resets. When the 6F detect signal 3024 remains active in response to the detection of at least a predetermined number of consecutive 6F(h) patterns detected by the 6F search circuit 3004, the second counter 3008 activates a consecutive 6F signal 3026. In one embodiment, the second counter 3008 activates the consecutive 6F signal 3026 in response to a count of 16 consecutive 6F detections. The second counter 3008 applies the consecutive 6F signal 3026 as an input to the XNOR gate 3012.

The XNOR gate 3012 receives the out of frame signal 356 and the consecutive 6F signal 3026 as inputs. When the out of frame signal 356 is activated and the state of the consecutive 6F signal 3026 indicates that at least the predetermined number of consecutive detections of the 6F(h) pattern have been detected, the XNOR gate 3012 activates the nibble shift signal 352 to the phase detector circuit 402 so that the phase detector circuit 402 shifts demultiplexing of the serial data 320 by 4 bits as described earlier in connection with FIG. 6. In one embodiment, the receiver 302 inverts the phases of the eight-phase clock signals 606, 607, 608, 609, 610, 611, 612, 613 to shift by a nibble. In another embodiment, the receiver 302 shifts a nibble by shifting data via a set of multiplexers. In one embodiment, the nibble shift signal 352 is active low, though it will be understood by one of ordinary skill in the art that the nibble shift signal 352 can be either active low or active high.

The A1A2/A2A2 detect circuit 3016 detects the framing bytes defined by the applicable transmission system, such as SONET. In one embodiment, the byte detect circuit 2824 provides an FP signal 342, which is supplied externally to provide an indication that the receiver 302 has detected a transition between the A1 framing bytes and the A2 framing bytes.

The A1A2/A2A2 detect circuit 3016 receives the aligned data 340 as an input. In response to a detection of the A1 byte or F6(h) in the high byte, i.e., bits N₁₅ to N₈, the A1A2/A2A2 detect circuit 3016 activates an A1 high byte signal 3032. In response to a detection of the A2 byte or 28(h) in the high byte, the A1A2/A2A2 detect circuit 3016 activates an A2 high byte signal 3034. In response to a detection of the A2 byte or 28(h) in the low byte, i.e., bits N₇ to N₀, the A1A2/A2A2 detect circuit 3016 activates an A2 low byte signal 3036.

The A1 high byte signal 3032, the A2 high byte signal 3034, and the A2 low byte signal 3036 from the A1A2/A2A2 detect circuit 3016 are applied as inputs to the A1A2 transition circuit 3018. The ARM signal 3030 from the ARM generator 3014 is also applied as an input to the A1A2 transition circuit 3018. When the A1A2 transition circuit 3018 is “armed” or enabled by an active ARM signal 3030 signal, the A1A2 transition circuit 3018 monitors the A1 high byte signal 3032, the A2 high byte signal 3034, and the A2 low byte 3036 for the A1 frame byte to A2 frame byte transition. If the ARM signal 3030 is not active, the A1A2 transition circuit 3018 deactivates the FP signal 342. When the A1A2 transition circuit 3018 is enabled, the A1A2 transition circuit 3018 activates the FP signal 342 when both the A1 high byte signal 3032 and A2 low byte signal 3036 are active, or when both the A2 high byte signal 3034 and the A2 low byte signal 3036 are active, i.e., when the aligned data 340 corresponds to either the A1A2 word F628(h) or the A2A2 word 2828(h).

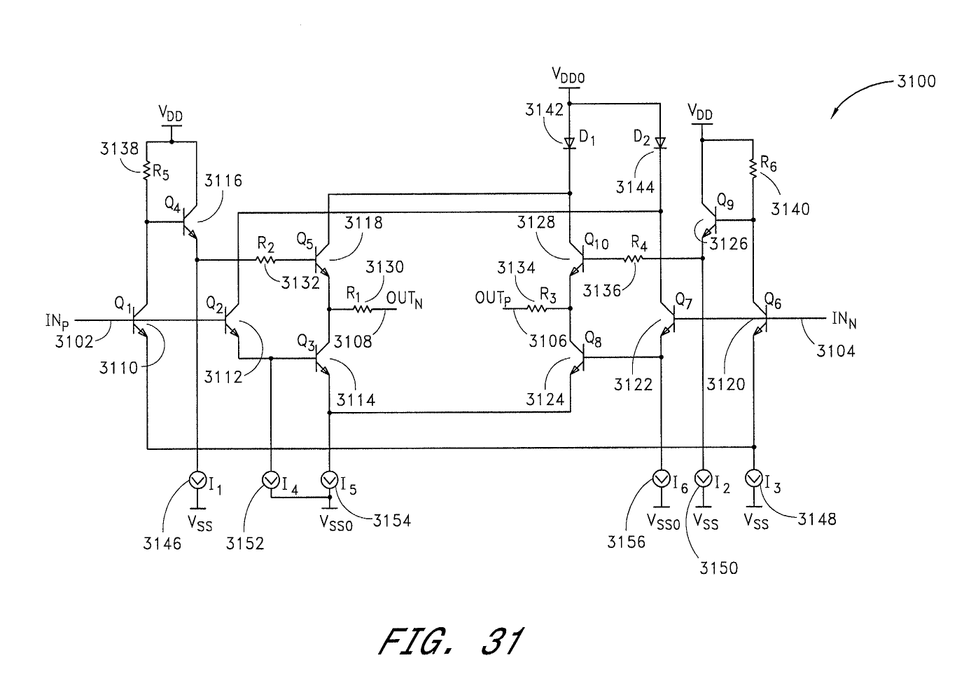

FIG. 31 illustrates one embodiment of a low voltage differential signaling (LVDS) buffer circuit 3100. The LVDS buffer circuit 3100 can be used throughout the illustrated transceiver 300, as well as in other data communications circuits as a driver. The LVDS buffer circuit 3100 advantageously allows relatively high-frequency data communication and relatively low power consumption.

The LVDS standard is somewhat defined by at least two standards. A first standard, ANSI/TIA/EIA-644 from the American National Standards Institute, Telecommunications Industry Association, and the Electronic Industries Association, describes certain aspects of the LVDS. A second standard, IEEE 1596.3 from the Institute for Electrical and Electronics Engineering, also describes some aspects of the LVDS. A typical output swing for an LVDS buffer is from about ±250 millivolts (mV) to about ±450 mV. A typical LVDS signal is terminated with about 100 ohms of resistance. A typical common mode voltage range is about ±1 volt around the LVDS buffer's offset voltage.

The LVDS buffer circuit 3100 accepts a differential input signal IN_{P} 3102 and IN_{N} 3104, and produces a differential output signal OUT_{P} 3106 and OUT_{N} 3108. The LVDS buffer circuit 3100 can be combined with another circuit, such as the single-ended to differential input buffer 1900 described in connection with FIG. 19, to receive a single-ended input and convert the single-ended input to an LVDS compatible output.

The LVDS buffer circuit 3100 uses two connections to power, V_{DD} and V_{DDO}, and uses two connections to ground, V_{SS} and V_{SSO}. In the illustrated embodiment, both V_{DD} and V_{DDO} refer to about 3.3 volts, and V_{SS} and V_{SSO} are both at ground potential. However, the biases and the ground connections are divided to prevent the relatively large currents of the output stage from generating relatively large voltage drops on conductors that would otherwise be shared with more sensitive stages such as an input stage of the LVDS buffer circuit 3100. In one embodiment, V_{DD} is within the range of 3.3 volts, ±5%. In another embodiment, V_{DD} is within the range of 3.3 volts, ±10%.

With reference to FIG. 31, the LVDS buffer circuit 3100 includes a first current sink I₁ 3146, a second current sink I₂ 3150, and a third current sink I₃ 3148, which are coupled to the V_{SS} connection to ground. The LVDS buffer circuit 3100 also includes a fourth current sink I₄ 3152, a fifth current sink I₅ 3154, and a sixth current sink I₆ 3156, which are coupled to the V_{SSO} connection to ground. In one embodiment, the first current sink I₁ 3146 and the second current sink I₂ 3150 each sink about 100 microamps (μA) of current, the third current sink I₃ 3148 sinks about 200 μA of current, the fourth current sink I₄ 3152 and the sixth current sink I₆ 3156 each sink about 500 μA, and the fifth current sink I₅ 3154 sinks about 5 milliamps (mA). In one embodiment, the above-referenced current sinks are selected to be within a range of about ±20%.

A first input stage of the LVDS buffer circuit 3100 includes a first transistor Q₁ 3110 and a second transistor Q₂ 3112. A second input stage of the LVDS buffer circuit 3100 includes a sixth transistor Q₆ 3120 and a seventh transistor Q₇ 3122. The first transistor Q₁ 3102 of the first input stage and the sixth transistor Q₆ 3120 of the second input stage share the third current source I₃ 3148.

The first input stage receives the non-inverted input signal IN_{P} 3102 to the base of the first transistor Q₁ 3110 and the base of the second transistor Q₂ 3112. Similarly, the second input stage receives the inverted input signal IN_{N} 3104 to the base of the sixth transistor Q₆ 3120 and to the base of the seventh transistor Q₇ 3122. The collectors of the first transistor Q₁ 3110 and of the sixth transistor Q₆ are out of phase with respect to their respective bases, and thereby invert the non-inverted input signal IN_{P} 3102 and the inverted input signal IN_{N} 3104, respectively.

The operation of the LVDS buffer circuit 3100 will first be described with the input high and will later be described with the input low. When the input to the LVDS buffer circuit 3100 is high so that the non-inverted input signal IN_{P} 3102 is high relative to the inverted input signal IN_{N} 3104, the collector of the first transistor Q₁ sinks relatively more current from a first terminal of a fifth resistor R₅ 3138 and the base of a fourth transistor Q₄ 3116 to the third current sink I₃ 3148. Relatively more current from the fifth resistor R₅ 3138 then bypasses through the first transistor Q₁ 3110 and to the third current sink I₃ 3148 instead of applying to the base of the fourth transistor Q₄ 3116. The fourth transistor Q₄ 3116 thus reduces conductance between its collector and emitter when the input to the LVDS buffer circuit 3100 is high.

The decreased conductance of the fourth transistor Q₄ 3116 allows the first current sink I₁ 3146 to pull the base of a fifth transistor Q₅ 3118 low via a second resistor R₂ 3132. A first resistor R₁ 3130 and the second resistor R₂ 3132 are selected to dampen reflections from mismatches in termination at the load. The second resistor R₂ 3132 and a corresponding fourth resistor R₄ 3136 allow a dramatic reduction in an amount of resistance for the first resistor R₁ 3130 and a third resistor R₃ 3134, which are used to absorb reflections due to termination mismatches. Advantageously, power dissipated by the first resistor R₁ 3130 and the third resistor R₃ 3134 is also reduced. The resistance of the second resistor R₂ 3132, and of the corresponding fourth resistor R₄ 3136, is effectively lower as seen by a load applied to the outputs OUT_{N} 3108 and OUT_{P} 3106 due to the current amplification of the fifth transistor Q₅ 3118. In the illustrated embodiment, a resistance of the first resistor R₁ 3130 is about 20 ohms and can range from about 16 ohms to about 24 ohms. In the illustrated embodiment, a resistance of the second resistor R₂ 3132 is about 500 ohms and can range from about 400 ohms to about 600 ohms. In one embodiment, the first resistor R₁ 3130 is approximately at least 10 times the value of the second resistor R₂ 3132.

With the base of the fifth transistor Q₅ pulled low, the emitter of the fifth transistor Q₅ 3118 decreases an amount of current injected to a first terminal of the first resistor R₁ and the collector of a third transistor Q₃ 3114. This allows the third transistor Q₃ 3114 to pull down or sink current from the load coupled to a second terminal of the first resistor R₁ 3130.

With the input to the non-inverted input signal IN_{P} 3102 high, the second transistor Q₂ 3112 applies relatively more current from the V_{DDO} source and a second diode D₂ 3144 to the base of the third transistor Q₃ 3114. A first diode D₁ 3142 and the second diode D₂ 3144 lower the potential of the VDDO supply coupled to the output stages of the LVDS buffer circuit 3100 to reduce power in the output stage. In turn, the third transistor Q₃ 3114 conducts relatively more current from the first resistor R₁ 3130 and the load applied to the inverted output OUT_{N} 3108 to the fifth current sink I₅ 3154, thereby pulling the inverted output OUT_{N} 3108 relatively lower in voltage.

With the input to the inverted input signal IN_{N} 3104 low, a seventh transistor Q₇ 3122 applies relatively less current from the V_{DDO} source and the second diode D₂ 3144 to the base of an eighth transistor Q₈ 3124, and the base of the eighth transistor Q₈ 3124 is pulled low by the sixth current sink I₆ 3156. In turn, the eighth transistor Q₈ 3124 conducts relatively less current from the third resistor R₃ 3134 and the load applied to the inverted output OUT_{P} 3106 to the fifth current sink I₅ 3154, thereby allowing the non-inverted output OUTP 3106 to rise in voltage.

When the input is high so that the inverted input signal IN_{N} 3104 is low, the base of the sixth transistor Q₆ 3120 sinks relatively less current from a first terminal of a sixth resistor R₆ 3140 and the base of the ninth transistor Q₉ 3126 to the third current source I₃ 3148. The sixth transistor Q₆ 3120 turns off or conducts relatively less current from the sixth resistor R₆ 3140 to the third current source I₃ 3148, thereby enabling relatively more current from the sixth resistor R₆ 3140 to be applied to the base of the ninth transistor Q₉ 3126. In turn, the ninth transistor Q₉ 3126 applies relatively more current to the fourth resistor R₄ 3136 and thereby to the base of tenth transistor Q₁₀ 3128, which increases the conductance of the tenth transistor Q₁₀ 3128 from collector to emitter. With increased conductance, relatively more current from a first diode D₁ 3142 is applied to the third resistor R₃ 3134 and to a load coupled to the non-inverted output OUT_{P} 3106, thereby raising the potential of the non-inverted output OUT_{P} 3106 higher relative to the inverted output OUT_{N} 3108.

The third resistor R₃ 3134 and the fourth resistor R₄ 3136 are also selected to dampen reflections from mismatches in termination at the load. In one embodiment, the resistances of the third resistor R₃ 3134 and of the fourth resistor R₄ 3136 are matched with the resistances of the first resistor R₁ 3130 and of the second resistor R₂ 3132, respectively.

The operation of the LVDS buffer circuit 3100 will now be described with the input low. When the input to the LVDS buffer circuit 3100 is low, the non-inverted input signal IN_{P} 3102 is low relative to the inverted input signal IN_{N} 3104. The collector of the first transistor Q₁ sinks relatively less current from the first terminal of the fifth resistor R₅ 3138 and from the base of the fourth transistor Q₄ 3116, thereby allowing the fourth transistor Q₄ 3116 to apply relatively more current to the fifth transistor Q₅ 3118 through the second resistor 3132. The fifth transistor Q₅ 3118 responds by applying relatively more current from the first diode D₁ 3142 to the first resistor R₁ 3130 and to the load coupled to OUT_{N} 3130, which thereby increases the relative voltage at OUT_{N} 3130.

When the input to the non-inverted input signal IN_{P} 3102 is low, the second transistor Q₂ 3112 sinks relatively less current from the V_{DDO} source and the second diode D₂ 3144 to the base of the third transistor Q₃ 3114. In turn, the fourth current sink I₄ 3152 pulls the base of the third transistor Q₃ 3114 low, thereby decreasing an amount of current sunk by the third transistor Q₃ 3114 from the first resistor R₁ 3130 and the load applied to the inverted output OUT_{N} 3108, and thereby raising the relative voltage at OUT_{N} 3130.

When the input is low so that the inverted input signal IN_{N} 3104 is high, the base of the sixth transistor Q₆ 3120 sinks relatively more current from the first terminal of the sixth resistor R₆ 3140 and the base of the ninth transistor Q₉ 3126 to the third current source I₃ 3148, thereby bypassing current that otherwise would apply to the base of the ninth transistor Q₉ 3126. In turn, the ninth transistor Q₉ 3126 applies relatively less current to the base of tenth transistor Q₁₀ 3128 through the fourth resistor R₄ 3136, which decreases the conductance of the tenth transistor Q₁₀ 3128 from collector to emitter. With decreased conductance, relatively less current from the first diode D₁ 3142 is applied to the third resistor R₃ 3134 and to the load coupled to the non-inverted output OUT_{P} 3106, thereby lowering the potential of the non-inverted output OUT_{P} 3106 relative to the inverted output OUT_{N} 3108.

With the input to the inverted input signal IN_{N} 3104 high, the seventh transistor Q₇ 3122 applies relatively more current from the V_{DDO} source and the second diode D₂ 3144 to the base of the eighth transistor Q₈ 3124. In turn, the eighth transistor Q₈ 3124 conducts relatively more current from the third resistor R₃ 3134 and from the load applied to the inverted output OUT_{P} 3106 to the fifth current sink I₄ 3154, thereby lowering the voltage at the non-inverted output OUT_{P} 3106.

In one embodiment of the LVDS buffer circuit 3100, the relative areas of the first transistor Q₁ 3110, the second transistor Q₂ 3112, the third transistor Q₃ 3114, the fourth transistor Q₄ 3116, the fifth transistor Q₅ 3118, the sixth transistor Q₆ 3120, the seventh transistor Q₇ 3122, the eighth transistor Q₈ 3124, the ninth transistor Q₉ 3126, and the tenth transistor Q₁₀ 3128 are about 1.0, 1.6, 10.4, 1.0, 10.6, 1.0, 1.6, 10.4, 1.0, and 10.6, respectively.

Various embodiments of the invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

APPENDIX A
Incorporation by Reference of Commonly Owned Applications
The following patent applications, commonly owned and filed on the
same day as the present application, are hereby incorporated herein
in their entirety by reference thereto:

| | | |
|---|---|---|
| | Application | Attorney |
| Title | No. | Docket No. |

| | |
|---|---|
| “Integration and Hold Phase Detection” | CCOM.003A |
| “Current Mode Phase Detection” | CCOM.004A |
| “Trigger Circuit” | CCOM.005A |
| “Two-Stage Multiplier Circuit” | CCOM.006A |
| “Reset Circuit” | CCOM.007A |
| “Multiplier Circuit” | CCOM.008A |
| “Data Transition Identifier” | CCOM.009A |
| “Frame Pattern Detection in an Optical | CCOM.016A |
| Receiver” | |
| “Single to Differential Input Buffer | CCOM.017A |
| Circuit” | |
| “Acquisition Aid Circuit” | CCOM.018A |
| “Low Frequency Loop-Back in a High- | CCOM.020A |
| Speed Optical Transceiver” | |
| “Phase Frequency Detector” | CCOM.021A |
| “Phase Alignment of Data to Clock” | CCOM.022A |
| “Voltage Controlled Oscillator” | CCOM.023A |
| “System and Method of Digital Tuning a | CCOM.024A |
| Voltage Controlled Oscillator” | |
| “System and Method of Tuning a Voltage | CCOM.025A |
| Controlled Oscillator” | |
| “High-Speed Output Driver” | CCOM.026A |

What is claimed is:

1. A low voltage differential signaling (LVDS) buffer output circuit, comprising:
a first voltage source terminal;
a first output terminal;
a first current sink circuit;
a second current sink circuit;
a first NPN transistor configured to source current to the first output terminal when biased to a first state, the first NPN transistor having a first base, a first collector, and a first emitter, the first collector coupled to the first voltage source terminal;
a first resistor having a first resistor terminal and a second resistor terminal, the first resistor terminal connected to the first base;
a second NPN transistor configured to sink current from the first output terminal when biased to a second state, the second NPN transistor having a second base, a second collector, and a second emitter, the second base coupled to the first current sink circuit, the second collector coupled to the first emitter, and the second emitter coupled to a second current sink; and
a second resistor having a third resistor terminal and a fourth resistor terminal, the third resistor terminal connected to the first emitter and the second collector, and the fourth resistor terminal coupled to the first output terminal, the second resistor selected to dampen reflections from a termination mismatch.

2. The LVDS buffer output circuit as defined in claim 1, further comprising:
a second output terminal, wherein the first output terminal is configured to be a non-inverting output terminal, and the second output terminal is configured to be an inverting output terminal;
a third current sink circuit;
a third NPN transistor configured to source current to the second output terminal when biased to a third state, the third NPN transistor having a third base, a third collector, and a third emitter, the third collector coupled to the first voltage source terminal;
a third resistor having fifth and sixth resistor terminals, the fifth resistor terminal connected to the third base;
a fourth NPN transistor configured to sink current from the second output terminal when biased to a fourth state, the fourth NPN transistor having a fourth base, a fourth collector, and a fourth emitter, the fourth base coupled to a third current sink circuit, the fourth collector coupled to the second emitter, and the fourth emitter coupled to the second current sink circuit; and
a fourth resistor having a seventh resistor terminal and an eighth resistor terminal, the seventh resistor terminal connected to the third emitter and the fourth collector and the fourth resistor terminal coupled to the second output terminal, the fourth resistor selected to dampen reflections from a termination mismatch.

3. The LVDS buffer output circuit as defined in claim 1, wherein a resistance of the first resistor is at least ten times a resistance of the second resistor.

4. The LVDS buffer output circuit as defined in claim 1, further comprising a diode having a first terminal and a second terminal, the first terminal configured to be connected to voltage source and the second terminal connected to the first voltage source terminal.

5. The LVDS buffer output circuit as defined in claim 1, wherein a resistance of the first resistor is effectively lower as seen by a load applied to the first output terminal as a result of current amplification provided by the first transistor.

6. The LVDS buffer output circuit as defined in claim 1, further comprising:
an input terminal; and
an inverter circuit having an input section and an output section, the input section coupled to the input terminal, and the output section coupled to the second terminal of the first resistor and to the base of the second transistor, the inverter configured to invert a signal received on the input terminal.

7. The LVDS buffer output circuit as defined in claim 1, further comprising:
a first input terminal configured to receive a first signal;
a second voltage source terminal;
a third current sink; and
an inverter circuit coupled to the first input terminal, the inverter circuit configured to invert a signal received at the first input terminal, the inverter circuit comprising:
a third transistor having a third base, a third collector, and a third emitter, the third base coupled to the first input terminal, and the third emitter coupled to a third current sink;
a third resistor having a fifth resistor terminal and a sixth resistor terminal, the fifth resistor terminal connected to the second voltage source terminal, and the sixth resistor terminal coupled to the third collector;
a fourth transistor having a fourth base, a fourth collector, and a fourth emitter, the fourth base coupled to the first input terminal, the fourth collector coupled to the second voltage source terminal, and the fourth emitter coupled to the second base; and
a fifth transistor having a fifth base, a fifth collector, and a fifth emitter, the fifth base coupled to the third collector, the fifth collector coupled to the second voltage source terminal, and the fifth emitter coupled to a fourth current sink.

8. A transceiver, comprising:
a first network port having an first input and a first output, the first input configured to receive a differential network signal;
a buffer input terminal having a second input and a second output, the second input coupled to the first output; and
a buffer, comprising:
an inverter having a third input and a third output, the third input coupled to the second output; and
an output circuit, comprising:
a first voltage source terminal;
a first output terminal;
a first current sink circuit;
a second current sink circuit;
a first NPN transistor configured to source current to the first output terminal when biased to a first state, the first NPN transistor having a first base, a first collector, and a first emitter, the first collector coupled to the first voltage source terminal;
a first resistor having a first resistor terminal and a second resistor terminal, the first resistor terminal connected to the first base;
a second NPN transistor configured to sink current from the first output terminal when biased to a second state, the second NPN transistor having a second base, a second collector, and a second emitter, the second base coupled to the first current sink circuit, the second collector coupled to the first emitter, and the second emitter coupled to a second current sink; and
a second resistor having a third resistor terminal and a fourth resistor terminal, the third resistor terminal connected to the first emitter and the second collector, and the fourth resistor terminal coupled to the first output terminal, the second resistor selected to dampen reflections from a termination mismatch.

9. A low voltage differential signaling (LVDS) buffer circuit, comprising:
a first input terminal configured to receive a non-inverted input signal;
a second input terminal configured to receive an inverted input signal;
a first output terminal configured to provide a non-inverted output signal;
a second output terminal configured to provide an inverted output signal;
a first transistor having a first base, a first collector, and a first emitter, the first base coupled to the first input terminal, and the first emitter coupled to a first current sink;
a first resistor having a first resistor terminal and a second resistor terminal, the first resistor terminal connected to a first voltage source, and the second resistor terminal coupled to the first collector;
a second transistor having a second base, a second collector, and a second emitter, the second base coupled to the first input terminal, the second collector coupled to a second voltage source, and the second emitter coupled to a second current sink;
a third transistor having a third base, a third collector, and a third emitter, the third base coupled to the first collector, the third collector coupled to the first voltage source, and the third emitter coupled to a third current sink;
a second resistor having a third resistor terminal and a fourth resistor terminal, the fourth resistor terminal coupled to the second output terminal;
a third resistor having a fifth resistor terminal and a sixth resistor terminal, the fifth resistor terminal connected to the third emitter and the third current sink;
a fourth transistor having a fourth base, a fourth collector, and a fourth emitter, the fourth base coupled to the second emitter and the second current sink, the fourth collector coupled to the third resistor terminal, and the fourth emitter coupled to a fourth current sink;
a fifth transistor having a fifth base, a fifth collector, and a fifth emitter, the fifth base coupled to the sixth resistor terminal, the fifth collector coupled to a third voltage source, and the fifth emitter coupled to the fourth collector and the third resistor terminal;
a sixth transistor having a sixth base, a sixth collector, and a sixth emitter, the sixth base coupled to the second input terminal, and the sixth emitter coupled to the first current sink;
a fourth resistor having a seventh resistor terminal and an eighth resistor terminal, the seventh resistor terminal connected to the first voltage source, and the eighth resistor terminal coupled to the sixth collector;
a seventh transistor having a seventh base, a seventh collector, and a seventh emitter, the seventh base coupled to the second input terminal, the seventh collector coupled to the second voltage source, and the seventh emitter coupled to a fifth current sink;
an eighth transistor having an eighth base, an eighth collector, and an eighth emitter, the eighth base coupled to the sixth collector, the eighth collector coupled to the first voltage source, and the eighth emitter coupled to a sixth current sink;
a fifth resistor having a ninth resistor terminal and a tenth resistor terminal, the tenth resistor terminal coupled to the second output terminal;
a sixth resistor having an eleventh resistor terminal and a twelfth resistor terminal, the eleventh resistor terminal connected to the eighth emitter and the sixth current sink;
a ninth transistor having a ninth base, a ninth collector, and a ninth emitter, the ninth base coupled to the seventh emitter and the fifth current sink, the ninth collector coupled to the ninth resistor terminal, and the ninth emitter coupled to the fourth current sink; and
a tenth transistor having a tenth base, a tenth collector, and a tenth emitter, the tenth base coupled to the twelfth resistor terminal, the tenth collector coupled to the third voltage source, and the tenth emitter coupled to the ninth collector and the ninth resistor terminal.

10. The LVDS buffer circuit as defined in claim 9, wherein the second and third voltage source are at a same voltage level.

11. The LVDS buffer circuit as defined in claim 9, wherein the second resistor is selected to dampen reflections from a termination mismatch.
